(19) United States
(12) Patent Application Publication
(10) Pub. No.: US 2026/0051338 A1
(43) Pub. Date: Feb. 19, 2026

(54) SEMICONDUCTOR MEMORY DEVICE

(71) Applicant: Kioxia Corporation, Tokyo (JP)

(72) Inventor: Hidenobu Nagashima, Yokkaichi Mie (JP)

(73) Assignee: Kioxia Corporation, Tokyo (JP)

(21) Appl. No.: 19/041,450

(22) Filed: Jan. 30, 2025

(30) Foreign Application Priority Data
Aug. 15, 2024 (JP) 2024-135689

(51) Int. Cl. G11C 5/06; G11C 16/04; H10B 41/10; H10B 41/35; H10B 43/10; H10B 43/35

(52) U.S. Cl. CPC G11C 5/063; G11C 16/0483; H10B 41/10; H10B 41/35; H10B 43/10; H10B 43/35

(57) ABSTRACT

According to one embodiment, a semiconductor memory device includes a layer stack in which a plurality of interconnect layers and a plurality of insulating layers are alternately stacked one by one, a memory pillar passing through the layer stack, and a first member dividing the layer stack. The plurality of insulating layers include a first insulating layer. The plurality of interconnect layers include a first interconnect layer and a second interconnect layer provided on the first insulating layer. The memory pillar includes a first sub-pillar passing through the first interconnect layer and a second sub-pillar provided on the first sub-pillar and passing through the second interconnect layer. The first member includes a first portion passing through the first interconnect layer and the second interconnect layer and including an upper end located above the second interconnect layer, and a second portion provided on the first portion.

### CROSS-REFERENCE TO RELATED APPLICATION

This application is based upon and claims the benefit of priority from prior Japanese Patent Application No. 2024-135689, filed Aug. 15, 2024, the entire contents of which are incorporated herein by reference.

### FIELD

Embodiments described herein relate generally to a semiconductor memory device.

### BACKGROUND

A NAND flash memory of a three-dimensional stack type is known as a semiconductor memory device.

### BRIEF DESCRIPTION OF THE DRAWINGS

FIG. 1 is a block diagram illustrating an overall configuration of a semiconductor memory device according to a first embodiment.

FIG. 2 is a circuit diagram illustrating an example of a memory cell array included in the semiconductor memory device according to the first embodiment.

FIG. 3 is a plan view illustrating an example of the memory cell array included in the semiconductor memory device according to the first embodiment.

FIG. 4 is a plan view illustrating an example of a planar layout of a coupling area of the memory cell array included in the semiconductor memory device according to the first embodiment.

FIG. 5 is a cross-sectional view of a memory cell area along line A1-A2 in FIG. 4.

FIG. 6 is a cross-sectional view of an XY plane of a memory pillar along line C1-C2 in FIG. 5.

FIG. 7 is a cross-sectional view of a coupling area along line B1-B2 in FIG. 4.

FIG. 8 is a conceptual view illustrating boundaries of a memory pillar, a member SLT, and a support pillar in the semiconductor memory device according to the first embodiment and a comparative embodiment.

FIG. 9 is a flowchart illustrating an example of a manufacturing process of the memory cell array included in the semiconductor memory device according to the first embodiment.

FIG. 10 illustrates an example of a planar layout of the memory cell array in the manufacturing process of the memory cell array included in the semiconductor memory device according to the first embodiment.

FIG. 11 is a cross-sectional view along line A1-A2 and line B1-B2 in FIG. 10.

FIG. 12 illustrates an example of a planar layout of the memory cell array in the manufacturing process of the memory cell array included in the semiconductor memory device according to the first embodiment.

FIG. 13 is a cross-sectional view along line A1-A2 and line B1-B2 in FIG. 12.

FIG. 14 illustrates an example of a planar layout of the memory cell array in the manufacturing process of the memory cell array included in the semiconductor memory device according to the first embodiment.

FIG. 15 is a cross-sectional view along line A1-A2 and line B1-B2 in FIG. 14.

FIG. 16 illustrates an example of a planar layout of the memory cell array in the manufacturing process of the memory cell array included in the semiconductor memory device according to the first embodiment.

FIG. 17 is a cross-sectional view along line A1-A2 and line B1-B2 in FIG. 16.

FIG. 18 illustrates an example of a planar layout of the memory cell array in the manufacturing process of the memory cell array included in the semiconductor memory device according to the first embodiment.

FIG. 19 is a cross-sectional view along line A1-A2 and line B1-B2 in FIG. 18.

FIG. 20 illustrates an example of a planar layout of the memory cell array in the manufacturing process of the memory cell array included in the semiconductor memory device according to the first embodiment.

FIG. 21 is a cross-sectional view along line A1-A2 and line B1-B2 in FIG. 20.

FIG. 22 illustrates an example of a planar layout of the memory cell array in the manufacturing process of the memory cell array included in the semiconductor memory device according to the first embodiment.

FIG. 23 is a cross-sectional view along line A1-A2 and line B1-B2 in FIG. 22.

FIG. 24 illustrates an example of a planar layout of the memory cell array in the manufacturing process of the memory cell array included in the semiconductor memory device according to the first embodiment.

FIG. 25 is a cross-sectional view along line A1-A2 and line B1-B2 in FIG. 24.

FIG. 26 illustrates an example of a planar layout of the memory cell array in the manufacturing process of the memory cell array included in the semiconductor memory device according to the first embodiment.

FIG. 27 is a cross-sectional view along line A1-A2 and line B1-B2 in FIG. 26.

FIG. 28 illustrates an example of a planar layout of the memory cell array in the manufacturing process of the memory cell array included in the semiconductor memory device according to the first embodiment.

FIG. 29 is a cross-sectional view along line A1-A2 and line B1-B2 in FIG. 28.

FIG. 30 illustrates an example of a planar layout of the memory cell array in the manufacturing process of the memory cell array included in the semiconductor memory device according to the first embodiment.

FIG. 31 is a cross-sectional view along line A1-A2 and line B1-B2 in FIG. 30.

FIG. 32 illustrates an example of a planar layout of the memory cell array in the manufacturing process of the memory cell array included in the semiconductor memory device according to the first embodiment.

FIG. 33 is a cross-sectional view along line A1-A2 and line B1-B2 in FIG. 32.

FIG. 34 illustrates an example of a planar layout of the memory cell array in the manufacturing process of the memory cell array included in the semiconductor memory device according to the first embodiment.

FIG. 35 is a cross-sectional view along line A1-A2 and line B1-B2 in FIG. 34.

FIG. 36 illustrates an example of a planar layout of the memory cell array in the manufacturing process of the memory cell array included in the semiconductor memory device according to the first embodiment.

FIG. 37 is a cross-sectional view along line A1-A2 and line B1-B2 in FIG. 36.

FIG. 38 is a cross-sectional view illustrating an example of a cross-sectional configuration of a memory cell area in a memory cell array included in a semiconductor memory device according to a second embodiment.

FIG. 39 is a cross-sectional view illustrating an example of a cross-sectional configuration of a coupling area in the memory cell array included in the semiconductor memory device according to the second embodiment.

FIG. 40 is a conceptual view illustrating boundaries of a memory pillar, a member SLT, and a support pillar in the semiconductor memory device according to the second embodiment and a comparative embodiment.

FIG. 41 is a flowchart illustrating an example of a manufacturing process of the memory cell array included in the semiconductor memory device according to the second embodiment.

FIG. 42 is a flowchart illustrating an example of a manufacturing process of the memory cell array included in the semiconductor memory device according to the second embodiment.

FIG. 43 illustrates an example of a planar layout of the memory cell array in the manufacturing process of the memory cell array included in the semiconductor memory device according to the second embodiment.

FIG. 44 is a cross-sectional view along line A1-A2 and line B1-B2 in FIG. 43.

FIG. 45 illustrates an example of a planar layout of the memory cell array in the manufacturing process of the memory cell array included in the semiconductor memory device according to the second embodiment.

FIG. 46 is a cross-sectional view along line A1-A2 and line B1-B2 in FIG. 45.

FIG. 47 illustrates an example of a planar layout of the memory cell array in the manufacturing process of the memory cell array included in the semiconductor memory device according to the second embodiment.

FIG. 48 is a cross-sectional view along line A1-A2 and line B1-B2 in FIG. 47.

FIG. 49 illustrates an example of a planar layout of the memory cell array in the manufacturing process of the memory cell array included in the semiconductor memory device according to the second embodiment.

FIG. 50 is a cross-sectional view along line A1-A2 and line B1-B2 in FIG. 49.

FIG. 51 illustrates an example of a planar layout of the memory cell array in the manufacturing process of the memory cell array included in the semiconductor memory device according to the second embodiment.

FIG. 52 is a cross-sectional view along line A1-A2 and line B1-B2 in FIG. 51.

FIG. 53 illustrates an example of a planar layout of the memory cell array in the manufacturing process of the memory cell array included in the semiconductor memory device according to the second embodiment.

FIG. 54 is a cross-sectional view along line A1-A2 and line B1-B2 in FIG. 53.

FIG. 55 illustrates an example of a planar layout of the memory cell array in the manufacturing process of the memory cell array included in the semiconductor memory device according to the second embodiment.

FIG. 56 is a cross-sectional view along line A1-A2 and line B1-B2 in FIG. 55.

FIG. 57 illustrates an example of a planar layout of the memory cell array in the manufacturing process of the memory cell array included in the semiconductor memory device according to the second embodiment.

FIG. 58 is a cross-sectional view along line A1-A2 and line B1-B2 in FIG. 57.

FIG. 59 illustrates an example of a planar layout of the memory cell array in the manufacturing process of the memory cell array included in the semiconductor memory device according to the second embodiment.

FIG. 60 is a cross-sectional view along line A1-A2 and line B1-B2 in FIG. 59.

FIG. 61 illustrates an example of a planar layout of the memory cell array in the manufacturing process of the memory cell array included in the semiconductor memory device according to the second embodiment.

FIG. 62 is a cross-sectional view along line A1-A2 and line B1-B2 in FIG. 61.

FIG. 63 illustrates an example of a planar layout of the memory cell array in the manufacturing process of the memory cell array included in the semiconductor memory device according to the second embodiment.

FIG. 64 is a cross-sectional view along line A1-A2 and line B1-B2 in FIG. 63.

FIG. 65 illustrates an example of a planar layout of the memory cell array in the manufacturing process of the memory cell array included in the semiconductor memory device according to the second embodiment.

FIG. 66 is a cross-sectional view along line A1-A2 and line B1-B2 in FIG. 65.

FIG. 67 illustrates an example of a planar layout of the memory cell array in the manufacturing process of the memory cell array included in the semiconductor memory device according to the second embodiment.

FIG. 68 is a cross-sectional view along line A1-A2 and line B1-B2 in FIG. 67.

FIG. 69 illustrates an example of a planar layout of the memory cell array in the manufacturing process of the memory cell array included in the semiconductor memory device according to the second embodiment.

FIG. 70 is a cross-sectional view along line A1-A2 and line B1-B2 in FIG. 69.

FIG. 71 illustrates an example of a planar layout of the memory cell array in the manufacturing process of the memory cell array included in the semiconductor memory device according to the second embodiment.

FIG. 72 is a cross-sectional view along line A1-A2 and line B1-B2 in FIG. 71.

FIG. 73 illustrates an example of a planar layout of the memory cell array in the manufacturing process of the memory cell array included in the semiconductor memory device according to the second embodiment.

FIG. 74 is a cross-sectional view along line A1-A2 and line B1-B2 in FIG. 73.

FIG. 75 is a plan view illustrating an example of a planar layout of a coupling area of a memory cell array included in a semiconductor memory device according to a third embodiment.

FIG. 76 is a cross-sectional view of the coupling area along line B1-B2 in FIG. 75.

FIG. 77 is a view illustrating an example of a cross-sectional configuration of the coupling area in a manufacturing process of the memory cell array included in the semiconductor memory device according to the third embodiment.

FIG. 78 is a view illustrating an example of a cross-sectional configuration of the coupling area in the manufacturing process of the memory cell array included in the semiconductor memory device according to the third embodiment.

FIG. 79 is a view illustrating an example of a cross-sectional configuration of the coupling area in the manufacturing process of the memory cell array included in the semiconductor memory device according to the third embodiment.

FIG. 80 is a view illustrating an example of a cross-sectional configuration of the coupling area in the manufacturing process of the memory cell array included in the semiconductor memory device according to the third embodiment.

FIG. 81 is a view illustrating an example of a cross-sectional configuration of the coupling area in the manufacturing process of the memory cell array included in the semiconductor memory device according to the third embodiment.

FIG. 82 is a view illustrating an example of a cross-sectional configuration of a memory cell area of a memory cell array included in a semiconductor memory device according to a first modification of the third embodiment.

FIG. 83 is a view illustrating an example of a cross-sectional configuration of a coupling area of the memory cell array included in the semiconductor memory device according to the first modification of the third embodiment.

FIG. 84 is a view illustrating an example of a cross-sectional configuration of a memory cell area of a memory cell array included in a semiconductor memory device according to a second modification of the third embodiment.

FIG. 85 is a view illustrating an example of a cross-sectional configuration of a coupling area of the memory cell array included in the semiconductor memory device according to the second modification of the third embodiment.

FIG. 86 is a plan view illustrating an example of a planar layout of a coupling area of a memory cell array included in a semiconductor memory device according to a fourth embodiment.

FIG. 87 is a cross-sectional view of the coupling area along line B1-B2 in FIG. 86.

FIG. 88 is a conceptual view illustrating boundaries of a support pillar and a contact plug in the semiconductor memory device according to the fourth embodiment and a comparative embodiment.

FIG. 89 is a flowchart illustrating an example of a manufacturing process of the memory cell array included in the semiconductor memory device according to the fourth embodiment.

FIG. 90 is a view illustrating an example of a cross-sectional configuration of the coupling area in the manufacturing process of the memory cell array included in the semiconductor memory device according to the fourth embodiment.

FIG. 91 is a view illustrating an example of a cross-sectional configuration of the coupling area in the manufacturing process of the memory cell array included in the semiconductor memory device according to the fourth embodiment.

FIG. 92 is a view illustrating an example of a cross-sectional configuration of the coupling area in the manufacturing process of the memory cell array included in the semiconductor memory device according to the fourth embodiment.

FIG. 93 is a view illustrating an example of a cross-sectional configuration of the coupling area in the manufacturing process of the memory cell array included in the semiconductor memory device according to the fourth embodiment.

FIG. 94 is a view illustrating an example of a cross-sectional configuration of the coupling area in the manufacturing process of the memory cell array included in the semiconductor memory device according to the fourth embodiment.

FIG. 95 is a view illustrating an example of a cross-sectional configuration of the coupling area in the manufacturing process of the memory cell array included in the semiconductor memory device according to the fourth embodiment.

FIG. 96 is a view illustrating an example of a cross-sectional configuration of the coupling area in the manufacturing process of the memory cell array included in the semiconductor memory device according to the fourth embodiment.

FIG. 97 is a view illustrating an example of a cross-sectional configuration of the coupling area in the manufacturing process of the memory cell array included in the semiconductor memory device according to the fourth embodiment.

FIG. 98 is a view illustrating an example of a cross-sectional configuration of the coupling area in the manufacturing process of the memory cell array included in the semiconductor memory device according to the fourth embodiment.

FIG. 99 is a cross-sectional view of a memory cell array included in a semiconductor memory device according to a modification.

### DETAILED DESCRIPTION

In general, according to one embodiment, a semiconductor memory device includes a layer stack in which a plurality of interconnect layers and a plurality of insulating layers are alternately stacked one by one in a first direction, a memory pillar extending in the first direction and passing through the layer stack, and a first member extending in the first direction and a second direction crossing the first direction and dividing the layer stack in a third direction crossing the first direction and the second direction. The plurality of insulating layers include a first insulating layer. The plurality of interconnect layers include a first interconnect layer on which the first insulating layer is provided and a second interconnect layer provided on the first insulating layer. The memory pillar includes a first sub-pillar extending in the first direction, passing through the first interconnect layer, and including an upper end located between the first interconnect layer and the second interconnect layer, and a second sub-pillar provided on the first sub-pillar, extending in the first direction, and passing through the second interconnect layer. The first member includes a first portion extending in the first direction and the second direction, passing through the first interconnect layer and the second interconnect layer, and including an upper end located above the second interconnect layer, and a second portion provided on the first portion and extending in the layer stack in the first direction and the second direction.

Hereinafter, embodiments are described with reference to the accompanying drawings. In the description below, common reference signs are added to structural elements having identical functions and structures. In addition, in a case of distinguishing structural elements having common reference signs, the structural elements are distinguished by adding additional characters to the common reference signs. If structural elements do not need to be particularly distinguished, only common reference signs are added to the structural elements, and no additional characters are added. Here, the additional characters are not limited to subscripts and superscripts, and include, for example, lowercase alphabet, an index indicating an arrangement, and the like, which are added to ends of reference signs.

### 1. First Embodiment

First, a semiconductor memory device according to a first embodiment is described. Hereinafter, a three-dimensional stack-type NAND flash memory, in which memory cell transistors are three-dimensionally stacked on a semiconductor substrate, is described as an example of the semiconductor memory device.

### 1.1. Configuration

### 1.1.1. Overall Configuration of Semiconductor Memory Device

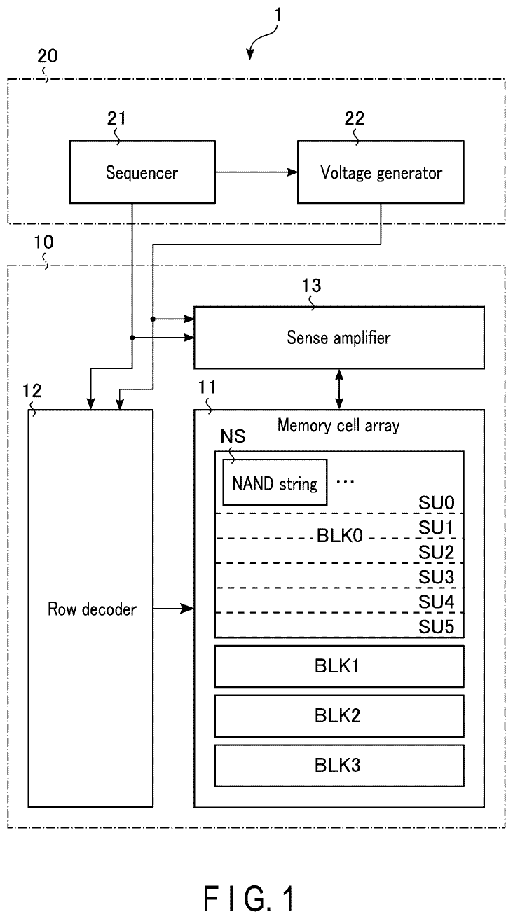

First, referring to FIG. 1, an example of an overall configuration of a semiconductor memory device 1 is described. FIG. 1 is a block diagram illustrating an overall configuration of the semiconductor memory device 1. Note that in FIG. 1, although some of couplings between structural elements are indicated by arrows, the couplings between the structural elements are not limited to this.

As illustrated in FIG. 1, the semiconductor memory device 1 includes a memory core section 10 and a peripheral circuit section 20.

The memory core section 10 includes a memory cell array 11, a row decoder 12, and a sense amplifier 13.

The memory cell array 11 is an area in which nonvolatile memory cell transistors (hereinafter, also referred to as “memory cells”) are three-dimensionally arranged. The memory cell array 11 includes a plurality of blocks BLK. In the example illustrated in FIG. 1, the memory cell array 11 includes blocks BLK0 to BLK3. The block BLK is, for example, a set of memory cell transistors in which data is collectively erased. The block BLK includes a plurality of memory cell transistors associated with rows and columns. Each block BLK includes one or more string units SU. In the example illustrated in FIG. 1, the block BLK includes six string units SU0, SU1, SU2, SU3, SU4 and SU5. The string unit SU includes, for example, a plurality of NAND strings NS that are collectively selected in a write operation or a read operation. The NAND string NS includes a set of memory cell transistors that are coupled in series. Note that the number of blocks BLK in the memory cell array 1, and the number of string units SU in the block BLK are arbitrary. The details of the memory cell array 11 will be described later.

The row decoder 12 is a circuit that decodes a row address. The row decoder 12 receives information relating to a row address that is input from an external controller (not illustrated). Based on the decoded result of the information relating to the row address, the row decoder 12 selects interconnects (word lines and select gate lines) in the row direction of the memory cell array 11. The row decoder 12 supplies voltages to the selected interconnects in the row direction.

The sense amplifier 13 is a circuit that executes data write and data read. In a case of the read operation, the sense amplifier 13 reads data from any one of the string units SU of any one of the blocks BLK. In addition, in a case of the write operation, the sense amplifier 13 supplies voltages based on write data, to the memory cell array 11.

The peripheral circuit section 20 includes a sequencer 21 and a voltage generator 22.

The sequencer 21 controls the operation of the entirety of the semiconductor memory device 1. More specifically, the sequencer 21 controls the voltage generator 22, the row decoder 12, and the sense amplifier 13 for the write operation, the read operation, and the erase operation.

The voltage generator 22 generates voltages used in the write operation, the read operation, and the erase operation, and supplies the voltages to the row decoder 12, the sense amplifier 13, and the like.

### 1.1.2. Circuit Configuration of Memory Cell Array

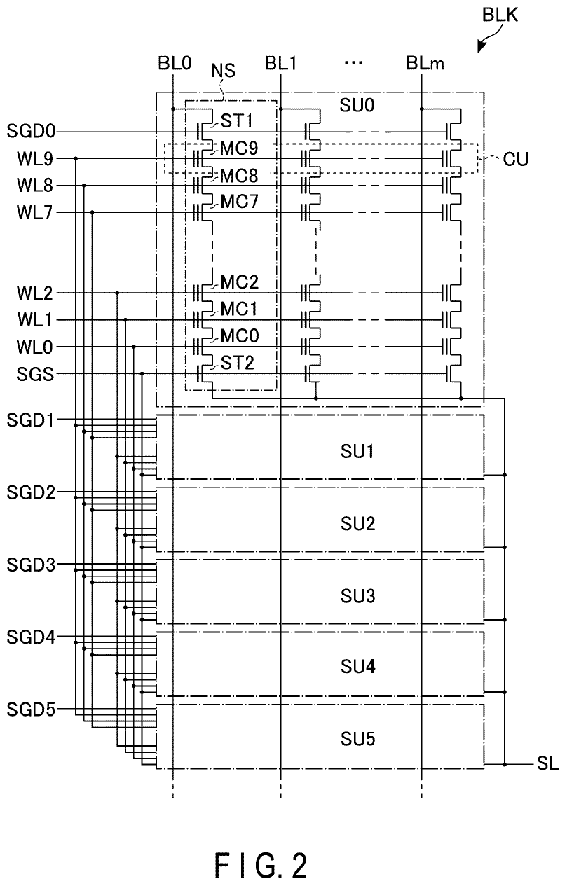

Next, referring to FIG. 2, an example of a circuit configuration of the memory cell array 11 is described. FIG. 2 is a circuit diagram of the memory cell array 11. Note that the example in FIG. 2 illustrates a circuit configuration of one block BLK.

As illustrated in FIG. 2, the string unit SU includes a plurality of NAND strings NS.

The NAND string NS includes a plurality of memory cell transistors MC and select transistors ST1 and ST2. In the example illustrated in FIG. 2, the NAND string NS includes ten memory cell transistors MC0 to MC9. Note that the number of memory cell transistors MC included in the NAND string NS is arbitrary.

The memory cell transistor MC is a memory element that stores data in a nonvolatile manner. The memory cell transistor MC includes a control gate and a charge storage film. The memory cell transistor MC may be of a metal-oxide-nitride-oxide-silicon (MONOS) type or a floating gate (FG) type. In the MONOS type, an insulating film is used for the charge storage film. In the FG type, a conductor is used for the charge storage film. Hereinafter, a case is described in which the memory cell transistor MC is of the MONOS type.

Each of the select transistors ST1 and ST2 is a switching element. Each of the select transistors ST1 and ST2 is used for selecting the string unit SU at a time of each of various operations. The number of select transistors ST1 and ST2 included in the NAND string NS is arbitrary. It suffices that at least one select transistor ST1 and at least one select transistor ST2 are included in the NAND string NS.

Current paths of the select transistor ST2, the memory cell transistors MC0 to MC9, and the select transistor ST1 in the NAND string NS are coupled in series. The drain of the select transistor ST1 is coupled to a bit line BL. The source of the select transistor ST2 is coupled to a source line SL.

The control gates of the memory cell transistors MC0 to MC9 in the same block BLK are coupled to word lines WL0 to WL9. More specifically, for example, the block BLK includes six string units SU0 to SU5. In addition, each string unit SU includes a plurality of memory cell transistors MC0. The control gates of the memory cell transistors MC0 in the block BLK are commonly coupled to one word line WL0. The same applies to the memory cell transistors MC1 to MC9.

The gates of a plurality of select transistors ST1 in the string unit SU are commonly coupled to one select gate line SGD. More specifically, the gates of the select transistors ST1 in the string unit SU0 are commonly coupled to a select gate line SGD0. The gates of the select transistors ST1 in the string unit SU1 are commonly coupled to a select gate line SGD1. The gates of the select transistors ST1 in the string unit SU2 are commonly coupled to a select gate line SGD2. The gates of the select transistors ST1 in the string unit SU3 are commonly coupled to a select gate line SGD3. The gates of the select transistors ST1 in the string unit SU4 are commonly coupled to a select gate line SGD4. The gates of the select transistors ST1 in the string unit SU5 are commonly coupled to a select gate line SGD5.

The gates of a plurality of select transistors ST2 in the block BLK are commonly coupled to a select gate line SGS. Note that, like the select gate line SGD, different select gate lines SGS may be provided for the respective string units SU.

The word lines WL0 to WL9, the select gate lines SGD0 to SGD5, and the select gate line SGS are coupled to the row decoder 12.

The bit line BL is commonly coupled to one NAND string NS in each string unit SU of each block BLK. In the example illustrated in FIG. 2, (m+1) bit lines BL0 to BLm (m is an integer of 0 or more) are provided. The (m+1) NAND strings NS in each string unit SU are coupled to bit lines BL0 to BLm, respectively. An identical column address is assigned to the NAND strings NS coupled to one bit line BL. Each bit line BL is coupled to the sense amplifier 13.

The source line SL is shared by, for example, a plurality of blocks BLK.

A set of a plurality of memory cell transistors MC coupled to a common word line WL in one string unit SU is described as, for example, “cell unit CU”. For example, a write operation and a read operation are executed in units of a cell unit CU.

### 1.1.3. Planar Layout of Memory Cell Array

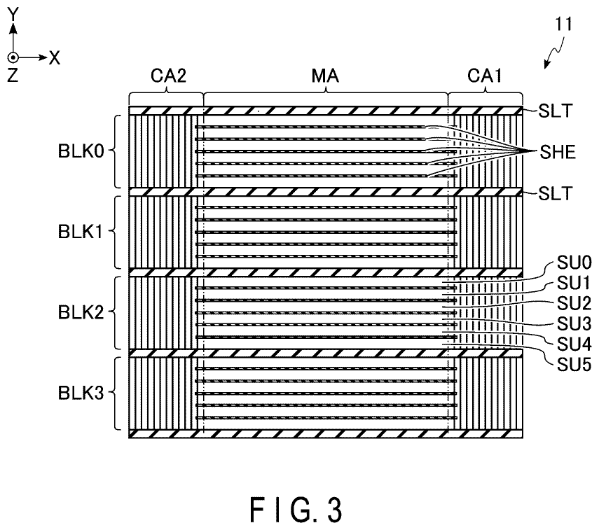

Next, referring to FIG. 3, a description is given of an example of a planar layout of the memory cell array 11. FIG. 3 is a plan view illustrating an example of the memory cell array 11. The example in FIG. 3 illustrates an area corresponding to four blocks BLK0 to BLK3. Note that in the example illustrated in FIG. 3, a part of interlayer insulating films is omitted. In plan views to be described below, hatching is added as appropriate, in order to make the drawings easier to view. The hatching added to the plan views is not necessarily associated with the material and characteristics of structural elements to which the hatching is added.

In the description below, a direction, which is parallel to the substrate and in which the word line WL extends, is defined as “X direction”. A direction, which is parallel to the substrate and intersects the X direction, is defined as “Y direction”. A direction, which intersects the X direction and Y direction and is perpendicular to the substrate, is defined as “Z direction”. In addition, in regard to the Z direction, a direction from the source line SL toward the word line WL, which are stacked apart from each other in the Z direction, is described as “upward”, and the direction from the word line WL toward the source line SL is described as “downward”.

As illustrated in FIG. 3, the planar layout of the memory cell array 11 is divided into, for example, a memory cell area MA and coupling areas CA1 and CA2 in the X direction. The memory cell array 11 includes a plurality of interconnect layers functioning as word lines WL and select gate lines SGD and SGS, and a plurality of members SLT and SHE. The interconnect layers are stacked apart from each other in the Z direction. Hereinafter, the interconnect layers corresponding to the word lines WL and the select gate lines SGD and SGS, which are stacked apart from each other in the Z direction, are also described as “stacked interconnects”.

The memory cell area MA is an area including a plurality of NAND strings NS (memory cell transistors MC).

The coupling area CA is an area that is used for coupling between each of the stacked interconnects and the row decoder 12. In the coupling area CA, each of the stacked interconnects is coupled to a corresponding contact plug. In the example illustrated in FIG. 3, twelve interconnect layers are provided. For example, the twelve interconnect layers function as the select gate line SGS, the word lines WL0 to WL9, and the select gate line SGD from a lower layer (on a side near the substrate) toward an upper layer.

In the example illustrated in FIG. 3, the coupling areas CA1 and CA2 are provided on both ends in the X direction of the memory cell area MA. Note that a coupling area CA may be provided between two memory cell areas MA. For example, in the coupling areas CA1 and CA2, in each interconnect layer, a coupling portion with a contact plug (hereinafter referred to as “plug coupling portion”) is provided. In the present embodiment, both ends extending in the X direction of each of the stacked interconnects is led out in a staircase fashion. In addition, a staircase part (staircase area) of the stacked interconnects, which is led out in a staircase fashion, corresponds to the plug coupling portion of each interconnect. In this case, no other interconnect layer is provided above the plug coupling portion. Hereinafter, in a case where a plug coupling portion is arranged in a staircase fashion and no other interconnect layer is provided above the plug coupling portion, the plug coupling portion is also referred to as “terrace”. Note that the stacked interconnects may not be led out in a staircase fashion. That is, another interconnect layer may be provided above the plug coupling portion. Also in this case, it is possible to form a contact plug that is electrically coupled to a target interconnect layer, but not electrically coupled to other interconnect layers.

The members SLT extend in the X direction and are arranged in the Y direction. Each member SLT extends across (passes through) the memory cell area MA and the coupling areas CA1 and CA2 in the X direction in a boundary area between mutually neighboring blocks BLK. In other words, the members SLT are provided over the memory cell area MA and the coupling areas CA1 and CA2. Each member SLT may have, for example, such a configuration that an insulator or a plate-shaped contact is buried. Each member SLT divides stacked interconnects that neighbor each other via the member SLT.

The members SHE extend in the X direction and are arranged in the Y direction. In the example illustrated in FIG. 3, five members SHE are arranged between mutually neighboring members SLT. Each member SHE extends across the memory cell area MA in the X direction. Both ends of each member SHE are included in the coupling areas CA1 and CA2, respectively. Each member SHE has, for example, such a configuration that an insulator is buried. Each member SHE divides select gate lines SGD that neighbor each other via the member SHE. Thus, the select gate lines SGD are divided by the members SLT and the members SHE for each string unit SU.

Each of the areas divided by the members SLT corresponds to one block BLK. In addition, each of the areas divided by the members SLT and SHE corresponds to one string unit SU. In the example illustrated in FIG. 3, one block BLK includes six string units SU0 to SU5.

Note that the planar layout of the memory cell array 11 is not limited to the above-described layout. For example, the number of members SHE arranged between mutually neighboring members SLT can be designed to be an arbitrary number. The number of string units SU formed between mutually neighboring members SLT can be changed based on the number of members SHE arranged between mutually neighboring members SLT.

### 1.1.4. Planar Layout of Coupling Area

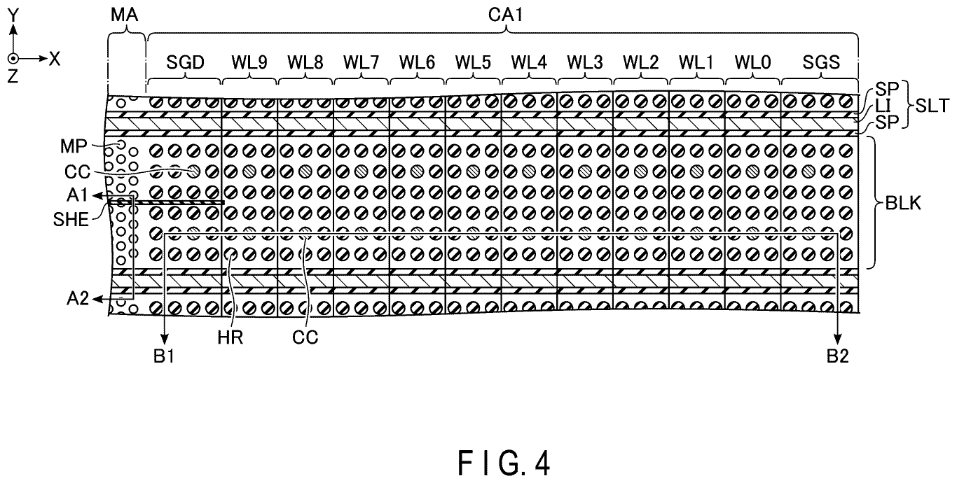

Next, referring to FIG. 4, an example of a planar layout of the coupling area CA1 is described. FIG. 4 is a plan view illustrating an example of the planar layout of the coupling area CA1. FIG. 4 illustrates the coupling area CA1 corresponding to one block BLK, and a part of the memory cell area MA located near the coupling area CA1. Note that in the example illustrated in FIG. 4, for the purpose of simpler description, only one member SHE is representatively shown in the block BLK. In addition, in the example illustrated in FIG. 4, a part of interlayer insulating films is omitted.

As illustrated in FIG. 4, in the coupling area CA1, terraces (plug coupling portions), which correspond to the select gate line SGD, the word lines WL9 to WL0, and the select gate line SGS, are successively provided from the memory cell area MA toward an X-directional end portion (toward the right on the drawing sheet).

Two side surfaces in the Y direction of one block BLK are provided with members SLT, respectively. The members SLT extend in the X direction and the Z direction. The member SLT divides the select gate line SGS, the word lines WL0 to WL9, and the select gate line SGD, which are stacked apart from each other in the Z direction, in each of the blocks BLK. For example, each member SLT includes a conductor LI and spacer SP. The conductor LI is a conductive member that is provided in the member SLT and extends in an XZ plane. The spacer SP is an insulator provided on a side surface of the conductor LI. The conductor LI is surrounded by the spacer SP in plan view from the Z direction. The conductor LI is electrically coupled to a source line SL provided below the stacked interconnects. Note that the conductor LI may be omitted. In this case, the inside of the member SLT is filled with an insulator.

The member SHE extends in the X direction. In the block BLK, the select gate line SGD is divided in the Y direction by the member SHE. Each of the areas divided by the members SLT and SHE corresponds to one string unit SU.

In the memory cell area MA, a plurality of memory pillars MP are provided. The memory pillar MP is a pillar corresponding to the NAND string NS. The details of the configuration of the memory pillar MP will be described later. For example, the memory pillar MP has a substantially columnar shape extending in the Z direction. The memory pillar MP penetrates (passes through) the select gate line SGS, the word lines WL0 to WL9, the and select gate line SGD, which are stacked apart from each other in the Z direction. In the example illustrated in FIG. 4, the memory pillars of the memory cell area MA are arranged in a staggered fashion. Note that the number of memory pillars MP and the arrangement of memory pillars MP can be freely designed.

In the coupling areas CA1 and CA2, a plurality of contact plugs CC and a plurality of support pillars HR are provided.

The contact plugs CC extend in the Z direction. For example, the contact plug CC is formed of a conductor in a substantially columnar shape. The contact plug CC is electrically coupled to an interconnect layer that is one of the stacked interconnects, and is not electrically coupled to the other interconnect layers. In other words, the contact plug CC is electrically coupled to a terrace of any one of the select gate line SGS, the word lines WL0 to WL9, and the select gate line SGD. For example, the contact plug CC, which is coupled to the terrace of the select gate line SGD, is not electrically coupled to the select gate line SGS and the word lines WL0 to WL9. An upper end of the contact plug CC is electrically coupled to the row decoder 12. FIG. 4 illustrates 24 contact plugs CC. The number of contact plugs CC, which are coupled to each interconnect layer (terrace), may be at least one.

As a method of forming the word lines WL and the select gate lines SGD and SGS, for example, there is known a method in which a structure corresponding to each interconnect layer is formed of a sacrificial film and then the sacrificial film is replaced with a conductive material, thereby forming an interconnect layer (hereinafter, this method is referred to as “WL replace”). In the WL replace, after a void is formed by removing the sacrificial film, a conductive material is buried in the void.

The support pillar HR functions, at a time of the WL replace, as a pillar for supporting a stacked structure including a void. The support pillar HR is not electrically coupled to the source line SL, the word line WL, and the select gate line SGD and SGS. The support pillar HR extends in the Z direction. For example, the support pillar HR has a substantially columnar structure formed of an insulator. In the coupling area CA1, the support pillar HR penetrates (passes through) the select gate line SGS, the word lines WL0 to WL9, and the select gate line SGD, which are stacked in the Z direction. Note that the number of support pillars HR and the arrangement of support pillars HR are arbitrary.

### 1.1.5. Cross-Sectional Configuration of Memory Cell Area

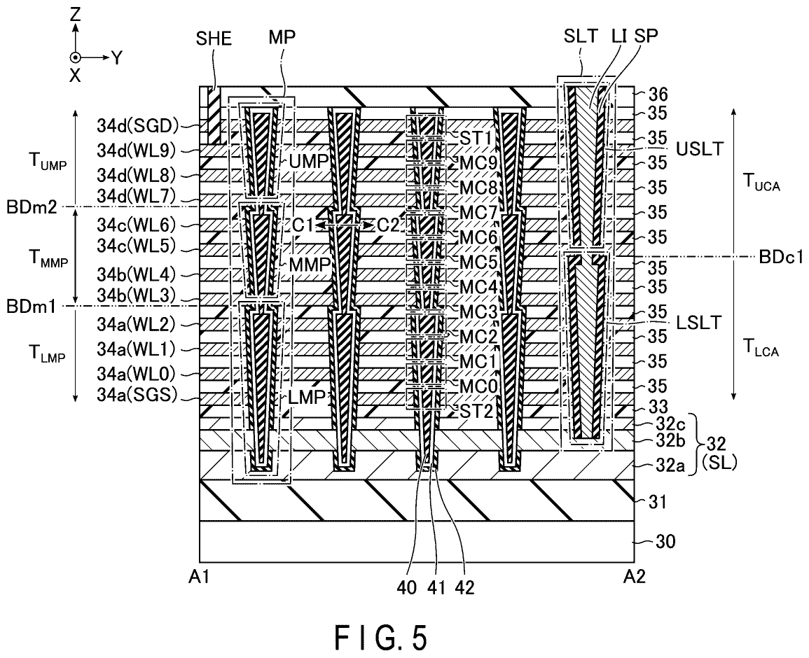

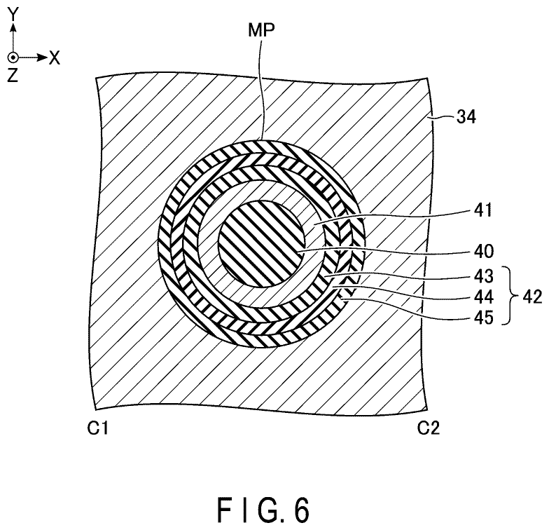

Referring to FIG. 5 and FIG. 6, an example of a cross-sectional configuration of the memory cell area MA is described. FIG. 5 is a cross-sectional view of the memory cell area MA along line A1-A2 in FIG. 4. FIG. 6 is a cross-sectional view of an XY plane of the memory pillar MP along line C1-C2 in FIG. 5. More specifically, FIG. 6 illustrates a cross-sectional configuration of the memory pillar MP in a layer that is parallel to the XY plane and includes the interconnect layers. Note that in the cross-sectional views to be described below, for the purpose of easier viewing, illustrations of configurations are omitted as appropriate.

As illustrated in FIG. 5, the memory cell array 11 includes a substrate 30, insulating layers 31, 33, 35, and 36, a semiconductor layer 32, interconnect layers 34, memory pillars MP, and members SLT and SHE.

The substrate 30 is, for example, a silicon substrate. On the substrate 30, the insulating layer 31 is provided. The insulating layer 31 includes, for example, silicon oxide. Circuits, such as the row decoder 12 or sense amplifier 13, may be provided in an area where the insulating layer 31 is provided, that is, an area between the substrate 30 and the semiconductor layer 32. Note that, for example, in a case where the semiconductor memory device 1 is configured such that a chip, in which the memory cell array 11 is provided, and a chip, in which circuits other than the memory cell array 11 are provided, are bonded, the substrate 30 provided under the insulating layer 31 may be omitted.

On the insulating layer 31, the semiconductor layer 32 is provided. The semiconductor layer 32 functions as the source line SL. The semiconductor layer 32 extends in the X direction and the Y direction. The semiconductor layer 32 includes, for example, three semiconductor layers 32a, 32b, and 32c. The semiconductor layer 32a is provided on the insulating layer 31. The semiconductor layer 32b is provided on the semiconductor layer 32a. The semiconductor layer 32c is provided on the semiconductor layer 32b. For example, the semiconductor layer 32b is provided in the memory cell area MA, and is not provided in the coupling area CA. Note that the semiconductor layer 32b may be provided also in the coupling area CA. The semiconductor layer 32b is formed, for example, by replacing an insulating layer provided between the semiconductor layer 32a and the semiconductor 32c. In the description below, the replacement of the semiconductor layer 32 is also described as “SL replace”. The semiconductor layer 32a to 32c include, for example, silicon. In addition, the semiconductor layer 32a to 32c include, for example, phosphorus (P) as an impurity of an n-type semiconductor.

The insulating layer 33 is provided on the semiconductor layer 32. The insulating layer 33 includes, for example, silicon oxide.

On the insulating layer 33, for example, twelve interconnect layers 34 (stacked interconnects) and twelve insulating layers 35 are alternately stacked one by one. Hereinafter, a stacked structure formed of the twelve interconnect layers 34 and twelve insulating layers 35 is also described as “layer stack”. In a case where four lower interconnect layers 34 of the twelve interconnect layers 34 are specified, the four lower interconnect layers 34 are described as “interconnect layers 34a”. The four interconnect layers 34a function as the select gate line SGS and the word lines WL0 to WL2 from the lowermost layer. In a case where two interconnect layers 34 provided above the interconnect layers 34a are specified, the two interconnect layers 34 are described as “interconnect layers 34b”. The two interconnect layers 34b function as the word lines WL3 and WL4 from the lower layer. In a case where two interconnect layers 34 provided above the interconnect layers 34b are specified, the two interconnect layers 34 are described as “interconnect layers 34c”. The two interconnect layers 34c function as the word lines WL5 and WL6 from the lower layer. In a case where four interconnect layers 34 provided above the interconnect layers 34c are specified, the four interconnect layers 34 are described as “interconnect layers 34d”. The four interconnect layers 34d function as the word lines WL7 to WL9 and the select gate line SGD from the lower layer. Note that a plurality of interconnect layers 34 may be provided as each of the interconnect layers 34 functioning as the select gate lines SGS or SGD.

For example, as a conductive material of the interconnect layer 34, a stacked structure of titanium nitride (TiN)/tungsten (W) is used. In this case, the titanium nitride is formed in a manner to cover the tungsten. For example, at a time of forming a film of tungsten by chemical vapor deposition (CVD), the titanium nitride has a function as a barrier layer for suppressing oxidation of the tungsten or as an adhesive layer for improving the adhesivity of the tungsten. In addition, the interconnect layer 34 can include a high-dielectric-constant material such as aluminum oxide (AlO). In this case, the high-dielectric-constant material is formed in a manner to cover the conductive material. For example, in each of the interconnect layers 34, the high-dielectric-constant material is formed in a manner to come in contact with the insulating layers 33 or 35 provided above or under the interconnect layer 34 and with side surfaces of the memory pillars MP. In addition, titanium nitride is provided in a manner to come in contact with the high-dielectric-constant material. Furthermore, tungsten is provided in a manner to come in contact with the titanium nitride and to fill the inside of the interconnect layer 34. For example, in a case where aluminum oxide is provided as the high-dielectric-constant material, the memory cell transistor MC is also described as a metal-aluminum-nitride-oxide-silicon (MANOS) type.

Next, a configuration of the memory pillar MP is described.

The memory pillar MP extends in the Z direction, and passes through the insulating layer 33, the twelve interconnect layers 34, and the twelve insulating layers 35. A lower end of the memory pillar MP reaches the semiconductor layer 32a. An upper end of the memory pillar MP is electrically coupled to the bit line BL via a contact plug (not illustrated).

The memory pillar MP can include one or more sub-pillars stacked in the Z direction. In the example illustrated in FIG. 5, the memory pillar MP includes a lower memory pillar LMP, a middle memory pillar MMP, and an upper memory pillar UMP. The lower memory pillar LMP, the middle memory pillar MMP, and the upper memory pillar UMP are sub-pillars of the memory pillar MP. In other words, the memory pillar MP has a configuration that is dividedly formed into three tiers. That is, the memory pillar MP is divisionally processed three times. Hereinafter, a tier corresponding to the lower memory pillar LMP is described as “lower tier T_{LMP}”. A tier corresponding to the middle memory pillar MMP is described as “middle tier T_{MMP}”. A tier corresponding to the upper memory pillar UMP is described as “upper tier T_{UMP}”. Note that the memory pillar MP may have a configuration of two tiers, or four or more tiers. That is, the memory pillar MP may be divisionally processed two times, or four or more times.

The lower memory pillar LMP passes through the insulating layer 33, four interconnect layers 34a, and four insulating layers 35 provided on the four interconnect layers 34a, respectively. That is, the lower memory pillar LMP passes through the four interconnect layers 34a functioning as the select gate line SGS and the word lines WL0 to WL2. A lower surface of the lower memory pillar LMP reaches the semiconductor layer 32a. Accordingly, the lower tier T_{LMP} includes the four interconnect layers 34a. Hereinafter, a stacked structure formed of the four interconnect layers 34a and the four insulating layers 35, through which the lower memory pillar LMP passes, is also described as “lower layer stack”.

The middle memory pillar MMP passes through two interconnect layers 34b, two interconnect layers 34c, and four insulating layers 35 provided on the interconnect layers 34b and 34c, respectively. That is, the middle memory pillar MMP passes through the two interconnect layers 34b functioning as the word lines WL3 and WL4, and the two interconnect layers 34c functioning as the word lines WL5 and WL6. Accordingly, the middle tier T_{MMP} includes the two interconnect layers 34b and the two interconnect layers 34c. A lower surface of the middle memory pillar MMP is in contact with an upper surface of the lower memory pillar LMP. A boundary BDm1, at which the upper surface of the lower memory pillar LMP and the lower surface of the middle memory pillar MMP come in contact, is located between the interconnect layer 34a functioning as the word line WL2 and the interconnect layer 34b functioning as the word line WL3. In other words, the boundary BDm1 between the lower tier T_{LMP} and the middle tier T_{MMP} is located between the interconnect layer 34a functioning as the word line WL2 and the interconnect layer 34b functioning as the word line WL3. Hereinafter, a stacked structure formed of the two interconnect layers 34b, two interconnect layers 34c and four insulating layers 35, through which the middle memory pillar MMP passes, is described as “middle layer stack”. Further, in the middle layer stack, layers including the two interconnect layers 34b and two insulating layers 35 are described as “lower layers of the middle layer stack”. In the middle layer stack, layers including the two interconnect layers 34c and two insulating layers 35 are described as “upper layers of the middle layer stack”.

The upper memory pillar UMP passes through four interconnect layers 34d, and four insulating layers 35 provided on the four interconnect layers 34d, respectively. That is, the upper memory pillar UMP passes through the four interconnect layers 34d functioning as the word lines WL7 to WL9 and the select gate line SGD. Accordingly, the upper tier T_{UMP} includes the four interconnect layers 34d. A lower surface of the upper memory pillar UMP is in contact with an upper surface of the middle memory pillar MMP. That is, a boundary BDm2, at which the upper surface of the middle memory pillar MMP and the lower surface of the upper memory pillar UMP come in contact, is located between the interconnect layer 34c functioning as the word line WL6 and the interconnect layer 34d functioning as the word line WL7. In other words, the boundary BDm2 between the middle tier T_{MMP} and the upper tier T_{UMP} is located between the interconnect layer 34c functioning as the word line WL6 and the interconnect layer 34d functioning as the word line WL7. Hereinafter, a stacked structure formed of the four interconnect layers 34d and the four insulating layers 35, through which the upper memory pillar UMP passes, is also described as “upper layer stack”.

Each of the lower memory pillar LMP, the middle memory pillar MMP, and the upper memory pillar UMP has, for example, a taper shape (also referred to as “forward taper shape”) with a greater diameter at an upper end than at a lower end thereof. In other words, each of the lower memory pillar LMP, the middle memory pillar MMP, and the upper memory pillar UMP has, for example, a truncated conical shape with a lower surface being smaller than an upper surface thereof. Thus, the boundary BDm1 between the lower memory pillar LMP and the middle memory pillar MMP and the boundary BDm2 between the middle memory pillar MMP and the upper memory pillar UMP can be confirmed by observing cross-sectional shapes.

The memory pillar MP includes, for example, a core film 40, a semiconductor film 41, and a stacked film 42. Each of the core film 40, the semiconductor film 41, and the stacked film 42 is formed, for example, as a continuous film in the lower memory pillar LMP, the middle memory pillar MMP, and the upper memory pillar UMP. The core film 40 has a substantially columnar shape extending in the Z direction. For example, an upper end of the core film 40 is located in a layer of a higher level than the interconnect layers 34, and a lower end of the core film 40 is located in the same layer as the semiconductor layer 32. The semiconductor film 41 extends in the Z direction and covers the circumference of the core film 40. The side surface of the semiconductor film 41 is in contact with the semiconductor layer 32b. The stacked film 42 covers the side surface and bottom surface of the semiconductor film 41, except for a part where the semiconductor film 41 and the semiconductor layer 32b are in contact with each other. The core film 40 includes, for example, an insulator such as silicon oxide. The semiconductor film 41 includes, for example, silicon.

As illustrated in FIG. 6, the stacked film 42 includes, for example, a tunnel insulating film 43, a charge storage film 44, and a block insulating film 45.

In a cross section including the interconnect layer 34, the core film 40 is provided, for example, at a central portion of the memory pillar MP. The semiconductor film 41 surrounds the side surface of the core film 40. The tunnel insulating film 43 surrounds the side surface of the semiconductor film 41. The charge storage film 44 surrounds the side surface of the tunnel insulating film 43. The block insulating film 45 surrounds the side surface of the charge storage film 44. The interconnect layer 34 surrounds the side surface of the block insulating film 45. Each of the tunnel insulating film 43 and the block insulating film 45 includes, for example, silicon oxide. The charge storage film 44 has a function of storing charge, and includes, for example, silicon nitride.

As illustrated in FIG. 5, the memory pillar MP and the interconnect layers 34 functioning as the word lines WL0 to WL9 are combined to constitute the memory cell transistors MC0 to MC9. Similarly, the memory pillar MP and the interconnect layer 34 functioning as the select gate line SGD are combined to constitute the select transistor ST1. The memory pillar MP and the interconnect layer 34 functioning as the select gate line SGS are combined to constitute the select transistor ST2. The semiconductor film 41 is used as channels (current paths) of the memory cell transistors MC0 to MC9 and select transistors ST1 and ST2. Thereby, each memory pillar MP can function as one NAND string NS.

Next, a configuration of the member SLT is described.

In the present embodiment, a configuration is described in which each of the member SLT, and the support pillar HR and the contact plug CC to be described layer, is formed by being divided into two tiers. That is, a case is described in which boundaries of the member SLT, the support pillar HR, and the contact plug CC are provided between the same interconnect layers 34. Hereinafter, a tier corresponding to a lower member LSLT, a lower support pillar LHR, and a lower contact plug LCC is described as “lower tier T_{LCA}”. In addition, a tier corresponding to an upper member USLT, an upper support pillar UHR, and an upper contact plug UCC is described as “upper tier T_{UCA}”.

The member SLT extends in the X direction and Z direction. The member SLT penetrates (passes through) the insulating layer 33, the twelve interconnect layers 34, and the twelve insulating layers 35. The member SLT divides the layer stack in the Y direction. A lower end of the member SLT reaches, for example, the semiconductor layer 32b.

The member SLT can include one or more sub-parts stacked in the Z direction. In the example illustrated in FIG. 5, the member SLT includes a lower member LSLT, and an upper member USLT provided on the lower member LSLT. The lower member LSLT and the upper member USLT are parts of the member SLT. In other words, the member SLT has a configuration in which the member SLT is formed by being divided into the lower tier T_{LCA} and upper tier T_{UCA}. That is, the member SLT is divisionally processed twice. Note that the member SLT may have a configuration of three or more tiers. That is, the member SLT may be divisionally processed three or more times. The number of tiers (the number of divisions) of the member SLT of the present embodiment is different from the number of tiers (the number of divisions) of the memory pillar MP.

The lower member LSLT passes through the insulating layer 33, the six interconnect layers 34 (four interconnect layers 34a and two interconnect layers 34b), and the six insulating layers 35 provided on the six interconnect layers 34, respectively. That is, the lower member LSLT passes through the six interconnect layers 34 (four interconnect layers 34a and two interconnect layers 34b) functioning as the select gate line SGS and the word lines WL0 to WL4. Accordingly, the lower tier T_{LCA} includes the four interconnect layers 34a and two interconnect layers 34b. A lower end of the lower member LSLT reaches the semiconductor layer 32b.

The upper member USLT passes through the six interconnect layers 34 (two interconnect layers 34c and four interconnect layers 34d), and the six insulating layers 35 provided on the six interconnect layers 34, respectively. That is, the upper member USLT passes through the six interconnect layers 34 (two interconnect layers 34c and four interconnect layers 34d) functioning as the word lines WL5 to WL9 and the select gate line SGD. Accordingly, the upper tier T_{UCA} includes the two interconnect layers 34c and the four interconnect layers 34d. A lower surface of the upper member USLT is in contact with an upper surface of the lower member LSLT. That is, a boundary BDc1, at which the upper surface of the lower member LSLT and the lower surface of the upper member USLT are in contact with each other, is located between the interconnect layer 34b functioning as the word line WL4 and the interconnect layer 34c functioning as the word line WL5. In other words, the boundary BDc1 between the lower tier T_{LCA} and upper tier T_{UCA} is located between the interconnect layer 34b functioning as the word line WL4 and the interconnect layer 34c functioning as the word line WL5. The tier boundary of the memory pillar MP and the tier boundary of the member SLT are located between different interconnect layers 34.

Each of the lower member LSLT and the upper member USLT has, for example, a taper shape with a greater width in the Y direction at an upper end than at a lower end thereof. Thus, the boundary BDc1 between the lower member LSLT and the upper member USLT can be confirmed by observing the cross-sectional shape.

The member SLT includes a conductor LI and a spacer SP. Each of the conductor LI and the spacer SP is formed, for example, as a continuous film in the lower member LSLT and the upper member USLT. In other words, the conductor LI is a conductive member provided in the member SLT and extending in the XZ plane. The spacer SP is an insulator provided on the side surface of the conductor LI. A lower end of the conductor LI is electrically coupled to the semiconductor layer 32 (source line SL). The conductor LI includes, for example, tungsten and titanium nitride, or silicon. The spacer SP includes, for example, silicon oxide.

The member SHE separates the interconnect layer 34 functioning as the select gate line SGD in the Y direction. In other words, the member SHE separates, among the interconnect layers 34, at least the uppermost interconnect layer 34 that is provided at a remotest position from the semiconductor layer 32. An upper end of the member SHE is located in a layer above the uppermost interconnect layer 34. A lower end of the member SHE is located in a layer between the interconnect layer 34 functioning as the select gate line SGD and the interconnect layer 34 functioning as the word line WL. The lower end of the member SHE may be located deeper in accordance with the number of interconnect layers 34 functioning as the select gate line SGD. The member SHE includes, for example, an insulator such as silicon oxide.

The insulating layer 36 is provided on the insulating layer 35. The insulating layer 36 includes, for example, silicon oxide.

### 1.1.6. Cross-Sectional Configuration of Coupling Area

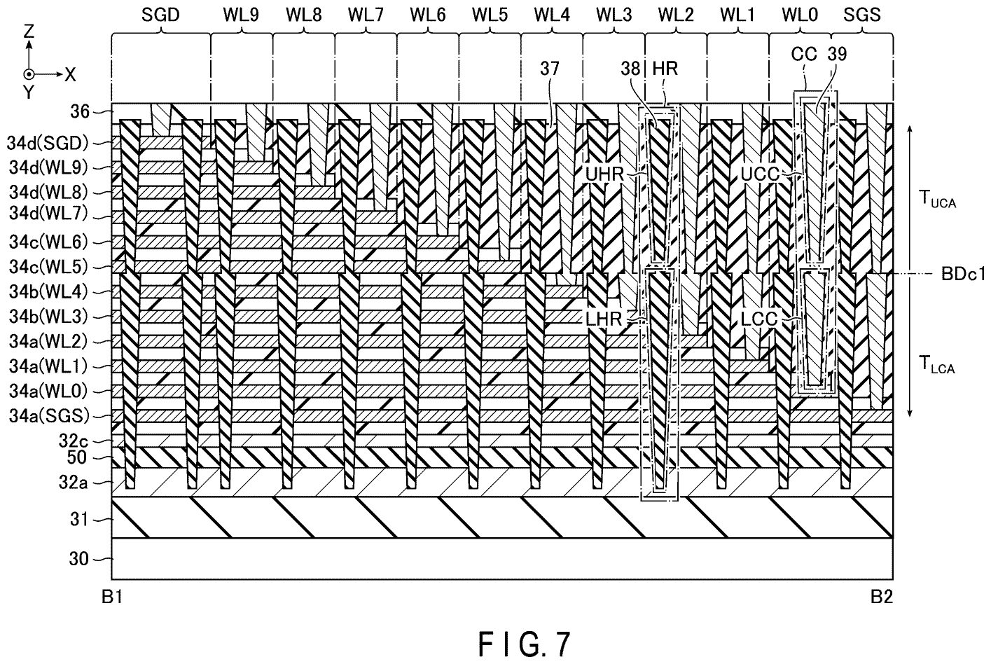

Referring to FIG. 7, an example of a cross-sectional configuration of the coupling area CA is described. FIG. 7 is a cross-sectional view of the coupling area CA1 along line B1-B2 in FIG. 4. Note that in the example illustrated in FIG. 7, in the terrace of the select gate line SGD, two support pillars HR passing through the terrace are illustrated in such a manner as to correspond to the cross section along line B1 to B2. On the other hand, in each terrace of the word lines WL0 to WL9 and the select gate line SGS, the depiction of some support pillars HR is omitted for the purpose of simpler illustration, and one support pillar HR passing through each terrace is illustrated. In each terrace of the word lines WL0 to WL9 and the select gate line SGS, although the depiction of some support pillars HR is omitted, the support pillars HR are provided in each terrace in the same arrangement as in the terrace of the select gate line SGD.

As illustrated in FIG. 7, in the coupling area CA, the memory cell array 11 further includes insulating layers 37 and 50, support pillars HR, and contact plugs CC.

The insulating layer 37 is formed in a manner to fill staircase parts (staircase areas) of the layer stack formed in the coupling area CA. The staircase parts are planarized by the insulating layer 37. The insulating layer 37 includes, for example, silicon oxide.

In the coupling area CA, the insulating layer 50 is provided between the semiconductor layer 32a and the semiconductor 32c. The insulating layer 50 in the coupling area CA is a layer that is left, without being removed, at a time of replace (SL replace) of the semiconductor layer 32. The insulating layer 50 includes, for example, silicon oxide.

Next, the support pillar HR is described.

The support pillar HR extends in the Z direction, and passes through the terrace of any one of the interconnect layers 34, and the interconnect layers 34 located under this terrace. Thus, the number of interconnect layers 34, through which the support pillar HR passes, varies depending on the corresponding terrace. For example, the support pillar HR provided in the terrace of the select gate line SGD passes through twelve interconnect layers 34. In addition, for example, the support pillar HR provided in the terrace of the select gate line SGS passes through one interconnect layer 34. The support pillars HR have substantially the same shape, regardless of the corresponding terraces. For example, a lower end of the support pillar HR reaches the semiconductor layer 32a. The support pillar HR is filled with an insulator 38. The insulator 38 includes, for example, silicon oxide.

The support pillar HR can include one or more sub-pillars stacked in the Z direction. In the example illustrated in FIG. 7, the support pillar HR includes a lower support pillar LHR, and an upper support pillar UHR provided on the lower support pillar LHR. The lower support pillar LHR and the upper support pillar UHR are sub-pillars of the support pillar HR. In other words, the support pillar HR has such a configuration that the support pillar HR is formed by being divided into the lower tier T_{LCA} and upper tier T_{UCA}. That is, the support pillar HR is divisionally processed twice. Note that the support pillar HR may have a configuration of three or more tiers. That is, the support pillar HR may be divisionally processed three or more times. The number of tiers (the number of divisions) of the support pillar HR of the present embodiment is different from the number of tiers (the number of divisions) of the memory pillar MP.

The lower support pillar LHR, which passes through each terrace of the select gate line SGS and the word lines WL0 to WL4, passes through the corresponding terrace and the interconnect layers 34 located under the terrace. For example, the lower support pillar LHR, which passes through the terrace of the select gate line SGS, passes through the interconnect layer 34a functioning as the select gate line SGS, and the insulating layer 35 provided on this interconnect layer 34a. The lower support pillar LHR, which passes through the terrace of the word line WL0, passes through two interconnect layers 34a functioning as the select gate line SGS and the word line WL0, and two insulating layers 35. The lower support pillar LHR, which passes through the terrace of the word line WL4, passes through the six interconnect layers 34 (four interconnect layers 34a and two interconnect layers 34b) functioning as the select gate line SGS and the word lines WL0 to WL4, and six insulating layers 35. Further, the lower support pillar LHR, which passes through each terrace of the select gate line SGS and the word lines WL0 to WL3, passes through the insulating layer 37 that is used for planarization (burying) of the staircase part. In addition, the lower support pillars LHR provided under the terraces of the word lines WL5 to WL9 and the select gate line SGD, do not pass through the terraces. These lower support pillars LHR pass through the six interconnect layers 34 (four interconnect layers 34a and two interconnect layers 34b) functioning as the select gate line SGS and the word lines WL0 to WL4, and the six insulating layers 35, under the corresponding terraces. The lower end of each lower support pillar LHR reaches, for example, the semiconductor layer 32a.

The upper support pillar UHR provided above each terrace of the select gate line SGS and the word lines WL0 to WL4 does not pass through the interconnect layer 34, and passes through the insulating layer 37. In addition, the upper support pillar UHR, which passes through each terrace of the word lines WL5 to WL9 and the select gate line SGD, passes through the corresponding terrace and the interconnect layers 34 of the upper tier T_{UCA} located under the terrace. For example, the upper support pillar UHR provided in the terrace of the word line WL5 passes through the interconnect layer 34c functioning as the word line WL5, and the insulating layer 35 provided on the interconnect layer 34c. For example, the upper support UHR, which passes through the terrace of the select gate line SGD, passes through six interconnect layers 34 (two interconnect layers 34c and four interconnect layers 34d) functioning as the word lines WL5 to WL9 and the select gate line SGD, and six insulating layers 35. Further, the upper support pillar UHR, which passes through each terrace of the word lines WL5 to WL9, passes through the insulating layer 37. The lower surface of each of the upper support pillars UHR is in contact with the upper surface of the corresponding lower support pillar LHR. That is, the boundary BDc1, at which the upper surface of the lower support pillar LHR and the lower surface of the upper support pillar UHR are in contact with each other, is located between the interconnect layer 34b functioning as the word line WL4 and the interconnect layer 34c functioning as the word line WL5. The tier boundary of the memory pillar MP and the tier boundary of the support pillar HR are located between different interconnect layers 34.

Each of the lower support pillar LHR and the upper support pillar UHR has, for example, a taper shape with a greater diameter at an upper end than at a lower end thereof. In other words, each of the lower support pillar LHR and the upper support pillar UHR has, for example, a truncated conical shape with a lower surface being smaller than an upper surface thereof. Thus, the boundary BDc1 between the lower support pillar LHR and the upper support pillar UHR can be confirmed by observing the cross-sectional shape.

Next, the contact plug CC is described.

In the coupling area CA, the contact plug CC is provided on each terrace. A lower end of the contact plug CC is in contact with the terrace of the corresponding interconnect layer 34. The contact plug CC extends in the Z direction. The contact plug CC of the present embodiment does not pass through the interconnect layers 34 located below the terrace. Thus, the shape (the height in the Z direction) of the contact plug CC varies depending on the terrace to which the contact plug CC is coupled. An upper end of the contact plug CC is located above the uppermost interconnect layer 34 that functions as the select gate line SGD. The contact plug CC includes, for example, tungsten or copper as a conductor.

The contact plug CC can include one or more sub-plugs stacked in the Z direction. In the example illustrated in FIG. 7, the contact plug CC includes a lower contact plug LCC and an upper contact plug UCC. The lower contact plug LCC and the upper contact plug UCC are sub-plugs of the contact plug CC. Some of the upper contact plugs UCC are provided on the corresponding lower contact plugs LCC. In other words, the contact plug CC has a configuration in which the contact plug CC is formed by being divided into a lower tier T_{LCA} and an upper tier T_{UCA}. That is, the contact plug CC is divisionally processed twice. Note that the contact plug CC may have a configuration of one tier, or may have a configuration of three or more tiers. That is, the contact plug CC may be collectively processed, without being divided, or may be divisionally processed three or more times. The number of tiers (the number of divisions) of the contact plug CC of the present embodiment is different from the number of tiers (the number of divisions) of the memory pillar MP.

The lower contact plug LCC is provided on each terrace of the select gate line SGS and the word lines WL0 to WL4. For example, an upper end of the lower contact plug LCC is located between the interconnect layer 34b functioning as the word line WL4 and the interconnect layer 34c functioning as the word line WL5. In other words, the upper end of the lower contact plug LCC is located at the boundary BDc1 between the lower tier T_{LCA} and upper tier T_{UCA}.

The upper contact plug UCC is provided on the lower contact plug LCC that is provided on each terrace of the select gate line SGS and the word lines WL0 to WL4. In addition, the upper contact plug UCC is provided on each terrace of the word lines WL5 to WL9 and the select gate line SGD. The lower surface of the upper contact plug UCC corresponding to each of the select gate line SGS and the word lines WL0 to WL4 is in contact with the upper surface of the lower contact plug LCC. That is, the boundary BDc1, at which the upper surface of the lower contact plug LCC and the lower surface of the upper contact plug UCC are in contact with each other, is located between the interconnect layer 34b functioning as the word line WL4 and the interconnect layer 34c functioning as the word line WL5. An upper end of the upper contact plug UCC is located above the uppermost interconnect layer 34d that functions as the select gate line SGD.

Each of the lower contact plug LCC and the upper contact plug UCC has, for example, a taper shape with a greater diameter at an upper end than at a lower end thereof. In other words, each of the lower contact plug LCC and the upper contact plug UCC has, for example, a truncated conical shape with a lower surface being smaller than an upper surface thereof. Thus, the boundary BDc1 between the lower contact plug LCC and the upper contact plug UCC can be confirmed by observing the cross-sectional shape.

### 1.2. Boundaries of Memory Pillar, Member SLT, and Support Pillar

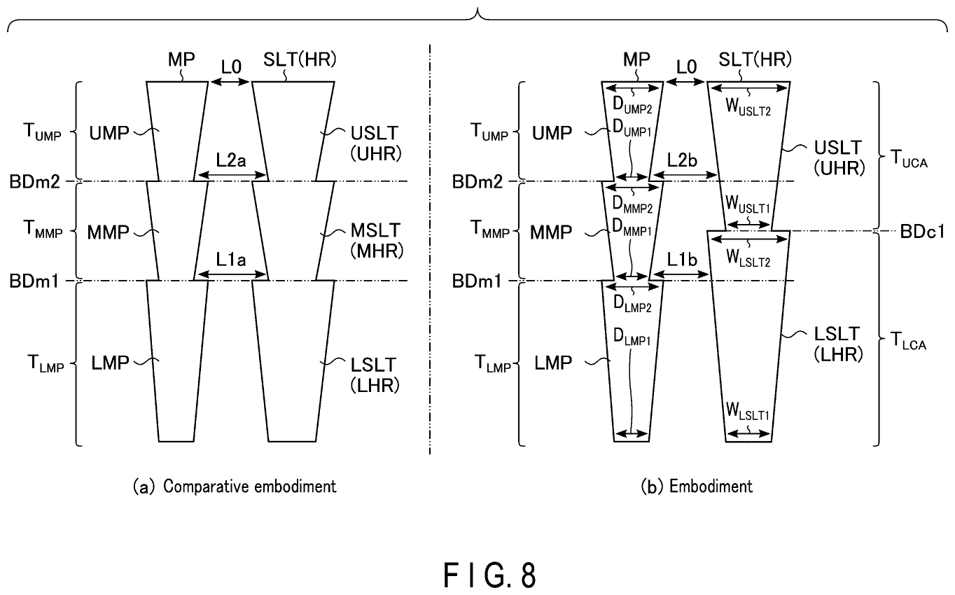

Next, referring to FIG. 8, boundaries of the memory pillar MP, the member SLT, and the support pillar HR are described. FIG. 8 is a conceptual view illustrating boundaries of the memory pillar MP, the member SLT, and the support pillar HR. FIG. 8 illustrates, as a comparative embodiment, a case in which the number of boundaries is equal in regard to the memory pillar MP, the member SLT, and the support pillar HR. Note that the shape and the number of boundaries of the memory pillar MP are equal between the comparative embodiment and an embodiment.

First, the comparative embodiment is described.

As illustrated in part (a) of FIG. 8, for example, in the comparative embodiment, the number of tiers (the number of boundaries) is equal between the memory pillar MP, the member SLT, and the support pillar HR. In this case, the tier boundaries of the memory pillar MP, the member SLT, and the support pillar HR are located between the same interconnect layers 34.

For example, the memory pillar MP includes a lower memory pillar LMP, a middle memory pillar MMP, and an upper memory pillar UMP. The member SLT includes a lower member LSLT, a middle member MSLT, and an upper member USLT. The support pillar HR includes a lower support pillar LHR, a middle support pillar MHR, and an upper support pillar UHR. For example, a boundary BDm1 between the lower memory pillar LMP and the middle memory pillar MMP is equal to a boundary between the lower member LSLT and the middle member MSLT, and to a boundary between the lower support pillar LHR and the middle support pillar MHR.

For example, a distance between the upper end of the memory pillar MP (upper memory pillar UMP) and the upper end of the member SLT (upper member USLT), which neighbor each other, is defined as L0. A distance between the middle memory pillar MMP and the middle member MSLT in the vicinity of the boundary BDm1 is defined as L1a. A distance between the upper memory pillar UMP and the upper member USLT in the vicinity of the boundary BDm2 is defined as L2a. Each of the memory pillar MP, the member SLT, and the support pillar HR has a taper shape at each of the divided parts thereof. Thus, the distance L0 and the distance L1a have a relationship of L0<L1a. Similarly, the distance L0 and the distance L2a have a relationship of L0<L2a.

Next, the embodiment is described.

As illustrated in part (b) of FIG. 8, in the embodiment, the memory pillar MP includes three tiers. Each of the member SLT and the support pillar HR includes two tiers. In other words, the memory pillar MP includes two boundaries BDm1 and BDm2. Each of the member SLT and the support pillar HR includes one boundary BDc1. That is, the number of tiers (the number of boundaries) is different between the memory pillar MP, and the member SLT and the support pillar HR.

In this case, the boundaries BDm1 and BDm2 of the memory pillar MP, and the boundary BDc1 of the member SLT and the support pillar HR, are located at different positions between the interconnect layers 34. More specifically, in the description using FIG. 5 and FIG. 7, the boundary BDm1 is located between the interconnect layer 34a functioning as the word line WL2 and the interconnect layer 34b functioning as the word line WL3. The boundary BDm2 is located between the interconnect layer 34c functioning as the word line WL6 and the interconnect layer 34d functioning as the word line WL7. On the other hand, the boundary BDc1 is located between the interconnect layer 34b functioning as the word line WL4 and the interconnect layer 34c functioning as the word line WL5.

Each of the memory pillar MP, the member SLT, and the support pillar HR has a taper shape at each of the divided parts (each of the tiers) thereof.

More specifically, a diameter D_{LMP1} of the lower end of the lower memory pillar LMP and a diameter D_{LMP2} of the upper end thereof have a relationship of D_{LMP1}<D_{LMP2}. A diameter D_{MMP1} of the lower end of the middle memory pillar MMP and a diameter D_{MMP2} of the upper end thereof have a relationship of D_{MMP1}<D_{MMP2}. A diameter D_{UMP1} of the lower end of the upper memory pillar UMP and a diameter D_{UMP2} of the upper end thereof have a relationship of D_{UMP1}<D_{UMP2}. Furthermore, the diameter D_{LMP2} of the upper end of the lower memory pillar LMP and the diameter D_{MMP1} of the lower end of the middle memory pillar MMP have a relationship of D_{LMP2}>D_{MMP1}. The diameter D_{MMP2} of the upper end of the middle memory pillar MMP and the diameter D_{UMP1} of the lower end of the upper memory pillar UMP have a relationship of D_{MMP2}>D_{UMP1}.

In addition, a width W_{LSLT1} in the Y direction of the lower end of the lower member LSLT and a width W_{LSLT2} in the Y direction of the upper end thereof have a relationship of W_{LSLT1}<W_{LSLT2}. A width W_{USLT1} in the Y direction of the lower end of the upper member USLT and a width W_{USLT2} in the Y direction of the upper end thereof have a relationship of W_{USLT1}<W_{USLT2}. Furthermore, a width W_{LSLT2} in the Y direction of the upper end of the lower member LSLT and a width W_{USLT1} in the Y direction of the lower end of the upper member USLT have a relationship of W_{LSLT2}>W_{USLT1}. The same relationships apply to the support pillar HR.

For example, a distance between the upper end of the memory pillar MP (upper memory pillar UMP) and the upper end of the member SLT (upper member USLT), which neighbor each other, is defined as L0 that is identical to the comparative embodiment of part (a) of FIG. 8. A distance between the memory pillar MP and the member SLT at the boundary BDm1 is defined as L1b. A distance between the memory pillar MP and the member SLT at the boundary BDm2 is defined as L2b. The distance L0 and the distance L1b have a relationship of L0<L1b. Similarly, the distance L0 and the distance L2b have a relationship of L0<L2b.

In the case of the comparative embodiment of part (a) of FIG. 8, for example, the width of the middle member MSLT is smallest at the boundary BDm1. On the other hand, in the case of the embodiment of part (b), the boundary BDm1 is located at an intermediate portion of the lower member LSLT. Accordingly, the distance L1a and the distance L1b, if compared, have a relationship of L1a>L1b. Similarly, in the case of the comparative embodiment of part (a), the width of the upper member USLT is smallest at the boundary BDm2. On the other hand, in the case of the embodiment of part (b), the boundary BDm2 is located at an intermediate portion of the upper member USLT. Accordingly, the distance L2a and the distance L2b, if compared, have a relationship of L2a>L2b. The same relationship applies to the relationship between the memory pillar MP and the support pillar HR.

Therefore, in the case of the configuration according to the present embodiment, it is possible to suppress an increase in distance between the memory pillar MP and the member SLT due to the taper shape. In other words, it is possible to suppress an increase in distance between the memory pillar MP and the member SLT by providing the boundary position of the memory pillar MP and the boundary position of the member SLT between mutually different interconnect layers 34. The same applies to the support pillar HR. It is possible to suppress an increase in distance between the memory pillar MP and the support pillar HR by providing the boundary position of the memory pillar MP and the boundary position of the support pillar HR between mutually different interconnect layers 34. Thereby, for example, bending of the layer stack due to the WL replace can be suppressed.

### 1.3. Manufacturing Method of Memory Cell Array

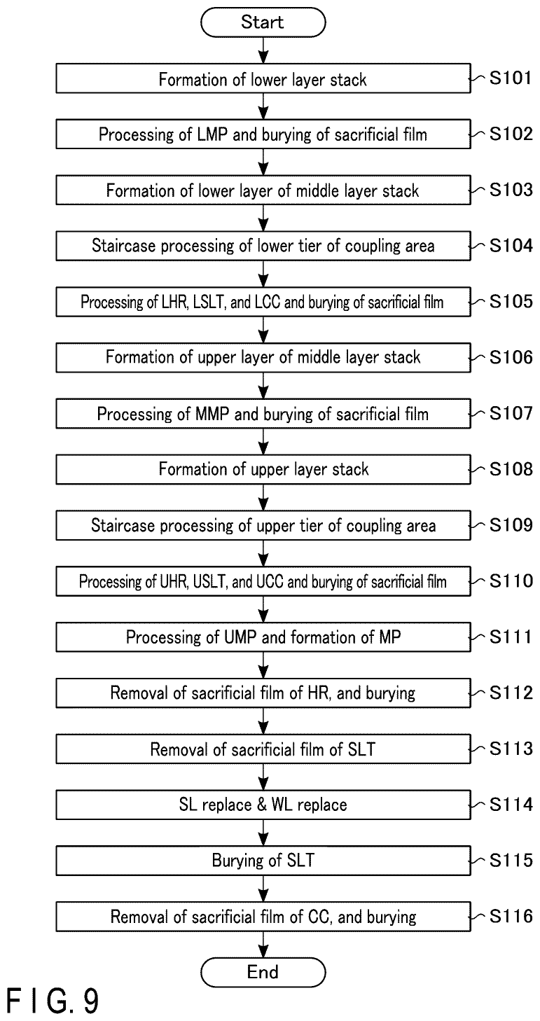

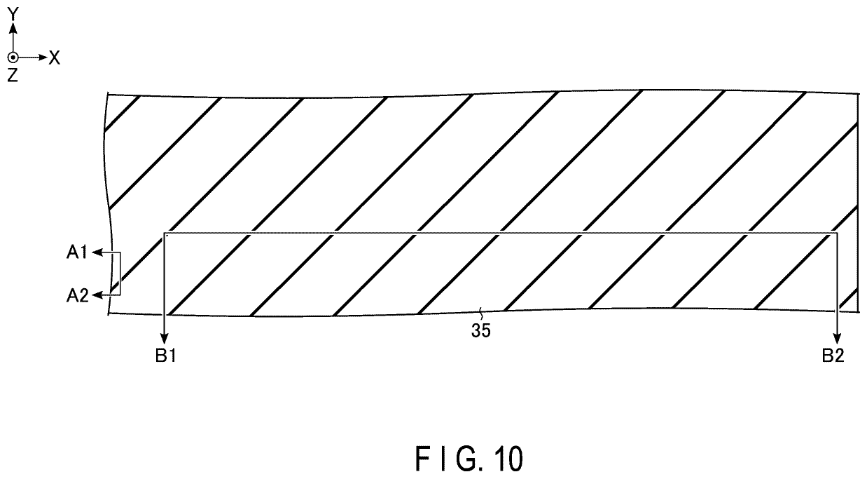

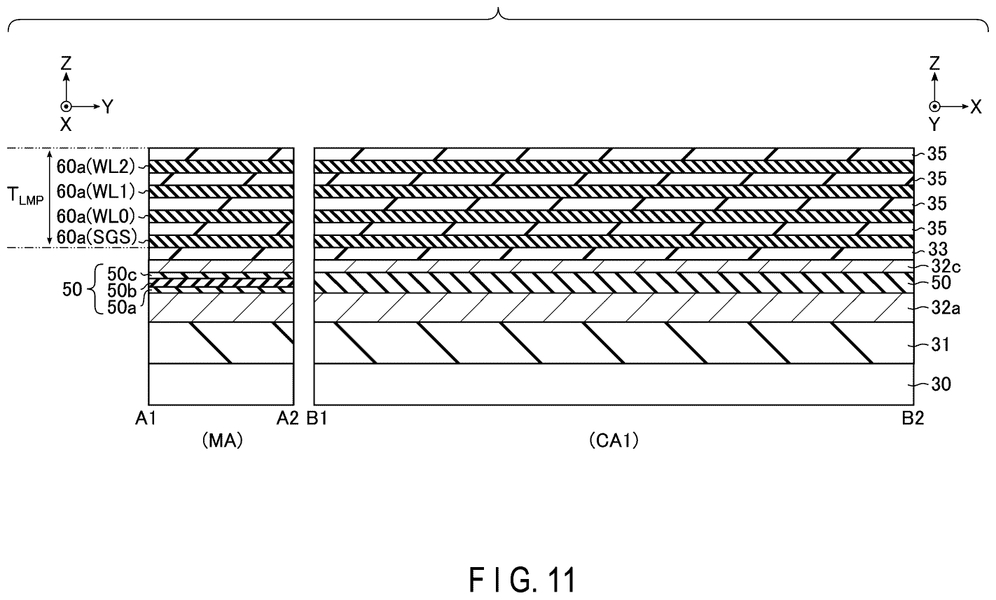

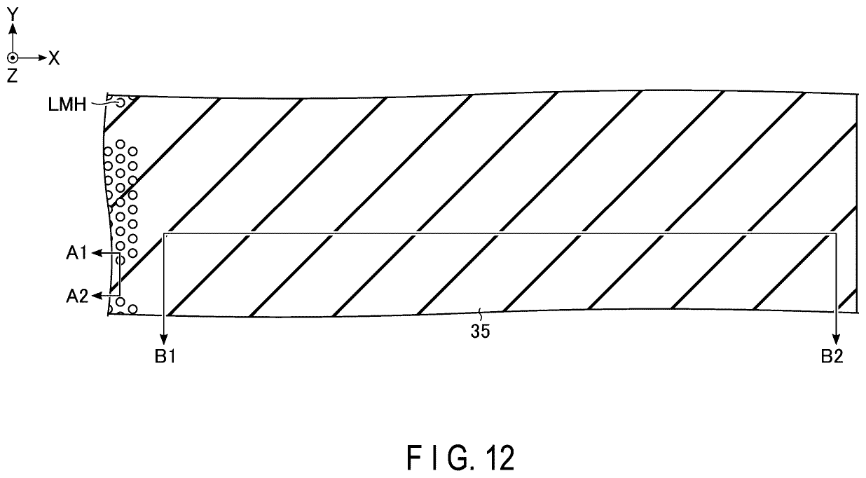

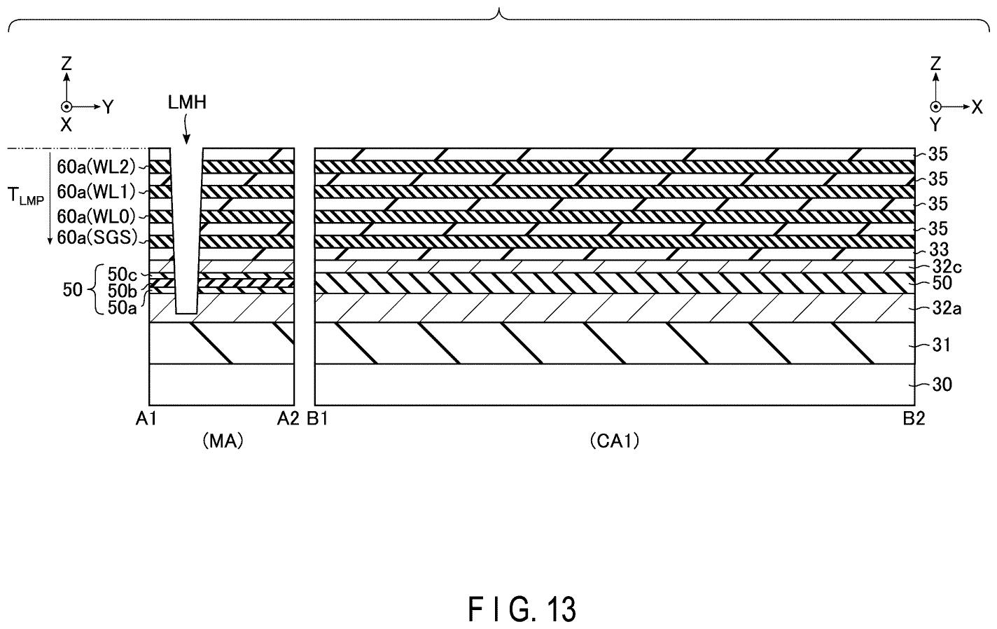

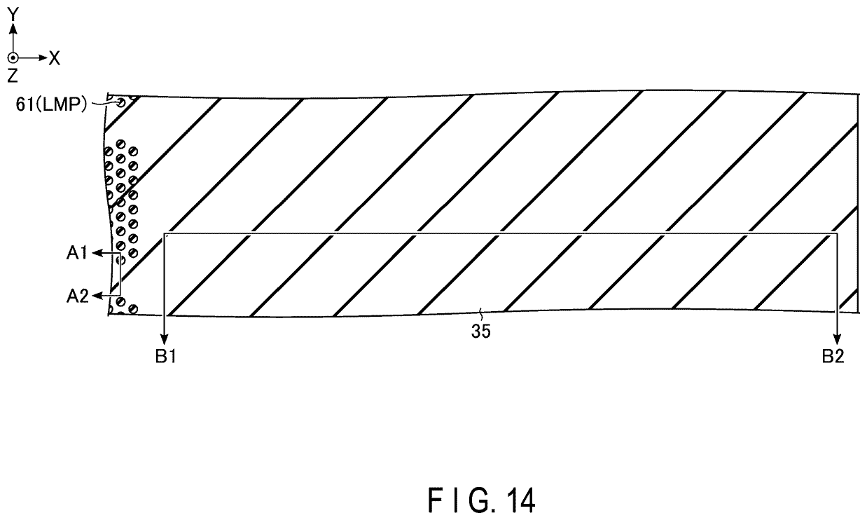

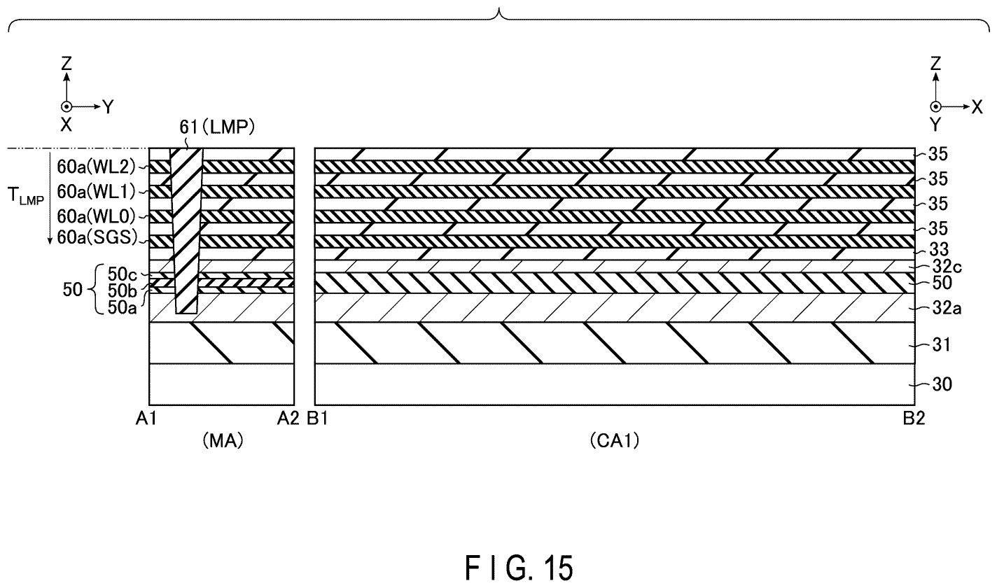

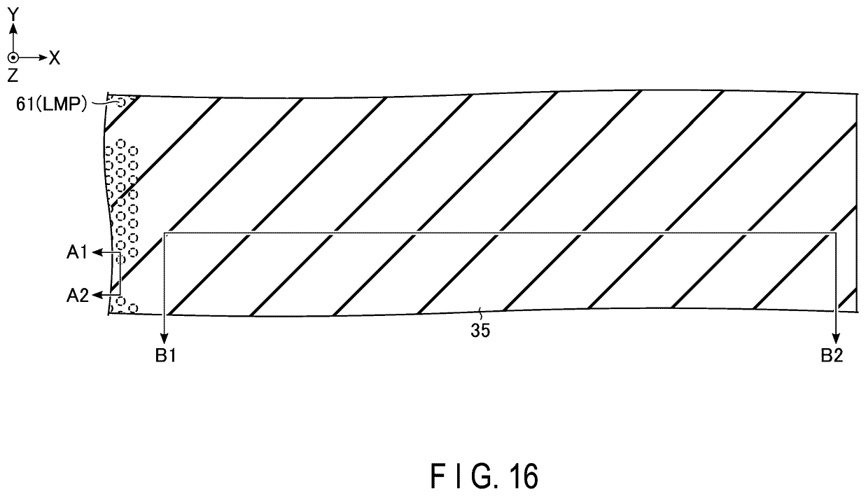

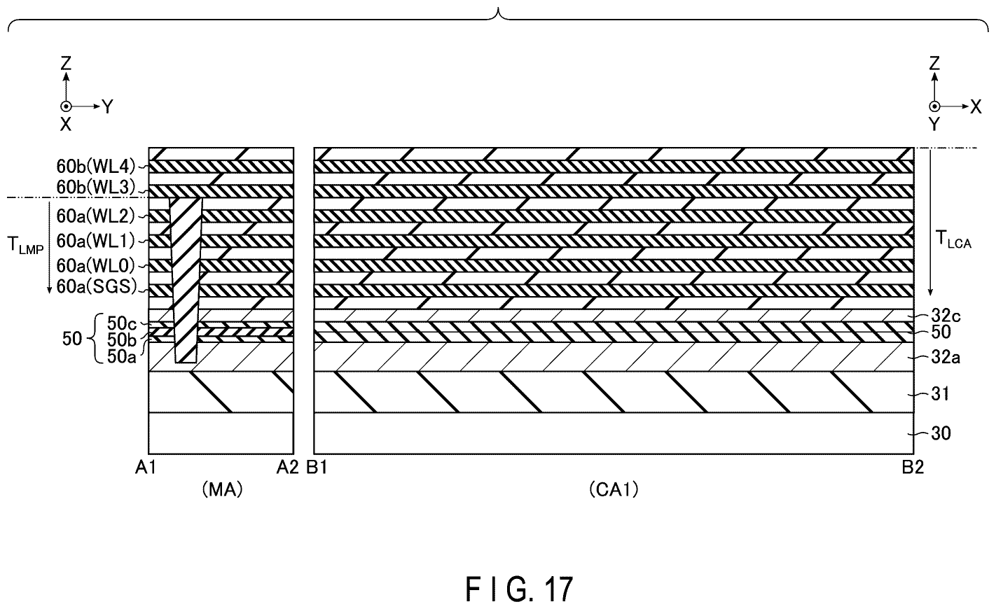

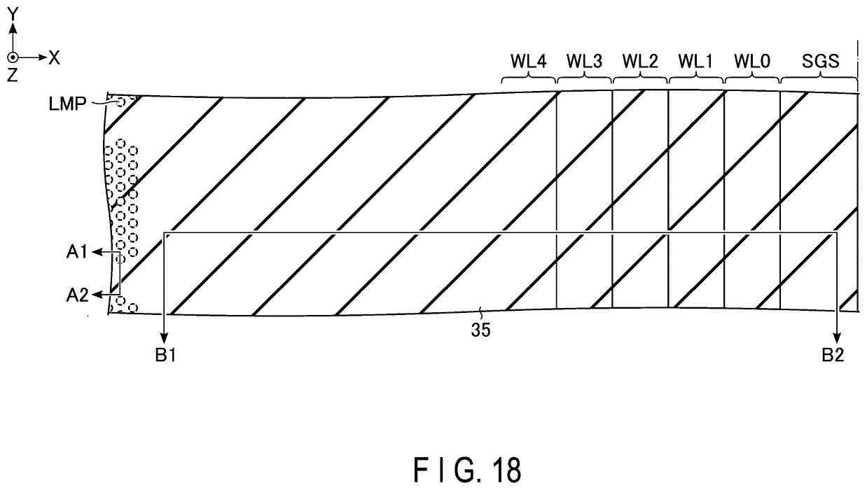

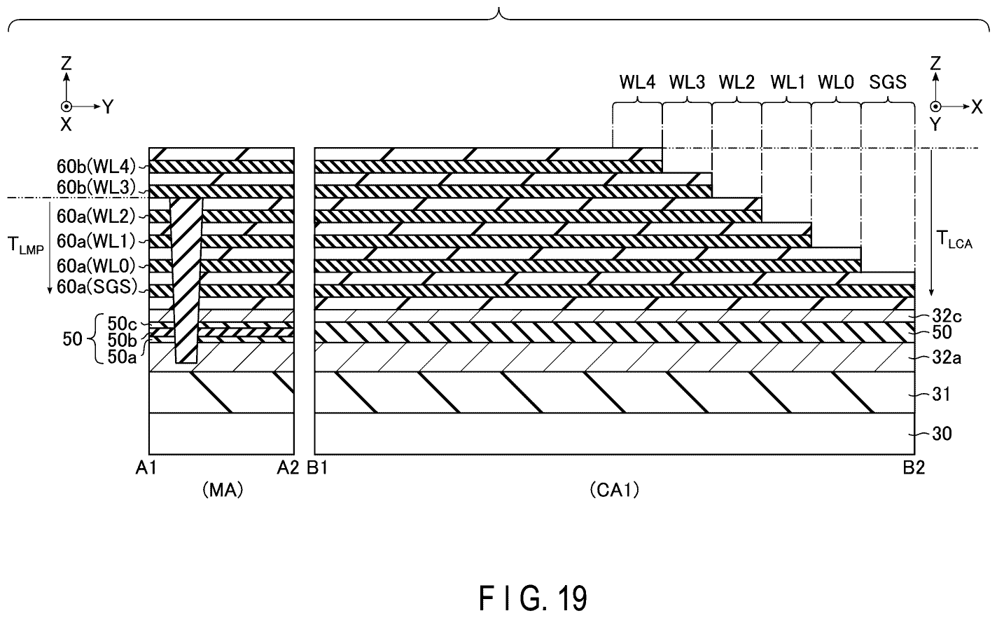

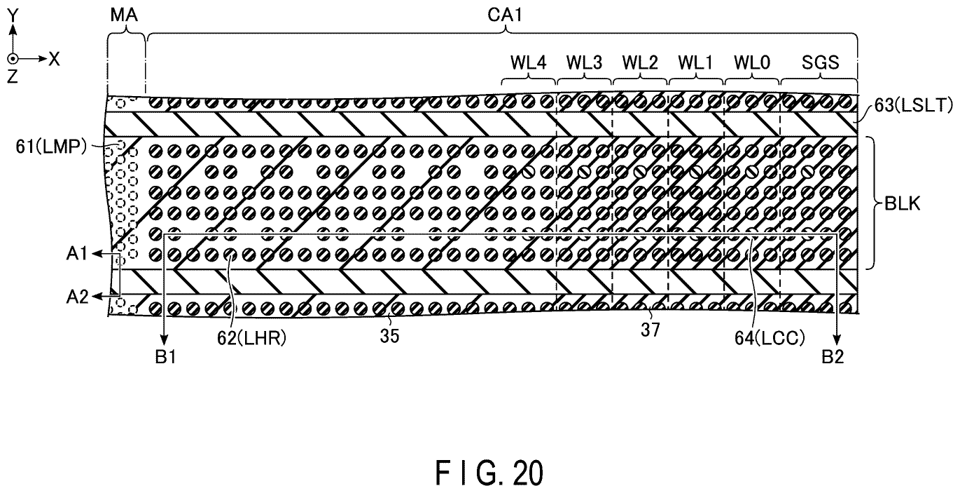

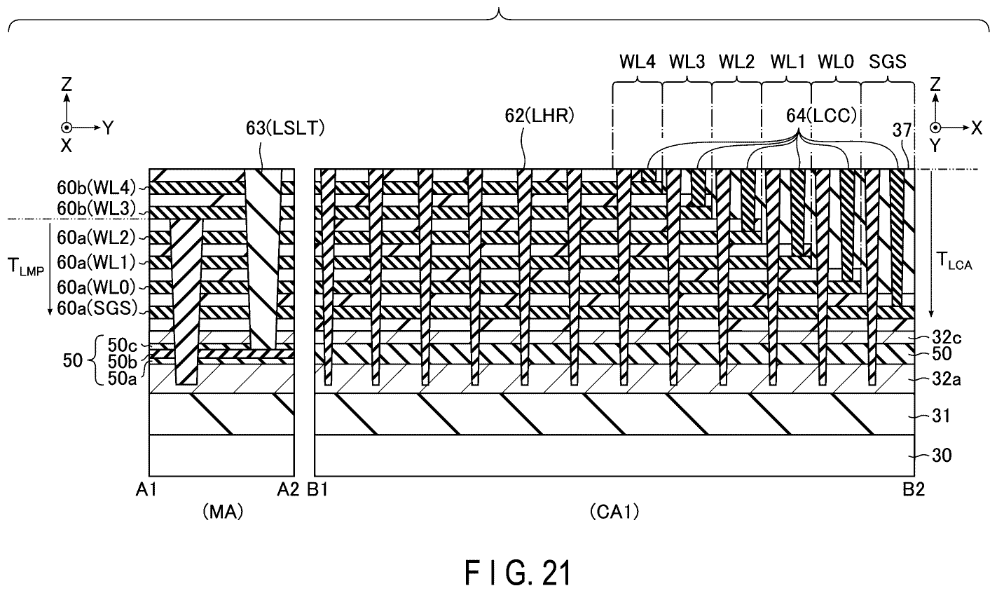

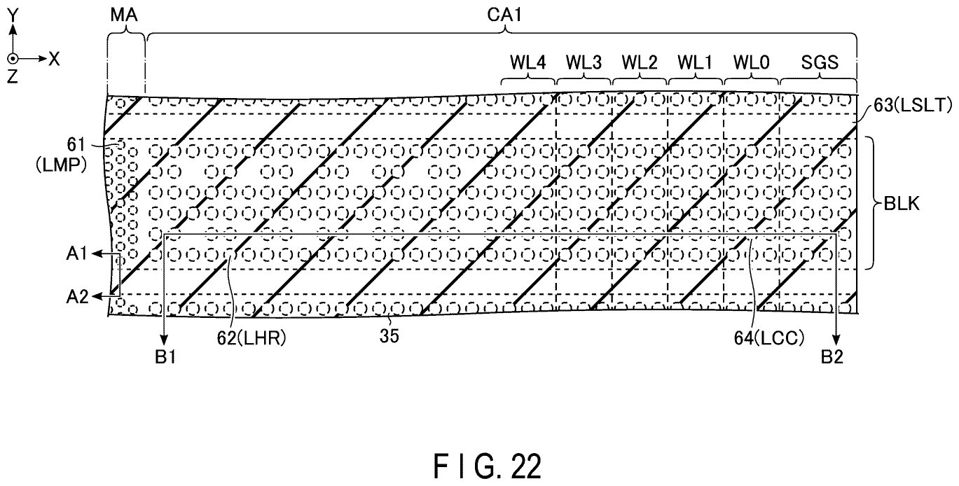

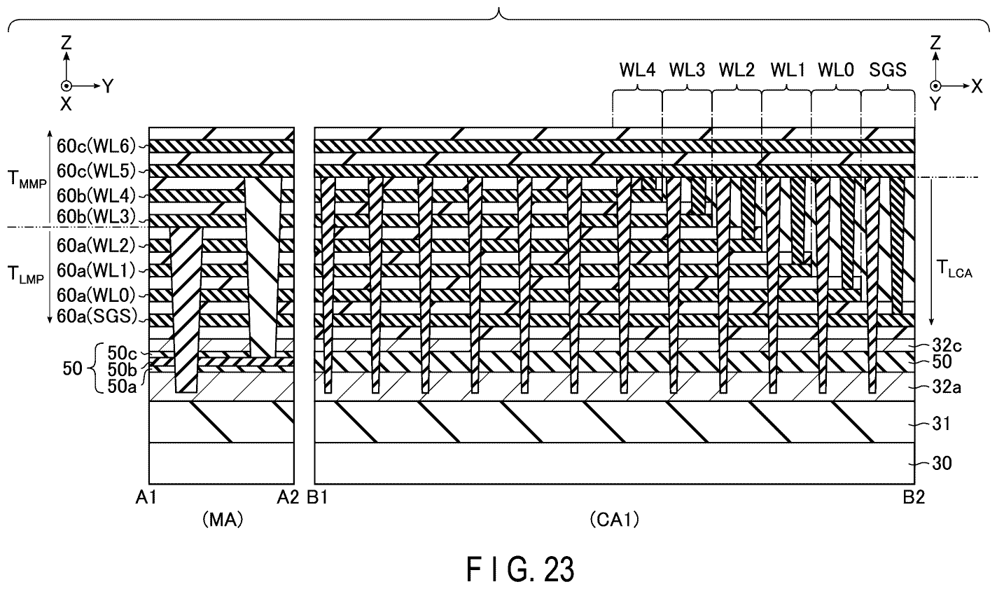

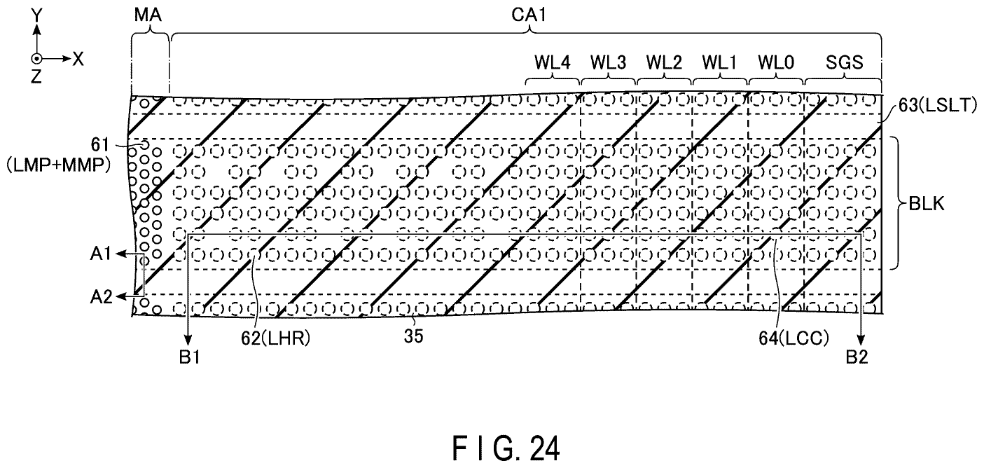

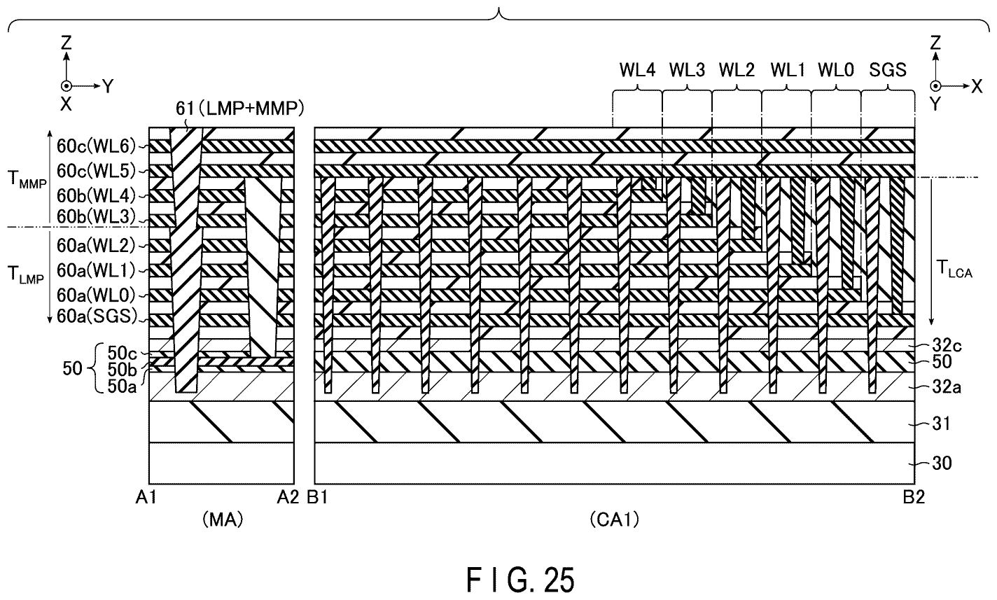

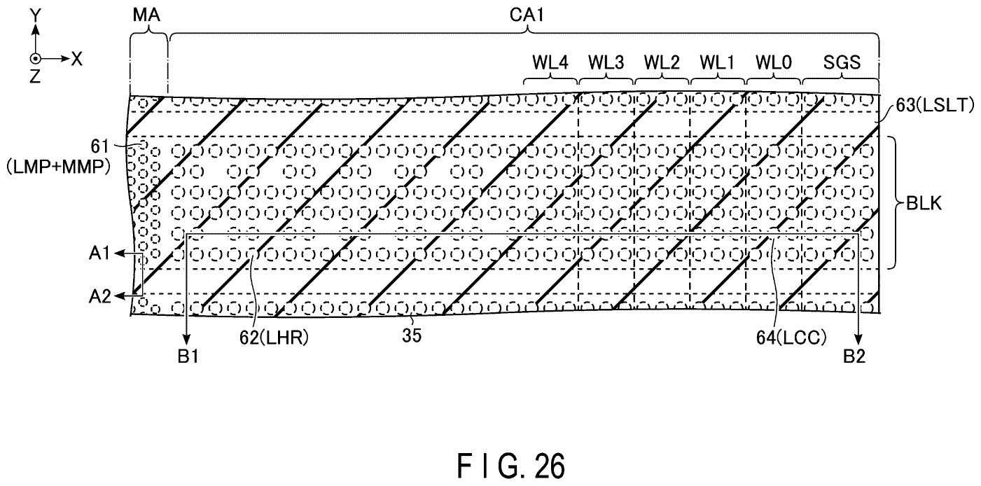

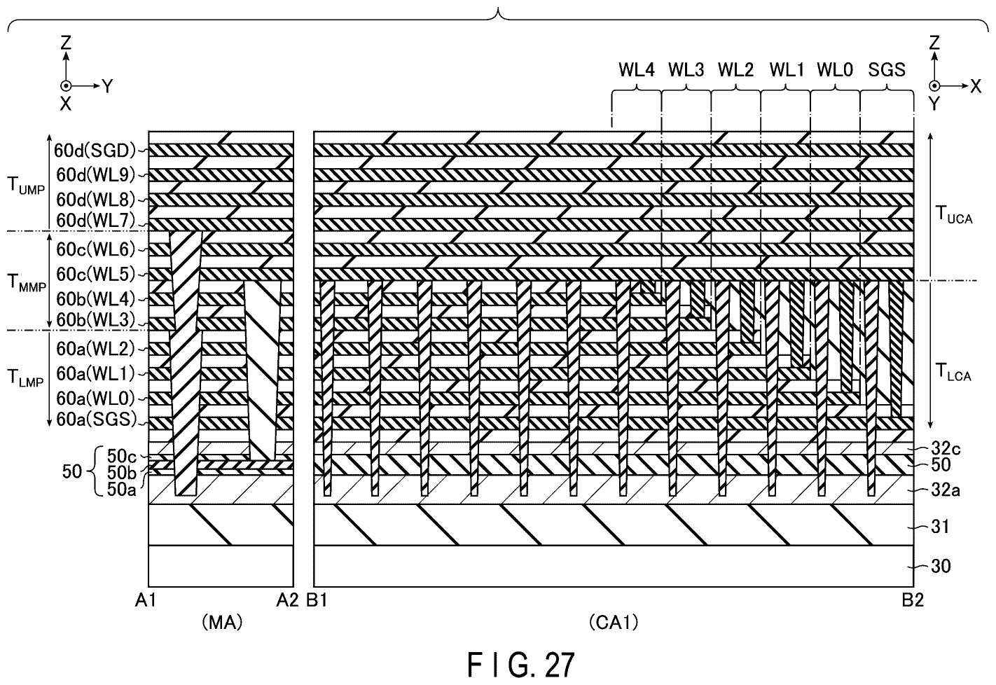

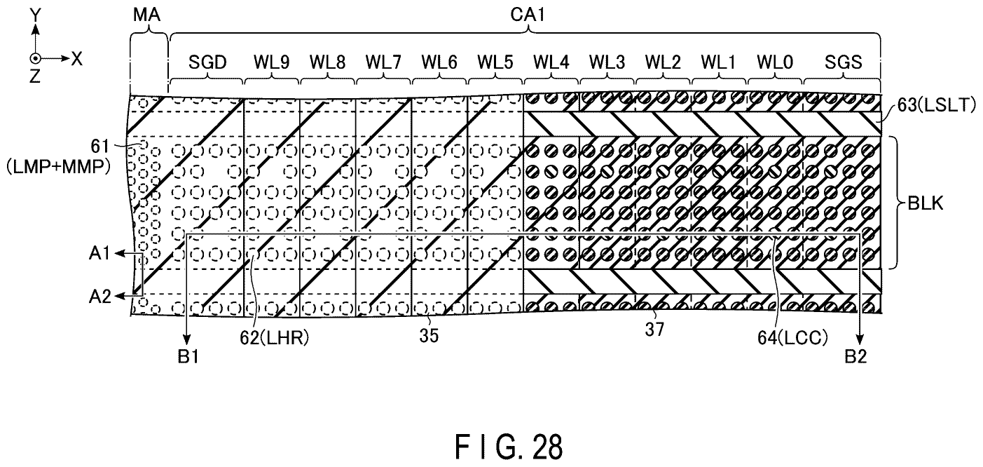

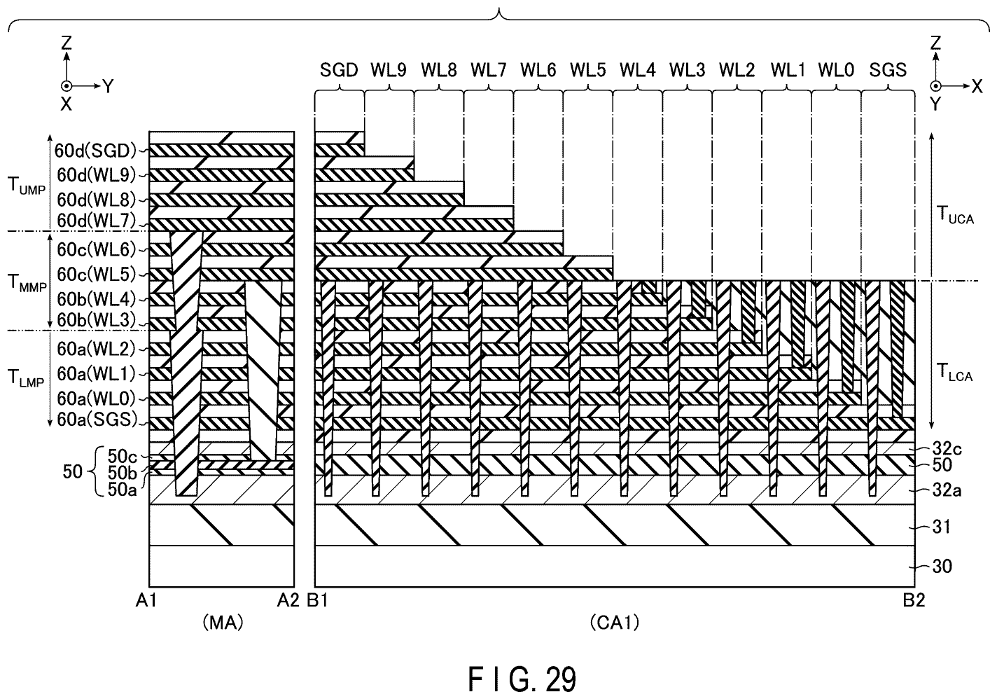

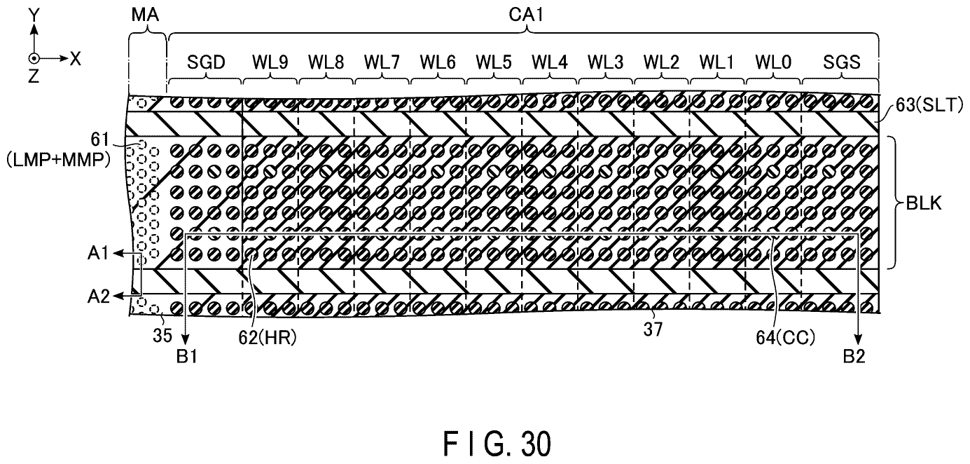

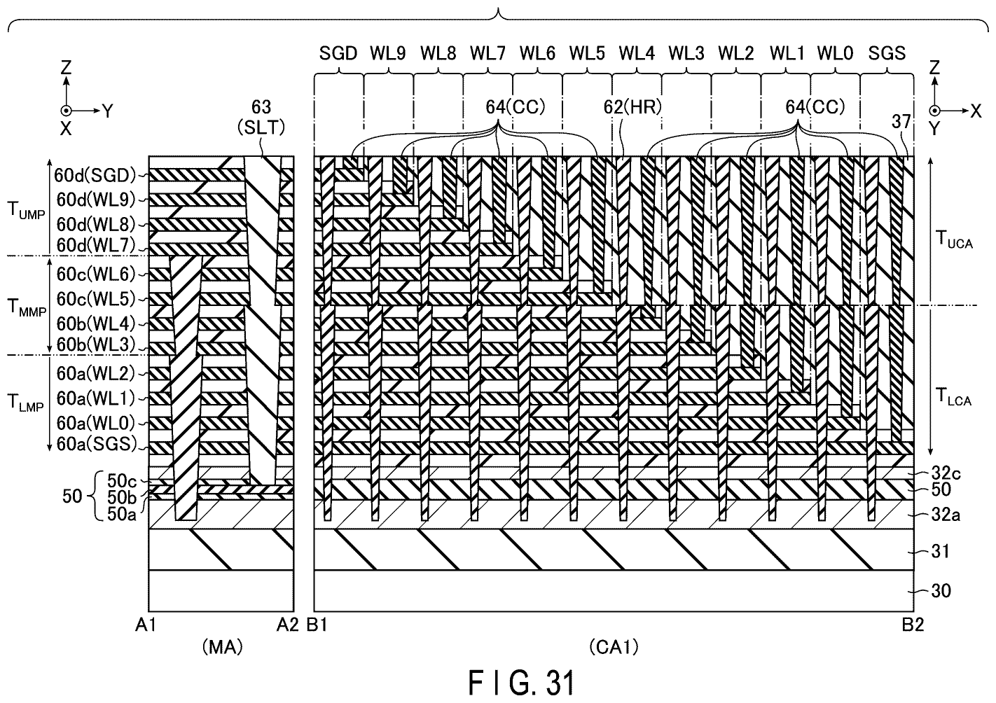

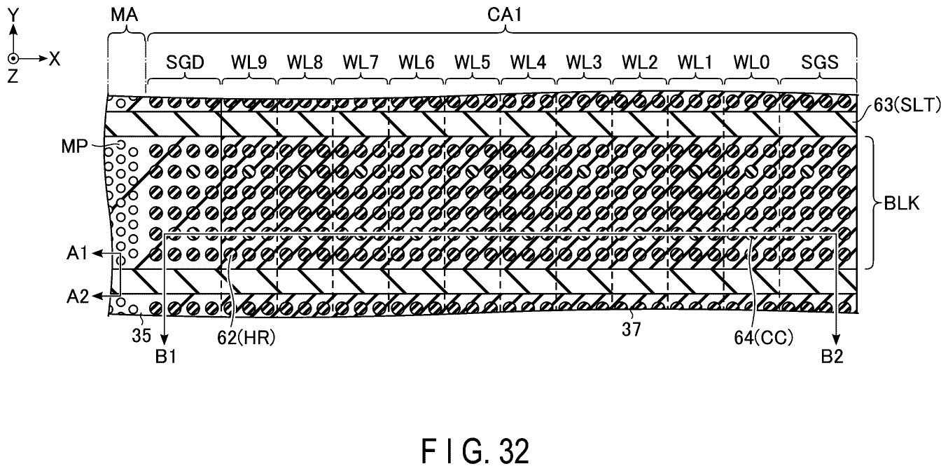

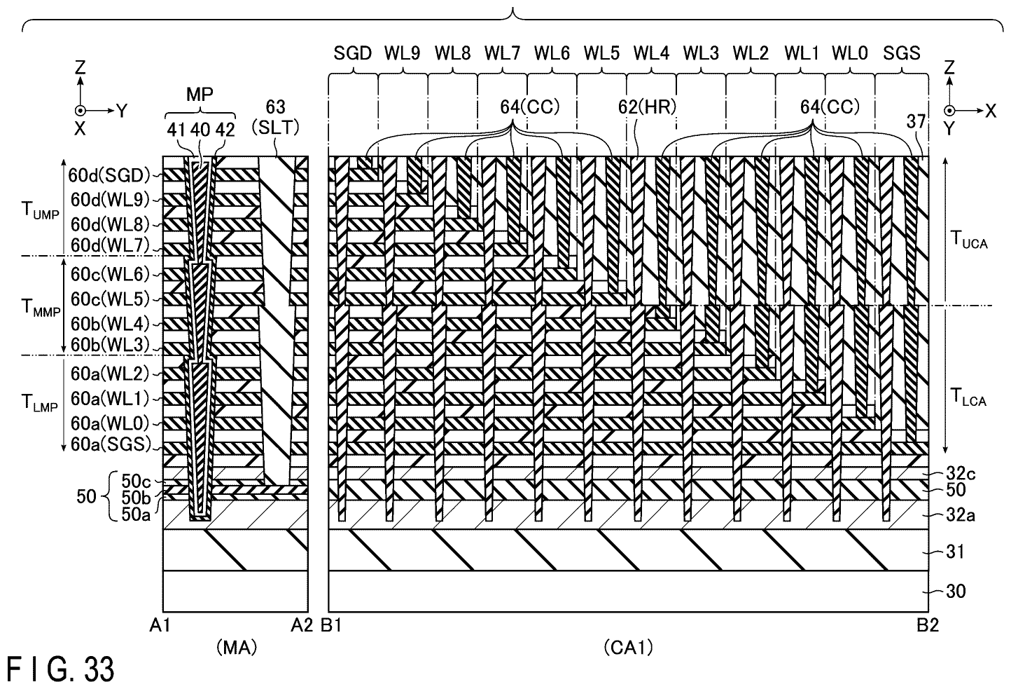

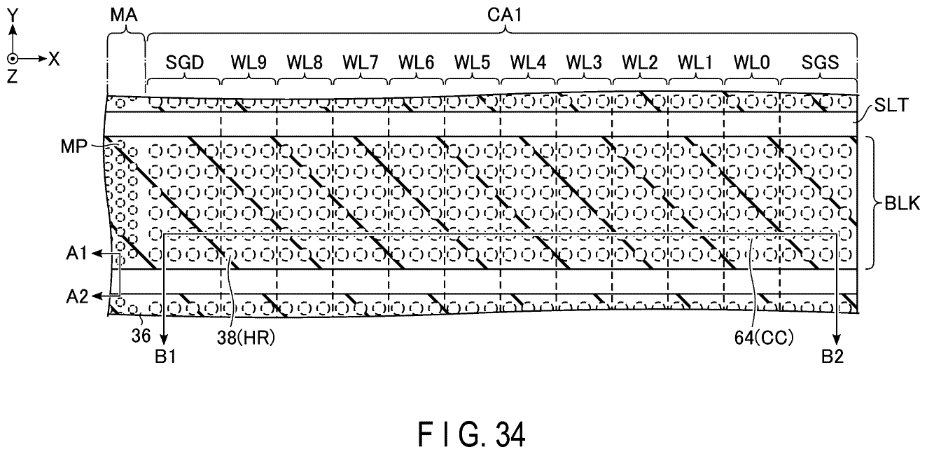

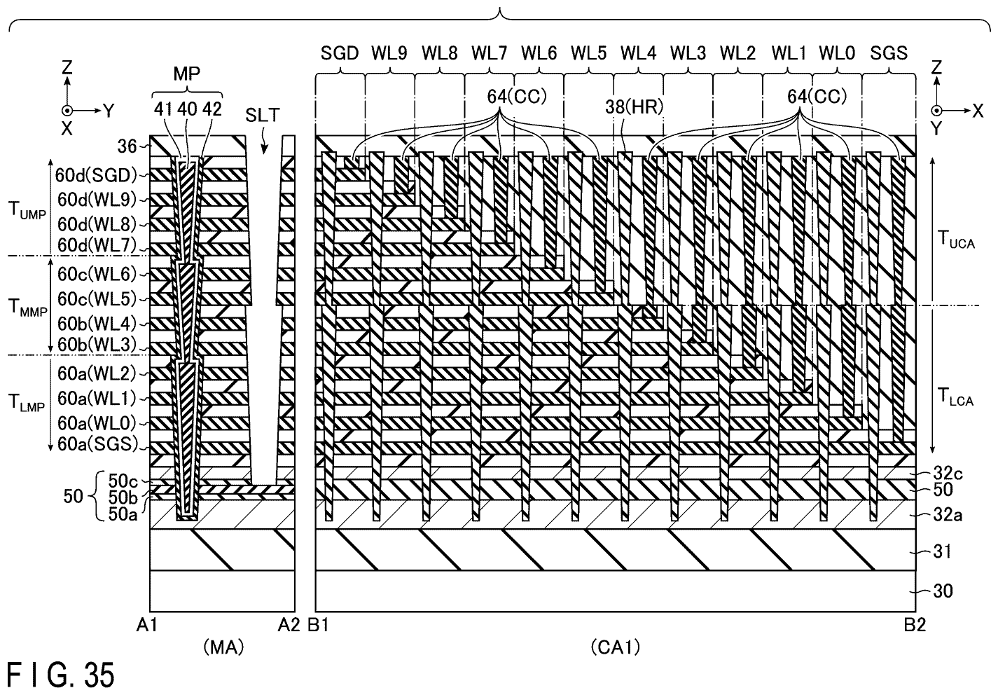

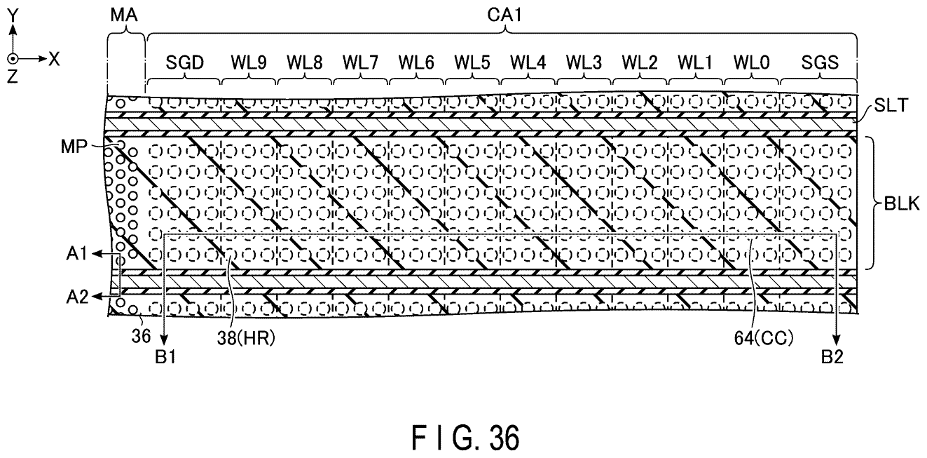

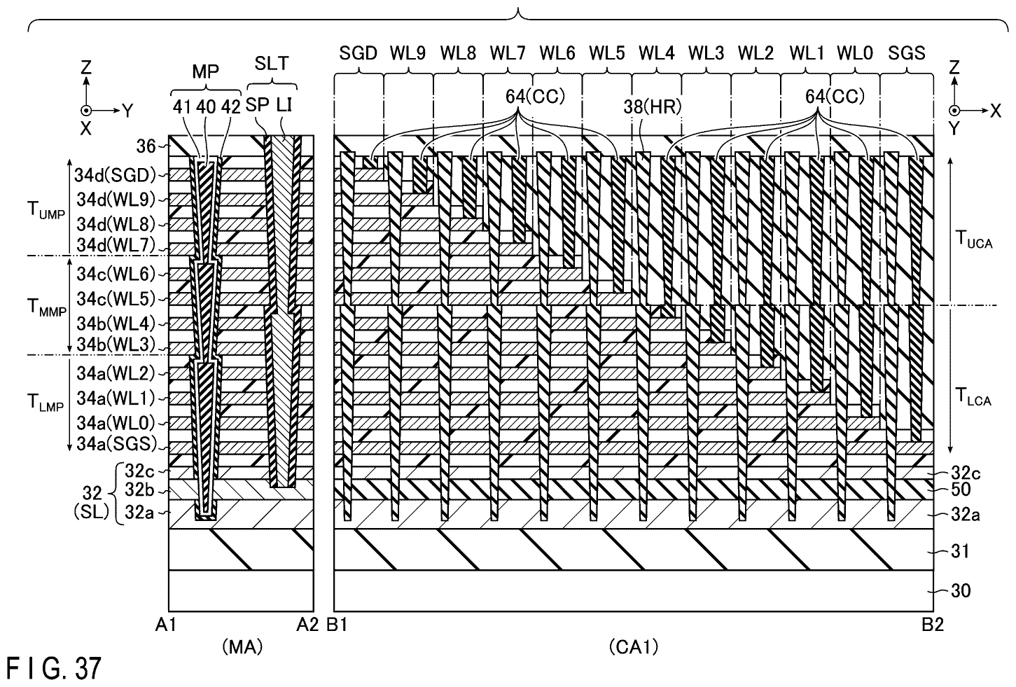

Next, referring to FIG. 9 to FIG. 37, an example of a manufacturing method of the memory cell array 11 is described. FIG. 9 is a flowchart illustrating an example of a manufacturing process of the memory cell array 11. FIG. 10, FIG. 12, FIG. 14, FIG. 16, FIG. 18, FIG. 20, FIG. 22, FIG. 24, FIG. 26, FIG. 28, FIG. 30, FIG. 32, FIG. 34, and FIG. 36 illustrate examples of planar layouts of the memory cell array 11 in the manufacturing process of the memory cell array 11. FIG. 11 is a cross-sectional view along line A1-A2 and line B1-B2 in FIG. 10. FIG. 13 is a cross-sectional view along line A1-A2 and line B1-B2 in FIG. 12. FIG. 15 is a cross-sectional view along line A1-A2 and line B1-B2 in FIG. 14. FIG. 17 is a cross-sectional view along line A1-A2 and line B1-B2 in FIG. 16. FIG. 19 is a cross-sectional view along line A1-A2 and line B1-B2 in FIG. 18. FIG. 21 is a cross-sectional view along line A1-A2 and line B1-B2 in FIG. 20. FIG. 23 is a cross-sectional view along line A1-A2 and line B1-B2 in FIG. 22. FIG. 25 is a cross-sectional view along line A1-A2 and line B1-B2 in FIG. 24. FIG. 27 is a cross-sectional view along line A1-A2 and line B1-B2 in FIG. 26. FIG. 29 is a cross-sectional view along line A1-A2 and line B1-B2 in FIG. 28. FIG. 31 is a cross-sectional view along line A1-A2 and line B1-B2 in FIG. 30. FIG. 33 is a cross-sectional view along line A1-A2 and line B1-B2 in FIG. 32. FIG. 35 is a cross-sectional view along line A1-A2 and line B1-B2 in FIG. 34. FIG. 37 is a cross-sectional view along line A1-A2 and line B1-B2 in FIG. 36. Note that the sizes of the memory pillar MP, the member SLT, the support pillar HR, and the contact plug CC in each cross-sectional view are arbitrary. Note that in the cross-sectional views of the manufacturing process to be described below, the depiction of some support pillars HR passing through terraces is omitted in order to make the drawings simpler.

As illustrated in FIG. 9, at first, a lower layer stack is formed (S101).

As illustrated in FIG. 10 and FIG. 11, more specifically, an insulating layer 31 is first formed on a semiconductor substrate 30. A semiconductor layer 32a is formed on the insulating layer 31. An insulating layer 50 is formed on the semiconductor layer 32a. The insulating layer 50 includes, for example, three insulating layers 50a, 50b, and 50c. For example, the insulating layers 50a and 50c include silicon oxide. The insulating layer 50b includes silicon nitride. Note that the insulating layer 50b is formed in the memory cell area MA in which the replace (SL replace) of the insulating layer 50 is executed in a later step, and is not formed in the coupling area CA in which the replace is not executed. A semiconductor layer 32c is formed on the insulating layer 50. An insulating layer 33 is formed on the semiconductor layer 32c. As a lower layer stack before the WL replace, four sacrificial films 60a and four insulating layers 35 are alternately stacked one by one on the insulating layer 33. The four sacrificial films 60a correspond to the lower tier T_{LMP}, and are, in the WL replace, replaced with four interconnect layers 34a functioning as the select gate line SGS and the word lines WL0 to WL2, respectively. For example, silicon nitride is used for the sacrificial films 60a.

As illustrated in FIG. 9, after step S101 is executed, memory holes LMH corresponding to lower memory pillars LMP are processed (formed), and the memory holes LMH are filled with a sacrificial film 61 (S102).

As illustrated in FIG. 12 and FIG. 13, in the memory cell area MA, the memory holes LMH corresponding to the lower memory pillars LMP are formed. Each memory holes LMH has a taper shape, and a lower end of each memory hole LMH reaches the semiconductor layer 32a.

Subsequently, as illustrated in FIG. 14 and FIG. 15, a sacrificial film 61 is buried in the memory hole LMH. The sacrificial film 61 may include carbon, or may include silicon, or may be a metallic material.

As illustrated in FIG. 9, after step S102 is executed, lower layers of the middle layer stack are formed (S103).

As illustrated in FIG. 16 and FIG. 17, as lower layers of the middle layer stack before the WL replace, two sacrificial films 60b and two insulating layers 35 are alternately stacked one by one on the lower layer stack. The two sacrificial films 60b are, in the WL replace, replaced with two interconnect layers 34b functioning as the word lines WL3 and WL4, respectively. For example, silicon nitride is used for the sacrificial films 60b.

As illustrated in FIG. 9, after step S103 is executed, a staircase part corresponding to the lower tier T_{LCA} of the coupling area CA is formed (S104).

As illustrated in FIG. 18 and FIG. 19, staircase processing is performed on the lower layer stack and the lower layers of the middle layer stack, and terraces corresponding to the sacrificial films 60a and 60b are formed. In the example illustrated in FIG. 19, the terraces corresponding to the select gate line SGS and the word lines WL0 to WL3 are processed.

As illustrated in FIG. 9, after step S104 is executed, processing of the lower support pillars LHR and burying by a sacrificial film 62, processing of the lower members LSLT and burying by a sacrificial film 63, and processing of the lower contact plugs LCC and burying by a sacrificial film 64, are successively executed (S105). Note that the order of the processing of the lower support pillars LHR, the lower members LSLT, and the lower contact plugs LCC and the burying by the sacrificial films 62 to 64 is arbitrary.

As illustrated in FIG. 20 and FIG. 21, the staircase part is filled with the insulating layer 37, and is planarized by, for example, chemical mechanical polishing (CMP). Next, in the coupling area CA, holes corresponding to the lower support pillars LHR are formed, and a sacrificial film 62 is buried in the holes. For example, a lower end of each hole corresponding to the lower support pillar LHR reaches the semiconductor layer 32a. Next, slits corresponding to the lower members LSLT are formed, and a sacrificial film 63 is buried in the slits. A lower end of each slit corresponding to the lower member LSLT reaches the insulating layer 50. Next, in the coupling area CA, holes corresponding to the lower contact plugs LCC are formed, and a sacrificial film 64 is buried in the holes. A lower end of each lower contact plug LCC is in contact with the terrace of the corresponding sacrificial film 60 (interconnect layer 34). Note that the lower contact plugs LCC are provided on the terraces of the select gate line SGS and the word lines WL0 to WL4, and are not provided at positions corresponding to the terraces of the word lines WL5 to WL9 and the select gate line SGD. For example, the sacrificial films 62 to 64 may include carbon, or may include silicon, or may be a metallic material. In addition, the sacrificial films 62 to 64 may be the same material or may be mutually different materials.

As illustrated in FIG. 9, after step S105 is executed, upper layers of the middle layer stack are formed (S106).

As illustrated in FIG. 22 and FIG. 23, two sacrificial films 60c and two insulating layers 35 are alternately stacked one by one as upper layers of the middle layer stack before the WL replace, on the lower layers of the middle layer stack. In the WL replace, the two sacrificial films 60c are replaced with two interconnect layers 34c that function as the word lines WL5 and WL6, respectively. For example, silicon nitride is used for the sacrificial films 60c.

As illustrated in FIG. 9, after step S106 is executed, memory holes corresponding to the middle memory pillars MMP are processed (formed), and a sacrificial film 61 is buried in the memory holes (S107).

As illustrated in FIG. 24 and FIG. 25, in the memory cell area MA, the memory holes corresponding to the middle memory pillars MMP are formed. A lower end of each memory hole corresponding to the middle memory pillar MMP reaches the lower memory pillar LMP. Next, a sacrificial film 61 is buried in the memory holes corresponding to the middle memory pillars MMP. In other words, a stacked structure of the lower memory pillar LMP and middle memory pillar MMP, which are filled with the sacrificial film 61, is formed.

As illustrated in FIG. 9, after step S107 is executed, an upper layer stack is formed (S108).

As illustrated in FIG. 26 and FIG. 27, four sacrificial films 60d and four insulating layers 35 are alternately stacked one by one on the upper layers of the middle layer stack, as an upper layer stack before WL replace. In the WL replace, the four sacrificial films 60d are replaced with four interconnect layers 34d functioning as the word lines WL7 to WL9 and the select gate line SGD. For example, silicon nitride is used for the sacrificial films 60d.

As illustrated in FIG. 9, after step S108 is executed, a staircase part corresponding to the upper tier T_{UCA} of the coupling area CA is formed (S109).

As illustrated in FIG. 28 and FIG. 29, staircase processing is performed on the upper layers of the middle layer stack and the upper layer stack, thereby forming terraces corresponding to the sacrificial films 60c and 60d. In the example illustrated in FIG. 29, the terraces corresponding to the word lines WL4 to WL9 are processed.

As illustrated in FIG. 9, after step S109 is executed, processing of the upper pillars UHR and burying by a sacrificial film 62, processing of the upper members USLT and burying by a sacrificial film 63, and processing of the upper contact plugs UCC and burying by a sacrificial film 64, are successively executed (S110). Note that the order of the processing of the upper support pillars UHR, the upper members USLT, and the upper contact plugs UCC and the burying by the sacrificial films 62 to 64 is arbitrary.

As illustrated in FIG. 30 and FIG. 31, an insulating layer 37 is buried in the staircase part, and is planarized by, for example, CMP. Next, in the coupling area CA, holes corresponding to the upper support pillars UHR are formed, and a sacrificial film 62 is buried in the holes. Thereby, the support pillars HR filled with the sacrificial film 62 are formed. Next, slits corresponding to the upper members USLT are formed, and a sacrificial film 63 is buried in the slits. Thereby, the members SLT filled with the sacrificial film 63 are formed. Next, in the coupling area CA, holes corresponding to the upper contact plugs UCC are formed, and a sacrificial film 64 is buried in the holes. Thereby, the contact plugs CC filled with the sacrificial film 64 are formed.

As illustrated in FIG. 9, after step S110 is executed, memory holes corresponding to the upper memory pillars UMP are processed (formed), and the memory pillars MP are formed (S111).

As illustrated in FIG. 32 and FIG. 33, in the memory cell area MA, the memory holes corresponding to the upper memory pillars UMP are formed. A lower end of each memory hole corresponding to the upper memory pillar UMP reaches the middle memory pillar MMP. Next, the sacrificial films 61 in the memory hole are removed. Subsequently, a stacked film 42, a semiconductor film 41, and a core film 40 are formed and filled in the memory holes, thus forming the memory pillars MP.

As illustrated in FIG. 9, after step S111 is executed, the sacrificial films 62 in the support pillars HR are removed, and an insulator 38 is buried in the holes (S112).

After step S112 is executed, the sacrificial films 63 in the members SLT are removed (S113).

As illustrated in FIG. 34 and FIG. 35, the sacrificial films 62 in the support pillars HR are removed, and an insulator 38 is buried therein. After an insulating layer 36 is formed, the members SLT are opened, and the sacrificial films 63 in the members SLT are removed.

As illustrated in FIG. 9, after step S113 is executed, SL replace and WL replace are successively executed (S114).

After step S114 is executed, a spacer SP and a conductor LI are buried in the member SLT (S115).

As illustrated in FIG. 36 and FIG. 37, for example, after an insulating film is formed on a side surface of the slit corresponding to the member SLT, the SL replace is executed to replace the insulating layer 50 (50a, 50b, 50c) of the memory cell area MA with a semiconductor layer 32b. At this time, in the memory pillar MP, the stacked layer 42 that is in the same layer as the semiconductor layer 32b is removed. More specifically, by wet etching, the insulating layer 50b is removed from the side surface of the slit corresponding to the member SLT. Next, by wet etching, the insulating layers 50a and 50c are removed from the side surface of the slit corresponding to the member SLT. Thereby, in the memory cell area MA in which the insulating layer 50b is formed, the insulating layer 50 (50a, 50b, 50c) is removed. At this time, the stacked film 42 located in the same layer as the insulating layer 50 is removed at the same time. Next, a semiconductor layer 32b is buried in the area from which the insulating layer 50 is removed. Subsequently, the semiconductor layer 32b is formed between the semiconductor layers 32a and 32c by removing the excess semiconductor layer 32b on the side surface of the slit corresponding to the member SLT and on the insulating layer 36.

Next, the WL replace is executed. More specifically, at first, the insulating layer provided on the side surface of the slit corresponding to the member SLT is removed. Next, by wet etching, the sacrificial films 60 (60a to 60d) are removed from the side surface of the slit corresponding to the member SLT. Next, interconnect layers 34 (34a to 34d) are formed.

Next, a spacer SP and a conductor LI are formed in the member SLT.

As illustrated in FIG. 9, after step S115 is executed, the sacrificial films 64 in the contact plugs CC are removed, and a conductor 39 is buried in the holes (S116). Thereby, the configuration of the memory cell array 11, which was described with reference to FIG. 5, FIG. 7 and FIG. 8, is formed.

### 1.4. Advantageous Effects According to Present Embodiment

With the configuration according to the present embodiment, the semiconductor memory device 1 can reduce the manufacturing cost. This advantageous effect is described in detail.

For example, in the three-dimensional stack-type NAND flash memory, with the increase in the number of stacked layers of word lines WL, the degree of difficulty in processing is increasing in regard to the memory pillar MP, the member SLT, the support pillar HR, and the contact plug CC. Thus, there is a case where the memory pillar MP, the member SLT, the support pillar HR, and the contact plug CC are processed by being divided into a plurality of tiers, respectively. In this case, the number of tiers is set to be equal for the memory pillar MP, the member SLT, the support pillar HR, and the contact plug CC. However, the degree of difficulty in processing is different between the memory pillar MP, the member SLT, the support pillar HR, and the contact plug CC. A desirable number of tiers varies depending on the degree of difficulty in processing. For example, if the number of tiers is set in accordance with the memory pillar MP, there is a case where the number of tiers (the number of times of processing) of the member SLT, the support pillar HR, and the contact plug CC is different from the desirable number of tiers. For example, if the set number of tiers is greater than the desirable number of tiers, the number of processes of the memory cell array and the manufacturing cost increase.

On the other hand, with the configuration according to the present embodiment, the number of tiers of the memory pillar MP can be set to be different from the number of tiers of the member SLT, the support pillar HR, and the contact plug CC. In addition, the position of a boundary corresponding to the tier of the memory pillar MP, and the position of a boundary corresponding to the tier of the member SLT, the support pillar HR, and the contact plug CC, can be set between different interconnect layers 34. For example, as described with reference to FIG. 5, the boundary BDm1, at which the upper surface of the lower memory pillar LMP and the lower surface of the middle memory pillar MMP come in contact, is located between the interconnect layer 34a functioning as the word line WL2 and the interconnect layer 34b functioning as the word line WL3. In addition, the boundary BDc1, at which the upper surface of the lower support pillar LHR and the lower surface of the upper support pillar UHR are in contact with each other, is located between the interconnect layer 34b functioning as the word line WL4 and the interconnect layer 34c functioning as the word line WL5. The number of processes of the memory cell array and the manufacturing cost can be reduced by appropriately setting the number of tiers of the memory pillar MP and the number of tiers of the member SLT, the support pillar HR, and the contact plug CC.

In addition, with the configuration according to the present embodiment, the position of the boundary corresponding to the tier of the memory pillar MP, and the position of the boundary corresponding to the tier of the member SLT, the support pillar HR, and the contact plug CC, can be set between different interconnect layers 34. Thereby, as described with reference to FIG. 8, for example, it is possible to suppress the distance between the memory pillar MP, and the member SLT or the support pillar HR, from increasing. Thereby, for example, bending of the layer stack can be suppressed.

### 2. Second Embodiment

Next, a second embodiment is described. In the second embodiment, a case is described in which the number of tiers of the member SLT, the support pillar HR, and the contact plug CC is greater than the number of tiers of the memory pillar MP. Hereinafter, different points from the first embodiment are mainly described.

### 2.1. Cross-Sectional Configuration of Memory Cell Area

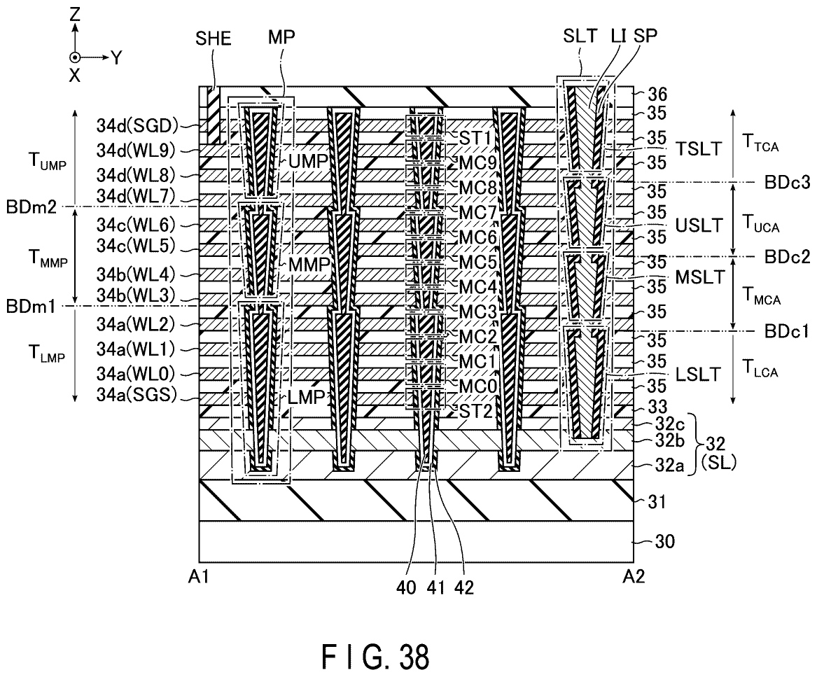

An example of a cross-sectional configuration of the memory cell area MA is described with reference to FIG. 38. FIG. 38 is a cross-sectional view illustrating an example of a cross-sectional configuration of the memory cell area MA.

As illustrated in FIG. 38, the shape of the memory pillar MP of the present embodiment is the same as illustrated in FIG. 5 of the first embodiment. The memory pillar MP includes a lower memory pillar LMP, a middle memory pillar MMP, and an upper memory pillar UMP.

Next, a configuration of the member SLT is described.

In the present embodiment, the member SLT, the support pillar HR, and the contact plug CC have such a configuration that the member SLT, the support pillar HR, and the contact plug CC are formed by being divided into four tiers. Hereinafter, a tier corresponding to a middle member MSLT, a middle support pillar MHR, and a middle contact plug MCC is described as “middle tier T_{MCA}”. In addition, a tier corresponding to a top member TSLT, a top support pillar THR, and a top contact plug TCC is described as “top tier T_{TCA}”.

The member SLT of the present embodiment includes the lower member LSLT, the middle member MSLT, the upper member USLT, and the top member TSLT. The middle member MSLT is provided on the lower member LSLT. The upper member USLT is provided on the middle member MSLT. The top member TSLT is provided on the upper member USLT. In other words, the member SLT of the present embodiment has a configuration in which the member SLT is formed by being divided into a lower tier T_{LCA}, a middle tier T_{MCA}, an upper tier T_{UCA}, and a top tier T_{TCA}. That is, the member SLT is divisionally processed four times.

The lower member LSLT passes through three interconnect layers 34a functioning as the select gate line SGS and the word lines WL0 and WL1. Accordingly, the lower tier T_{LCA} includes the three interconnect layers 34a. A lower end of each lower member LSLT reaches the semiconductor layer 32b.

The middle member MSLT passes through three interconnect layers 34 (one interconnect layer 34a and two interconnect layers 34b) functioning as the word lines WL2 to WL4. Accordingly, the middle tier T_{MCA} includes the three interconnect layers 34 (one interconnect layer 34a and two interconnect layers 34b). A lower surface of the middle member MSLT is in contact with an upper surface of the lower member LSLT. That is, a boundary BDc1, at which the upper surface of the lower member LSLT and the lower surface of the middle member MSLT are in contact with each other, is located between the interconnect layer 34a functioning as the word line WL1 and the interconnect layer 34a functioning as the word line WL2. In other words, the boundary BDc1 between the lower tier T_{LCA} and the middle tier T_{MCA} is located between the interconnect layer 34a functioning as the word line WL1 and the interconnect layer 34a functioning as the word line WL2.

The upper member USLT passes through three interconnect layers 34 (two interconnect layers 34c and one interconnect layer 34d) functioning as the word lines WL5 to WL7. Accordingly, the upper tier T_{UCA} includes the three interconnect layers 34 (two interconnect layers 34c and one interconnect layer 34d). A lower surface of the upper member USLT is in contact with an upper surface of the middle member MSLT. That is, a boundary BDc2, at which the upper surface of the middle member MSLT and the lower surface of the upper member USLT are in contact with each other, is located between the interconnect layer 34b functioning as the word line WL4 and the interconnect layer 34c functioning as the word line WL5. In other words, the boundary BDc2 between the middle tier T_{MCA} and the upper tier T_{UCA} is located between the interconnect layer 34b functioning as the word line WL4 and the interconnect layer 34c functioning as the word line WL5.

The top member TSLT passes through three interconnect layers 34d functioning as the word lines WL8 and WL9 and the select gate line SGD. Accordingly, the top tier T_{TCA} includes the three interconnect layers 34d. A lower surface of the top member TSLT is in contact with an upper surface of the upper member USLT. That is, a boundary BDc3, at which the upper surface of the upper member USLT and the lower surface of the top member TSLT are in contact with each other, is located between the interconnect layer 34d functioning as the word line WL7 and the interconnect layer 34d functioning as the word line WL8. In other words, the boundary BDc3 between the upper tier T_{UCA} and the top tier T_{TCA} is located between the interconnect layer 34d functioning as the word line WL7 and the interconnect layer 34d functioning as the word line WL8. Also in the present embodiment, the tier boundary of the memory pillar MP and the tier boundary of the member SLT are located between different interconnect layers 34.

Each of the lower member LSLT, the middle member MSLT, the upper member USLT, and the top member TSLT has, for example, a taper shape with a greater width in the Y direction at an upper end than at a lower end thereof. Thus, each boundary can be confirmed by observing the cross-sectional shape.

### 2.2. Cross-Sectional Configuration of Coupling Area

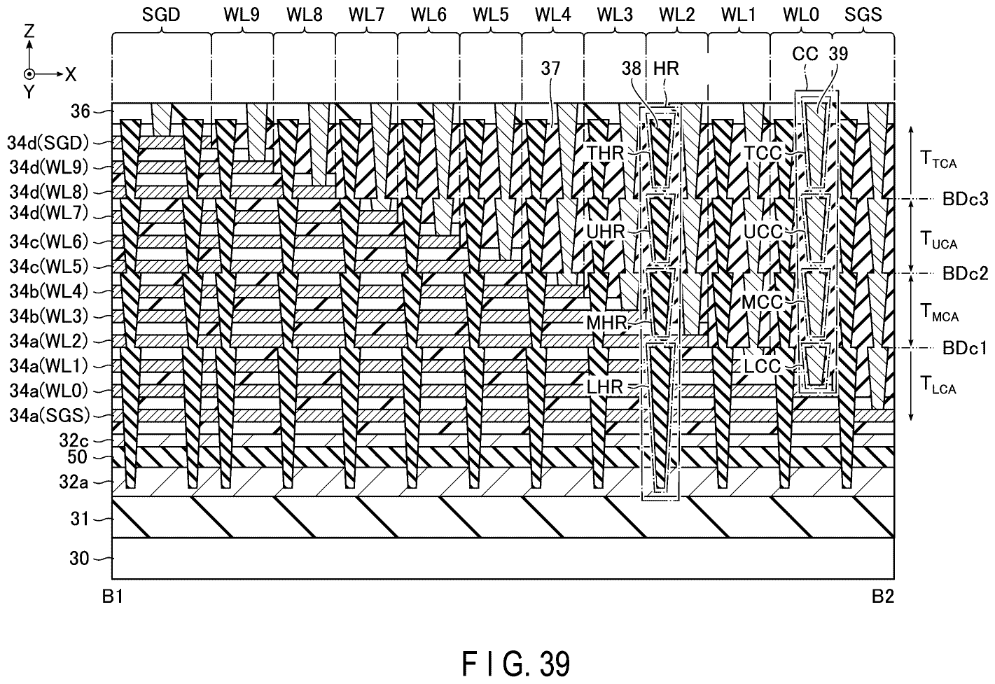

Referring to FIG. 39, an example of a cross-sectional configuration of the coupling area CA is described. FIG. 39 is a cross-sectional view illustrating an example of the cross-sectional configuration of the coupling area CA1. Note that in the example illustrated in FIG. 39, like FIG. 7, in the terrace of the select gate line SGD, two support pillars HR passing through the terrace are illustrated in such a manner as to correspond to the cross section along line B1 to B2. On the other hand, in each terrace of the word lines WL0 to WL9 and the select gate line SGS, the depiction of some support pillars HR is omitted for the purpose of simpler illustration, and one support pillar HR passing through each terrace is illustrated. In each terrace of the word lines WL0 to WL9 and the select gate line SGS, although the depiction of some support pillars HR is omitted, the support pillars HR are provided in each terrace in the same arrangement as in the terrace of the select gate line SGD.

As illustrated in FIG. 39, the support pillar HR of the present embodiment includes a lower support pillar LHR, a middle support pillar MHR, an upper support pillar UHR and a top support pillar THR. The middle support pillar MHR is provided on the lower support pillar LHR. The upper support pillar UHR is provided on the middle support pillar MHR. The top support pillar THR is provided on the upper support pillar UHR. The support pillar HR of the present embodiment includes, like the member SLT, a lower tier T_{LCA}, a middle tier T_{MCA}, an upper tier T_{UCA}, and a top tier T_{TCA}. That is, the support pillar HR is divisionally processed four times.

The lower support pillar LHR, which passes through each terrace of the select gate line SGS and the word lines WL0 and WL1, passes through the corresponding terrace and the interconnect layers 34 located below the terrace. For example, the lower support pillar LHR, which passes through the terrace of the select gate line SGS, passes through the interconnect layer 34a functioning as the select gate line SGS, and the insulating layer 35 provided on this interconnect layer 34a. For example, the lower support pillar LHR, which passes through the terrace of the word line WL1, passes through three interconnect layers 34a functioning as the select gate line SGS and the word lines WL0 and WL1, and three insulating layers 35. Further, the lower support pillar LHR, which passes through each terrace of the select gate line SGS and the word line WL0, passes through the insulating layer 37 provided above the corresponding terrace. The lower support pillars LHR provided below the terraces of the word lines WL2 to WL9 and the select gate line SGD do not pass through the terraces. These lower support pillars LHR pass through the three interconnect layers 34a functioning as the select gate line SGS and the word lines WL0 and WL1, and the three insulating layers 35, below the corresponding terraces. A lower end of each lower support pillar LHR reaches, for example, the semiconductor layer 32a.

The middle support pillar MHR, which is provided above each terrace of the select gate line SGS and the word lines WL0 and WL1, passes through the insulating layer 37. The middle support pillar MHR, which passes through each terrace of the word lines WL2 to WL4, passes through the corresponding terrace and the interconnect layers 34 of the middle tier T_{MCA} located below the terrace. For example, the middle support pillar MHR, which passes through the terrace of the word line WL2, passes through the interconnect layer 34a functioning as the word line WL2 and the insulating layer 35 provided on the interconnect layer 34a. For example, the middle support pillar MHR, which passes through the terrace of the word line WL4, passes through three interconnect layers 34 (uppermost interconnect layer 34a and two interconnect layers 34b) functioning as the word lines WL2 to WL4, and three insulating layers 35. Further, the middle support pillar MHR, which passes through each terrace of the word lines WL2 and WL3, passes through the insulating layer 37 provided above the terrace. In addition, the middle support pillars MHR, which are provided below the terraces of the word lines WL5 to WL9 and the select gate line SGD, do not pass though the terraces. These lower middle pillars MHR pass through the three interconnect layers 34 (uppermost interconnect layer 34a and two interconnect layers 34b) functioning as the word lines WL2 to WL4, and the three insulating layers 35, under the corresponding terraces. A lower surface of each middle support pillar MHR is in contact with an upper surface of the corresponding lower support pillar LHR. That is, the boundary BDc1, at which the upper surface of the lower support pillar LHR and the lower surface of the middle support pillar MHR are in contact with each other, is located between the interconnect layer 34a functioning as the word line WL1 and the uppermost interconnect layer 34a functioning as the word line WL2.

The upper support pillar UHR, which is provided above each terrace of the select gate line SGS and the word lines WL0 to WL4, passes through the insulating layer 37. The upper support pillar UHR, which passes through each terrace of the word lines WL5 to WL7, passes through the corresponding terrace and the interconnect layers 34 of the upper tier T_{UCA} located below the terrace. For example, the upper support pillar UHR, which passes through the terrace of the word line WL5, passes through the interconnect layer 34c functioning as the word line WL5 and the insulating layer 35 provided on this interconnect layer 34c. For example, the upper support pillar UHR, which passes through the terrace of the word line WL7, passes through three interconnect layers 34 (two interconnect layers 34c and lowermost interconnect layer 34d) functioning as the word lines WL5 to WL7, and three insulating layers 35. Further, the upper support pillar UHR, which passes through each terrace of the word lines WL5 and WL6, passes through the insulating layer 37 provided above the terrace. In addition, the upper support pillars UHR, which are provided below the terraces of the word lines WL8 and WL9 and the select gate line SGD, do not pass though the terraces. These upper support pillars UHR pass through the three interconnect layers 34 (two interconnect layers 34c and lowermost interconnect layers 34d) functioning as the word lines WL5 to WL7, and the three insulating layers 35, below the corresponding terraces. A lower surface of each upper support pillar UHR is in contact with an upper surface of the corresponding middle support pillar MHR. That is, the boundary BDc2, at which the upper surface of the middle support pillar MHR and the lower surface of the upper support pillar UHR are in contact with each other, is located between the uppermost interconnect layer 34b functioning as the word line WL4 and the lowermost interconnect layer 34c functioning as the word line WL5.

The top support pillar THR provided above each terrace of the select gate line SGS and the word lines WL0 to WL7 passes through the insulating layer 37. The top support pillar THR, which passes through each terrace of the word lines WL8 and WL9 and the select gate line SGD, passes through the corresponding terrace and the interconnect layers 34 of the top tier T_{TCA} located below the terrace. For example, the top support pillar THR passing through the terrace of the word line WL8 passes through the interconnect layer 34d functioning as the word line WL8, and the insulating layer 35 provided on the interconnect layer 34d. For example, the top support pillar THR passing through the terrace of the select gate line SGD passes through the three interconnect layers 34 (three interconnect layers 34d) functioning as the word lines WL8 and WL9 and the select gate line SGD, and the three insulating layers 35. Further, the top support pillar THR passing through each terrace of the word lines WL8 and WL9 passes through the insulating layer 37 provided above the terrace. A lower surface of each of the top support pillars THR is in contact with an upper surface of the corresponding upper support pillar UHR. That is, the boundary BDc3, at which the upper surface of the upper support pillar UHR and the lower surface of the top support pillar THR are in contact with each other, is located between the interconnect layer 34d functioning as the word line WL7 and the interconnect layer 34d functioning as the word line WL8.

In the present embodiment, the tier boundary of the memory pillar MP and the tier boundary of the support pillar HR are located between different interconnect layers 34.

Each of the lower support pillar LHR, the middle support pillar MHR, the upper support pillar UHR, and the top support pillar THR has, for example, a taper shape with a greater diameter at an upper end than at a lower end thereof. In other words, each of the lower support pillar LHR, the middle support pillar MHR, the upper support pillar UHR, and the top support pillar THR has, for example, a truncated conical shape with a lower surface being smaller than an upper surface thereof. Thus, the boundary of each of the lower support pillar LHR, the middle support pillar MHR, the upper support pillar UHR, and the top support pillar THR can be confirmed by observing the cross-sectional shape.

Next, the contact plug CC is described.

The contact plug CC includes a lower contact plug LCC, a middle contact plug MCC, an upper contact plug UCC, and a top contact plug TCC. Some of the middle contact plugs MCC are provided on the corresponding lower contact plugs LCC. Some of the upper contact plugs UCC are provided on the corresponding middle contact plugs MCC. Some of the top contact plugs TCC are provided on the corresponding upper contact plugs UCC. Accordingly, like the member SLT and the support pillar HR, the contact plug CC of the present embodiment has a configuration in which the contact plug CC is formed by being divided into the lower tier T_{LCA}, the middle tier T_{MCA}, the upper tier T_{UCA}, and the top tier T_{TCA}. That is, the contact plug CC is divisionally processed four times.

The lower contact plug LCC is provided on each terrace of the select gate line SGS and the word lines WL0 and WL1. For example, an upper end of the lower contact plug LCC is located between the interconnect layer 34a functioning as the word line WL1 and the interconnect layer 34a functioning as the word line WL2. In other words, the upper end of the lower contact plug LCC is located at the boundary BDc1 between the lower tier T_{LCA} and the middle tier T_{MCA}.

The middle contact plugs MCC are provided on the lower contact plugs LCC corresponding to the select gate line SGS and the word lines WL0 and WL1. In addition, the middle contact plugs MCC are provided on the terraces of the word lines WL2 to WL4. A lower surface of the middle contact plug MCC corresponding to each of the select gate line SGS and the word lines WL0 and WL1 is in contact with an upper surface of the lower contact plug LCC. That is, the boundary BDc1, at which the upper surface of the lower contact plug LCC and the lower surface of the middle contact plug MCC are in contact with each other, is located between the interconnect layer 34a functioning as the word line WL1 and the interconnect layer 34a functioning as the word line WL2.

The upper contact plugs UCC are provided on the middle contact plugs MCC corresponding to the select gate line SGS and the word lines WL0 to WL4. In addition, the upper contact plugs UCC are provided on the terraces of the word lines WL5 to WL7. A lower surface of the upper contact plug UCC corresponding to each of the select gate line SGS and the word lines WL0 to WL4 is in contact with an upper surface of the middle contact plug MCC. That is, the boundary BDc2, at which the upper surface of the middle contact plug MCC and the lower surface of the upper contact plug UCC are in contact with each other, is located between the interconnect layer 34b functioning as the word line WL4 and the interconnect layer 34c functioning as the word line WL5.

The top contact plugs TCC are provided on the upper contact plugs UCC corresponding to the select gate line SGS and the word lines WL0 to WL7. In addition, the top contact plugs TCC are provided on the terraces of the word lines WL8 and WL9 and the select gate line SGD. A lower surface of the top contact plug TCC corresponding to each of the select gate line SGS and the word lines WL0 to WL7 is in contact with an upper surface of the upper contact plug UCC. That is, the boundary BDc3, at which the upper surface of the upper contact plug UCC and the lower surface of the top contact plug TCC are in contact with each other, is located between the interconnect layer 34d functioning as the word line WL7 and the interconnect layer 34d functioning as the word line WL8. An upper end of the top contact plug TCC is located above the uppermost interconnect layer 34d that functions as the select gate line SGD.

Each of the lower contact plug LCC, the middle contact plug MCC, the upper contact plug UCC, and the top contact plug TCC has, for example, a taper shape with a greater diameter at an upper end than at a lower end thereof. In other words, each of the lower contact plug LCC, the middle contact plug MCC, the upper contact plug UCC, and the top contact plug TCC has, for example, a truncated conical shape with a lower surface being smaller than an upper surface thereof. Thus, the boundary of each of the lower contact plug LCC, the middle contact plug MCC, the upper contact plug UCC, and the top contact plug TCC can be confirmed by observing the cross-sectional shape.

### 2.3. Boundaries of Memory Pillar, Member SLT, and Support Pillar

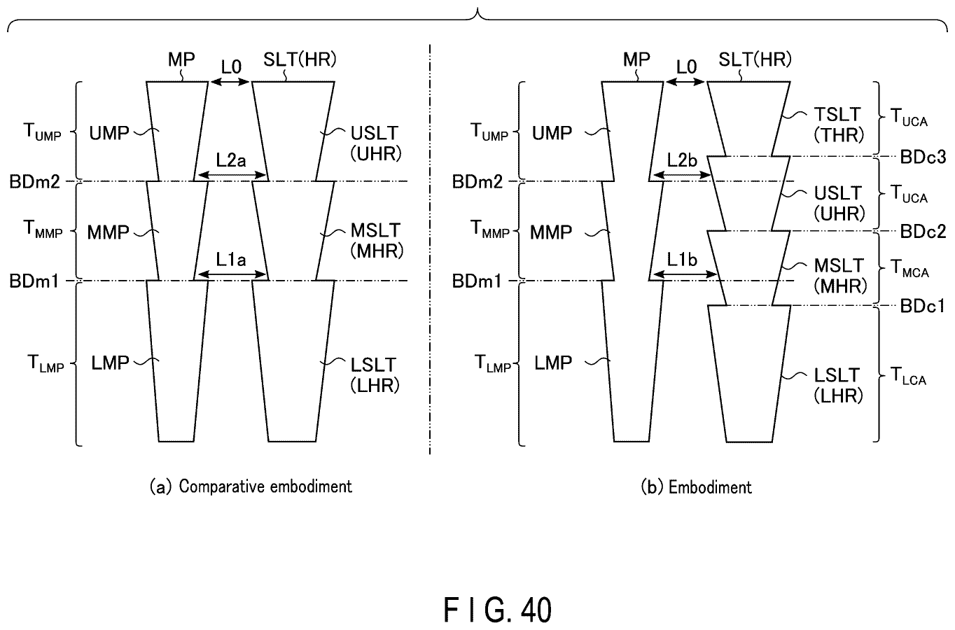

Next, referring to FIG. 40, boundaries of the memory pillar MP, the member SLT, and the support pillar HR are described. FIG. 40 is a conceptual view illustrating boundaries of the memory pillar MP, the member SLT, and the support pillar HR.

A comparative embodiment illustrated in part (a) of FIG. 40 is the same as the comparative embodiment described with reference to FIG. 8 of the first embodiment. In the description below, attention is paid to an embodiment.

In the embodiment, as illustrated in part (b) of FIG. 40, the memory pillar MP includes three tiers. Each of the member SLT and the support pillar HR includes four tiers. In other words, the memory pillar MP includes two boundaries BDm1 and BDm2. Each of the member SLT and support pillar HR includes three boundaries BDc1, BDc2, and BDc3. That is, the number of tiers of the member SLT and the support pillar HR is greater than the number of tiers of the memory pillar MP.

In this case, the boundaries BDm1 and BDm2 of the memory pillar MP, and the boundaries BDc1, BDc2, and BDc3 of the member SLT and the support pillar HR, are located at different positions between the interconnect layers 34. More specifically, in the description with reference to FIG. 38 and FIG. 39, the boundary BDm1 is located between the interconnect layer 34a functioning as the word line WL2 and the interconnect layer 34b functioning as the word line WL3. The boundary BDm2 is located between the interconnect layer 34c functioning as the word line WL6 and the interconnect layer 34d functioning as the word line WL7. On the other hand, the boundary BDc1 is located between the interconnect layer 34a functioning as the word line WL1 and the interconnect layer 34a functioning as the word line WL2. The boundary BDc2 is located between the interconnect layer 34b functioning as the word line WL4 and the interconnect layer 34c functioning as the word line WL5. The boundary BDc3 is located between the interconnect layer 34d functioning as the word line WL7 and the interconnect layer 34d functioning as the word line WL8.

For example, a distance between the upper end of the memory pillar MP (upper memory pillar UMP) and the upper end of the member SLT (top member TSLT), which neighbor each other, is defined as L0 that is identical to the comparative embodiment of part (a) of FIG. 40. A distance between the memory pillar MP and the member SLT at the boundary BDm1 is defined as L1b. A distance between the memory pillar MP and the member SLT at the boundary BDm2 is defined as L2b. The distance L0 and the distance L1b have a relationship of L0<L1b. Similarly, the distance L0 and the distance L2b have a relationship of L0<L2b.

If the distance L1a and the distance L1b are compared, the distance L1a and the distance L1b have a relationship of L1a>L1b, similarly with the description using FIG. 8 of the first embodiment. In addition, if the distance L2a and the distance L2b are compared, the distance L2a and the distance L2b have a relationship of L2a>L2b.

### 2.4. Manufacturing Method of Memory Cell Array

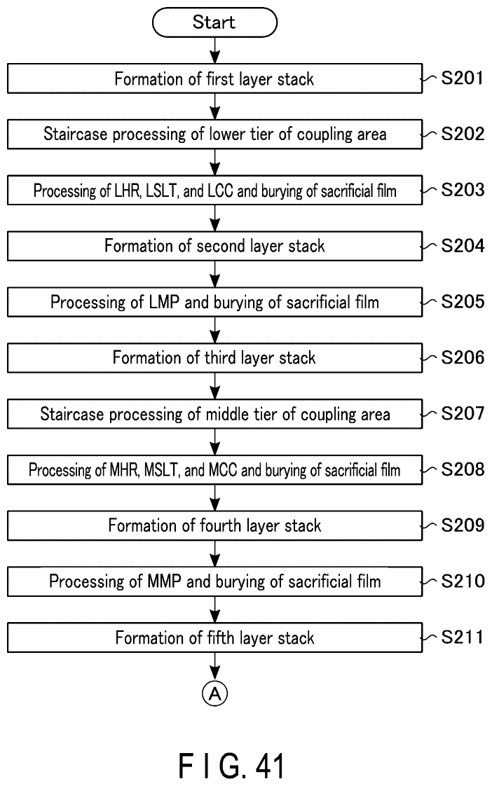

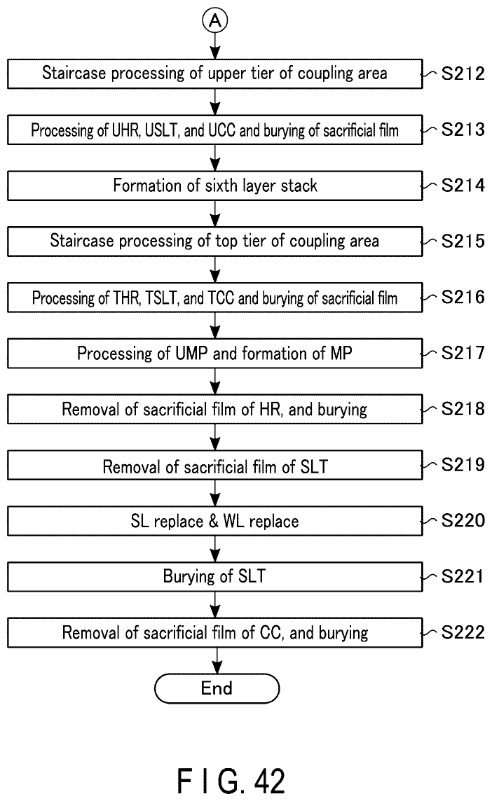

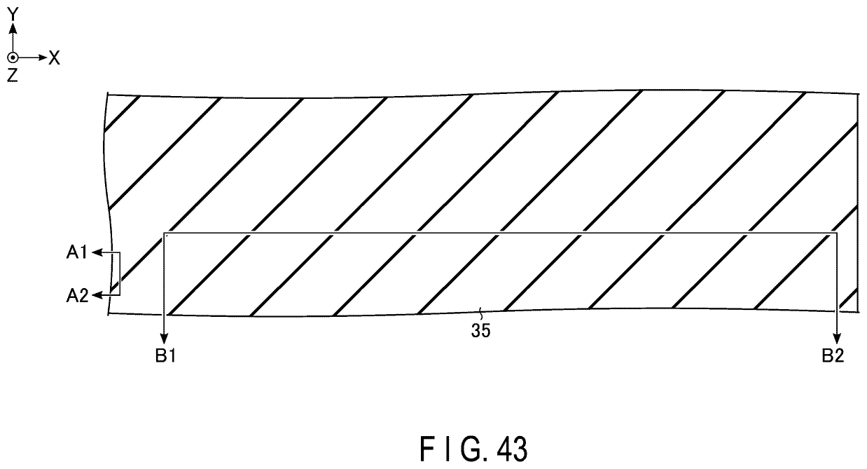

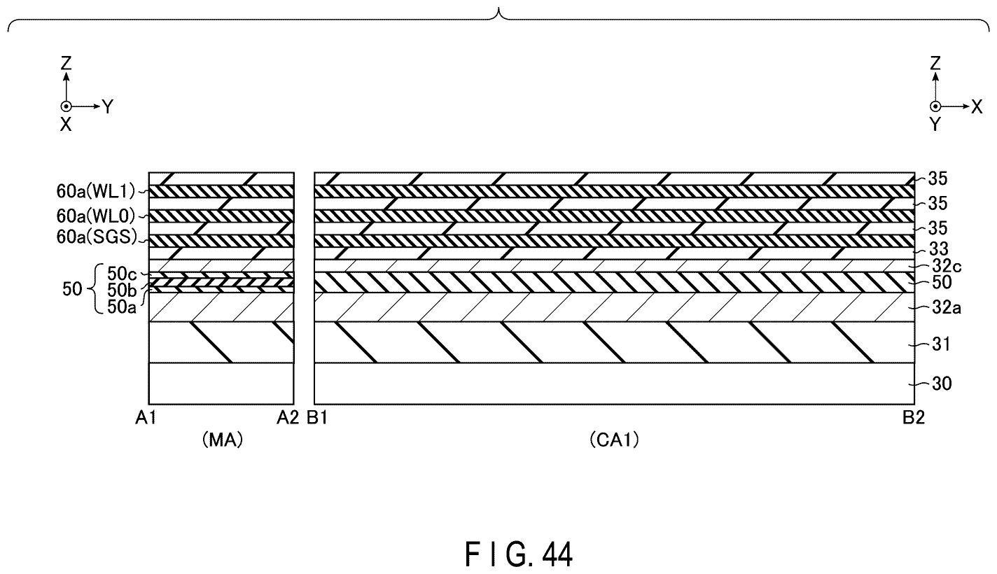

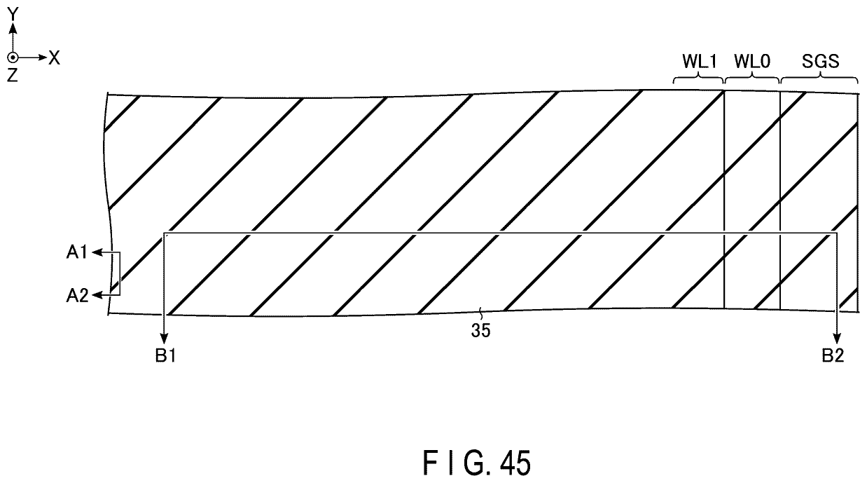

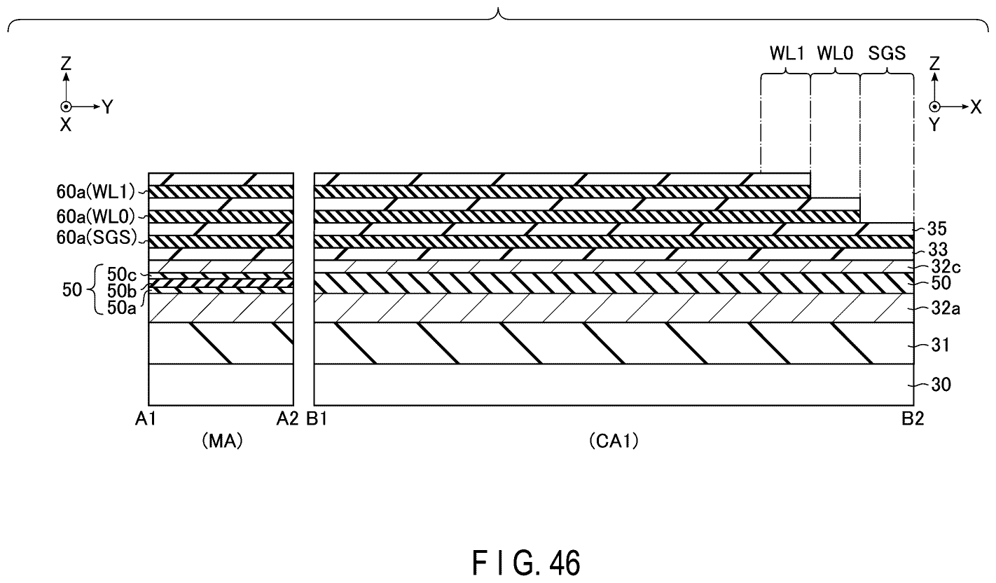

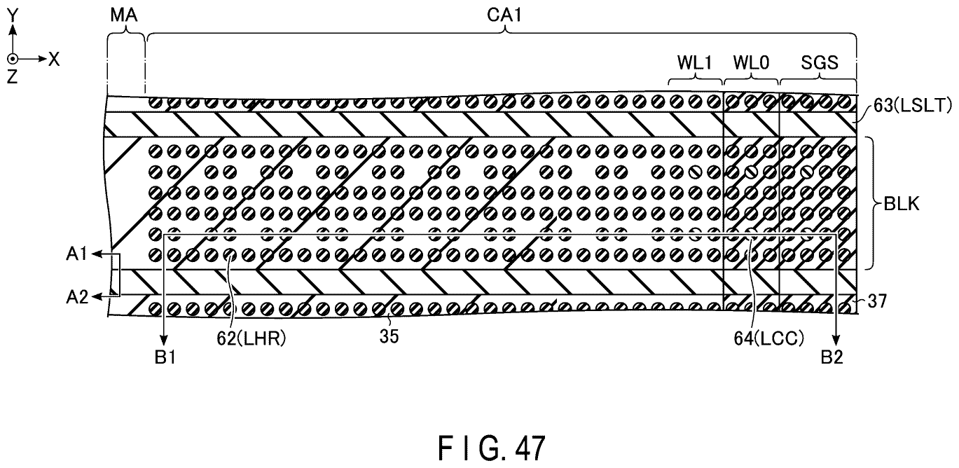

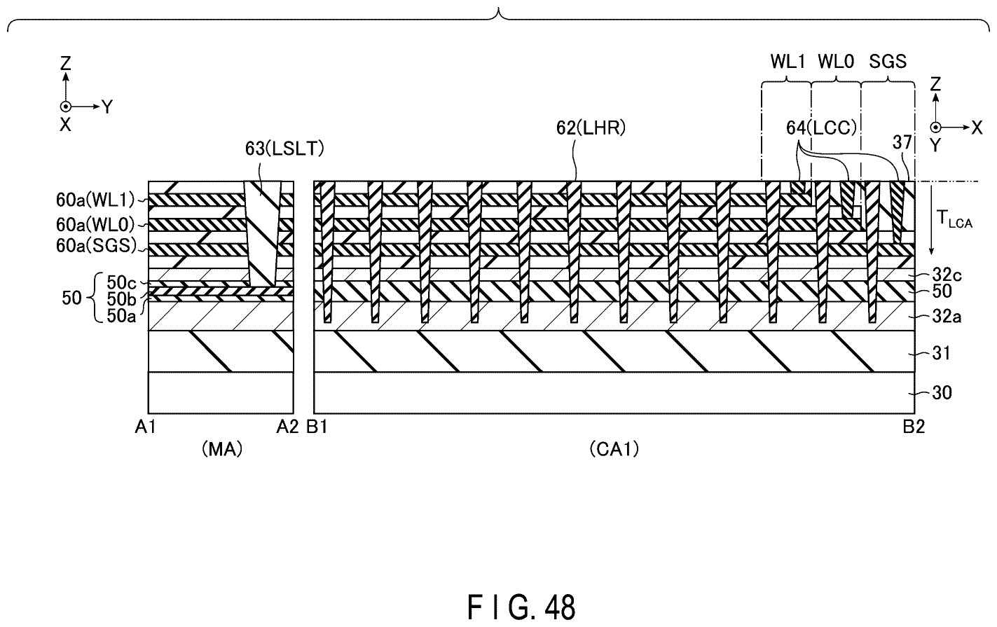

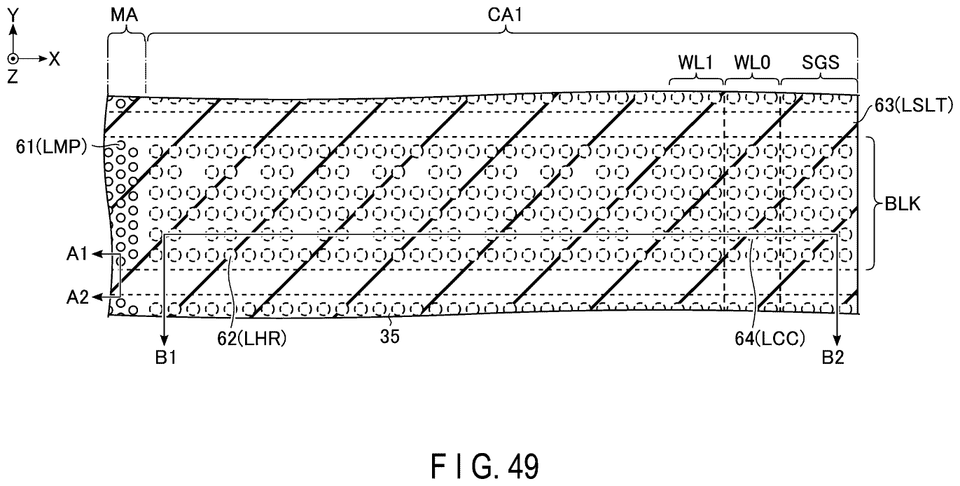

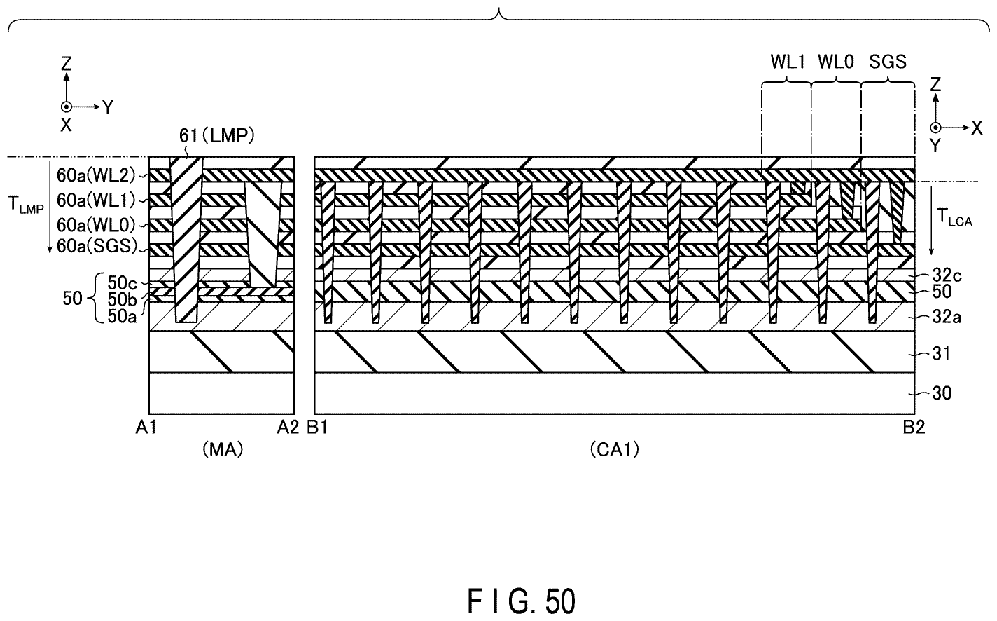

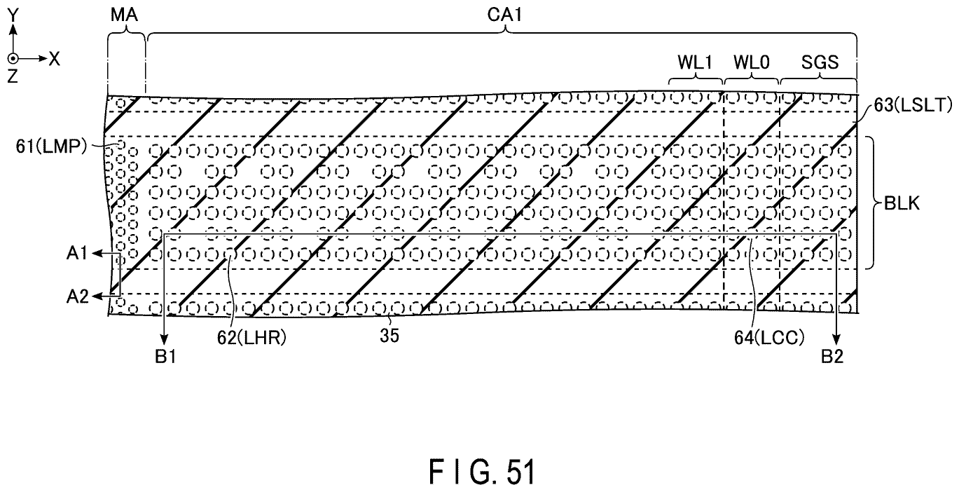

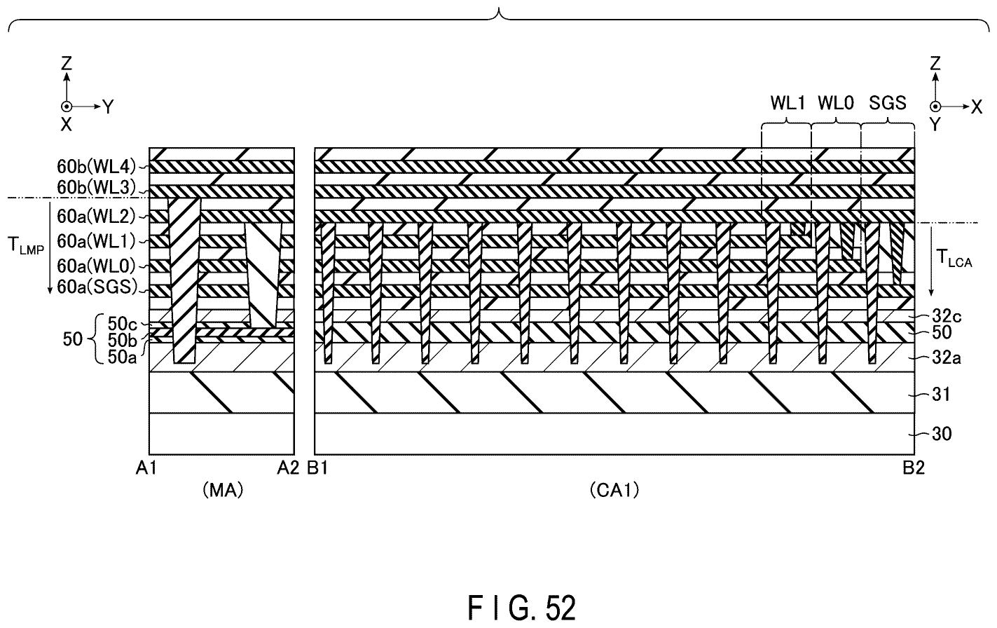

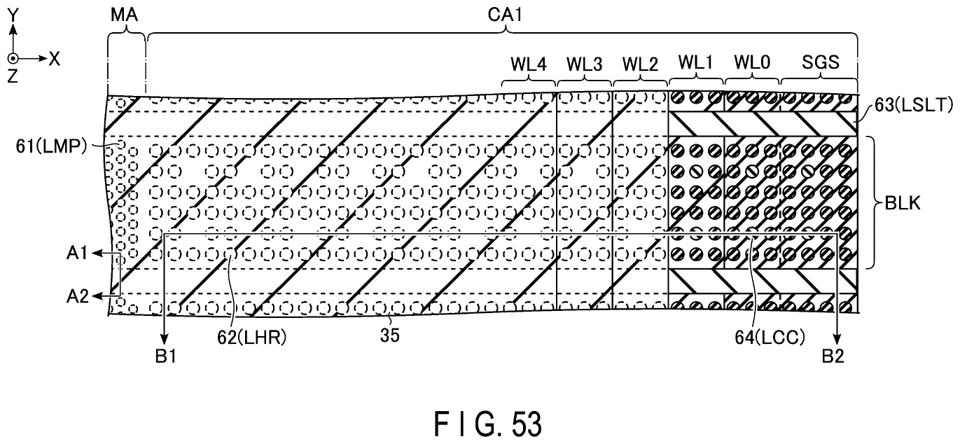

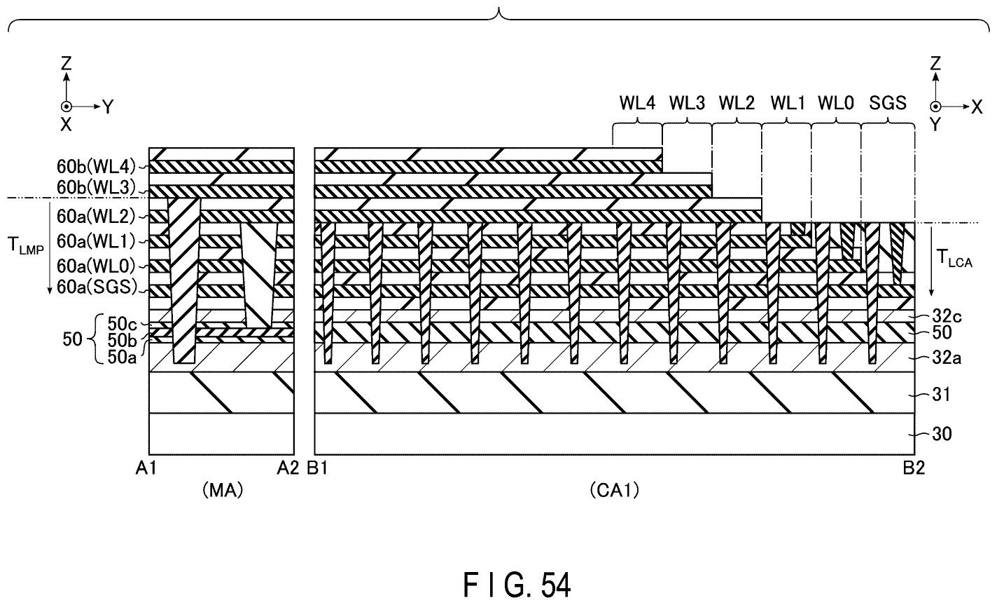

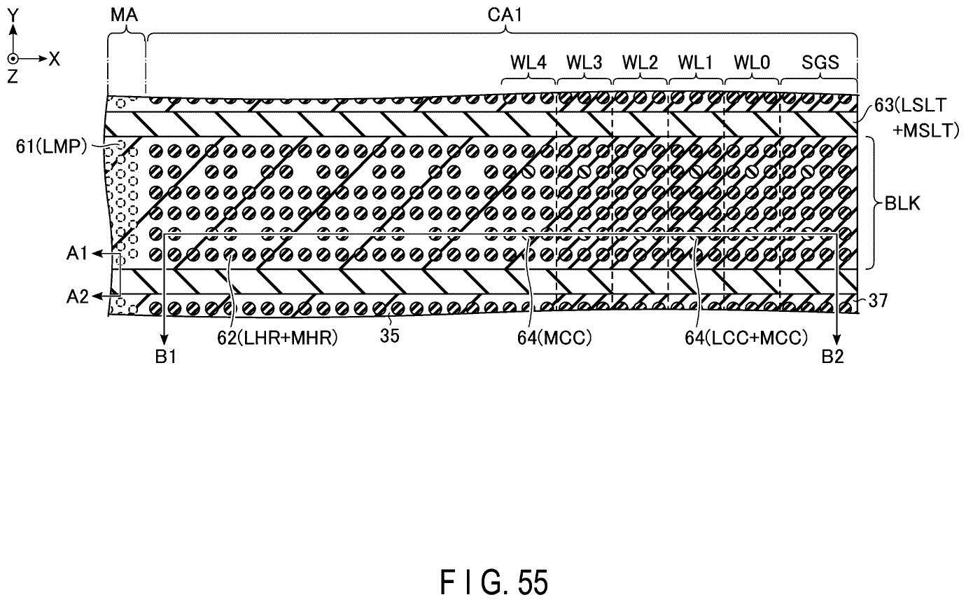

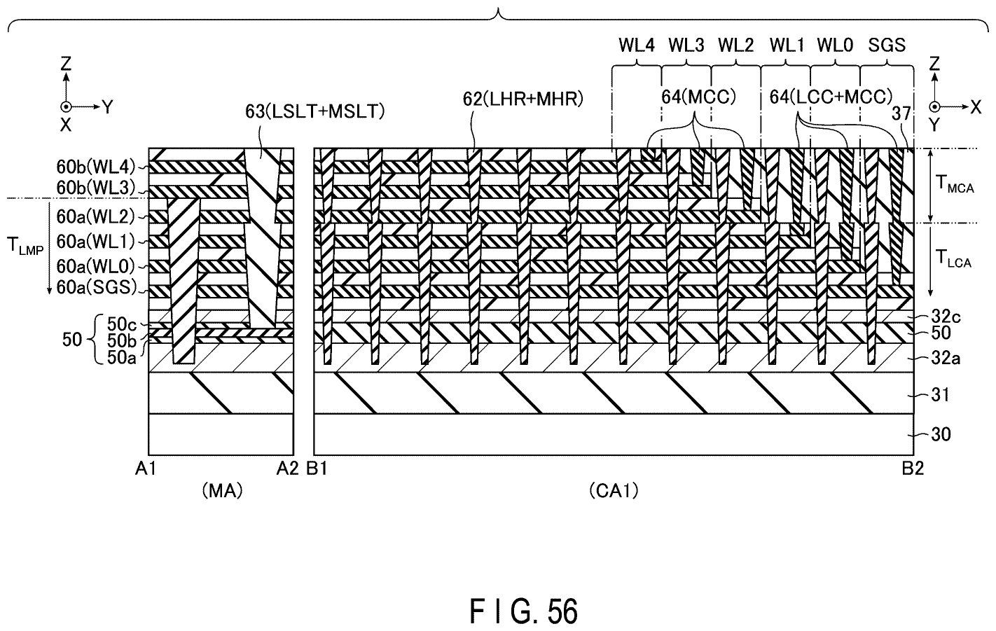

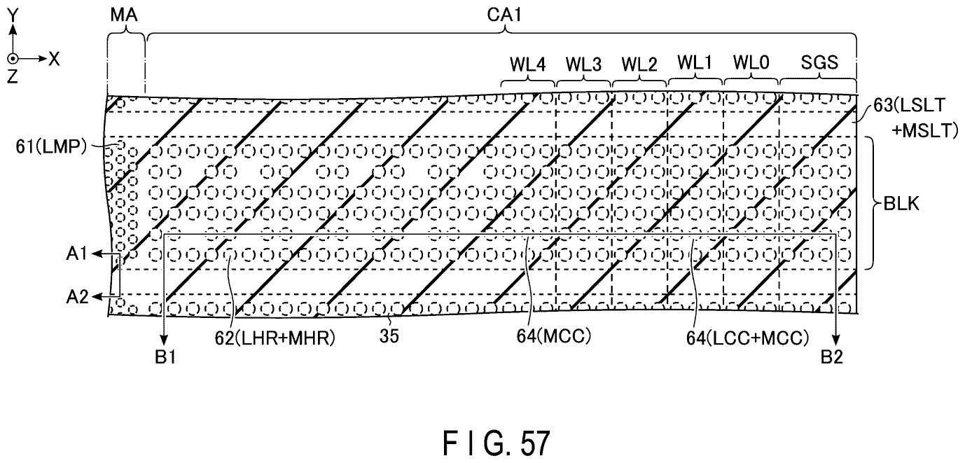

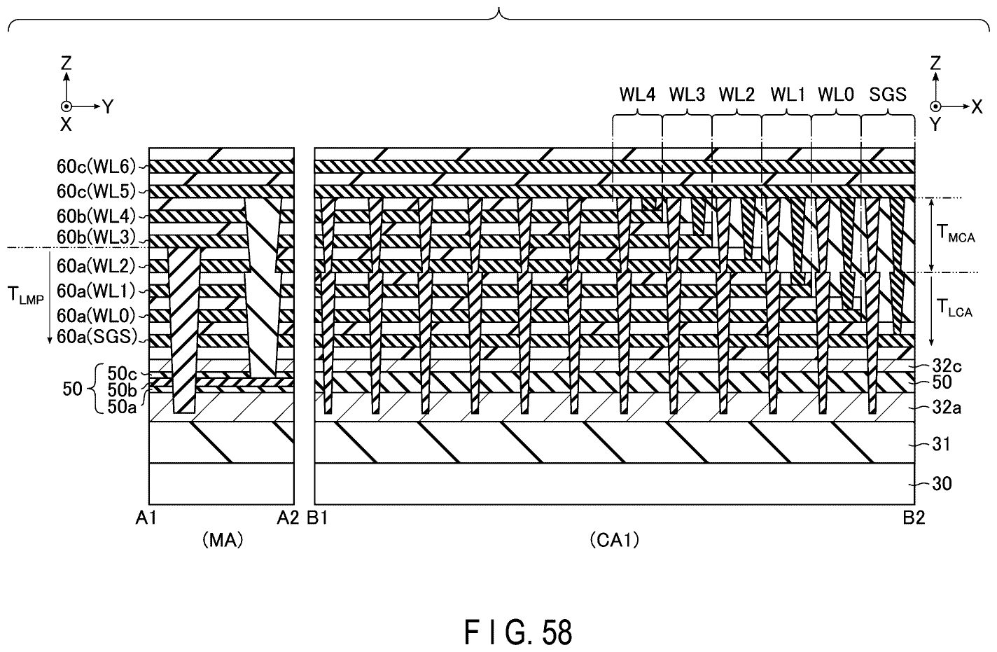

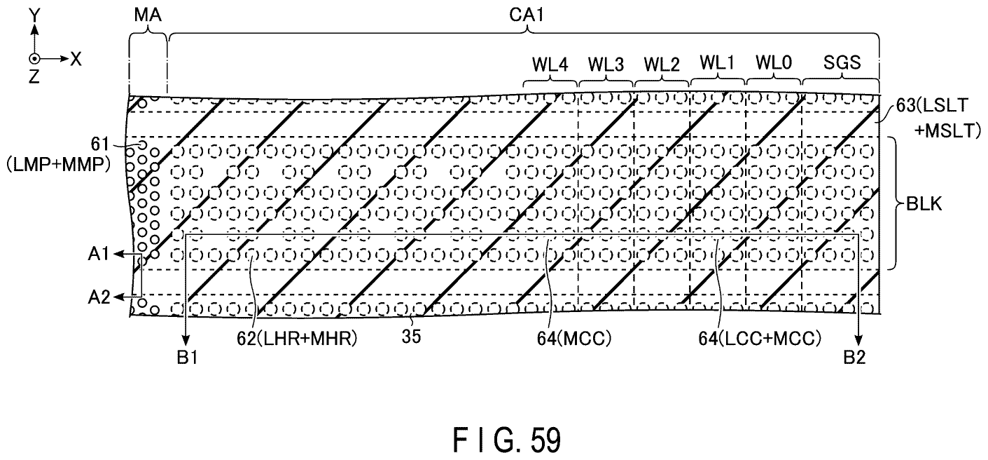

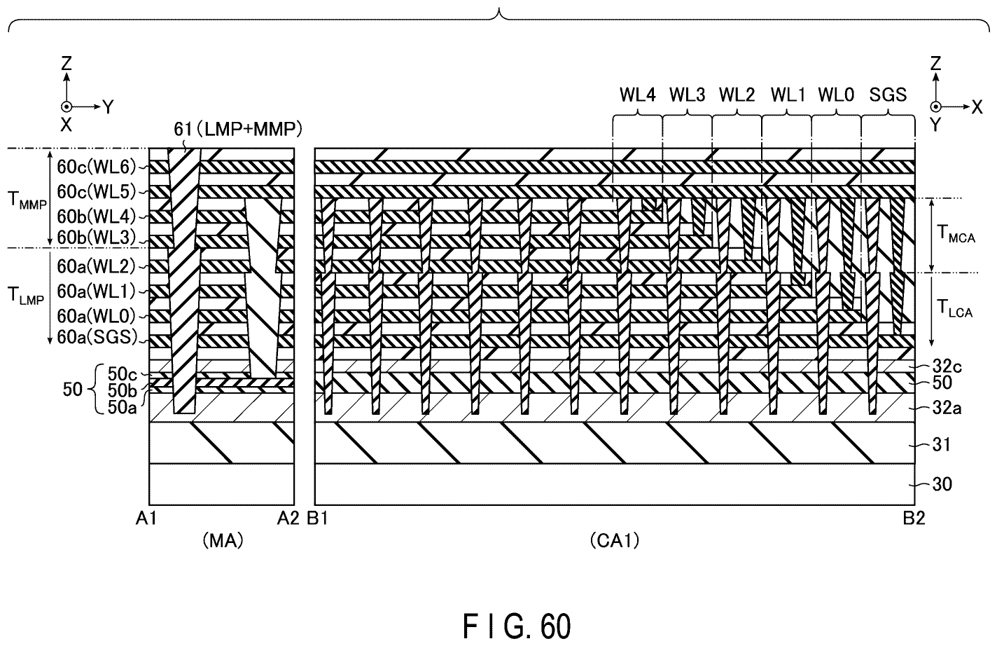

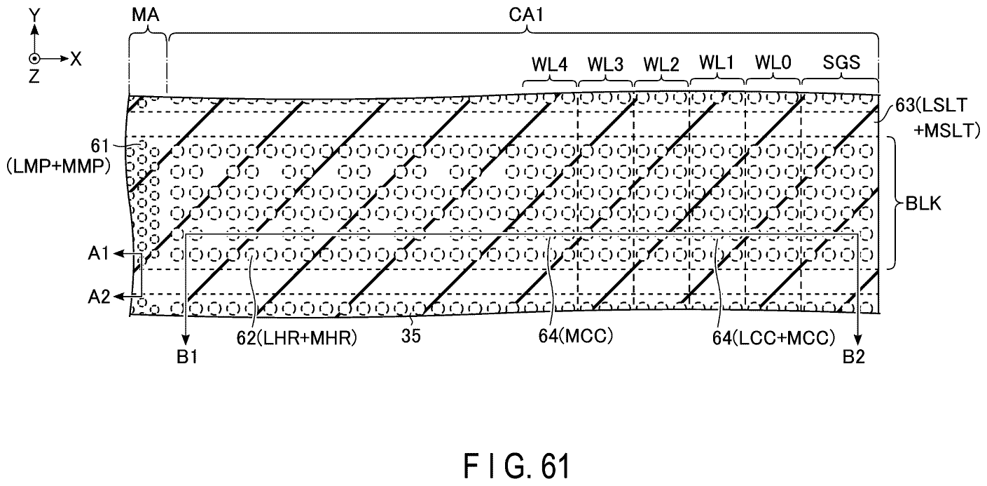

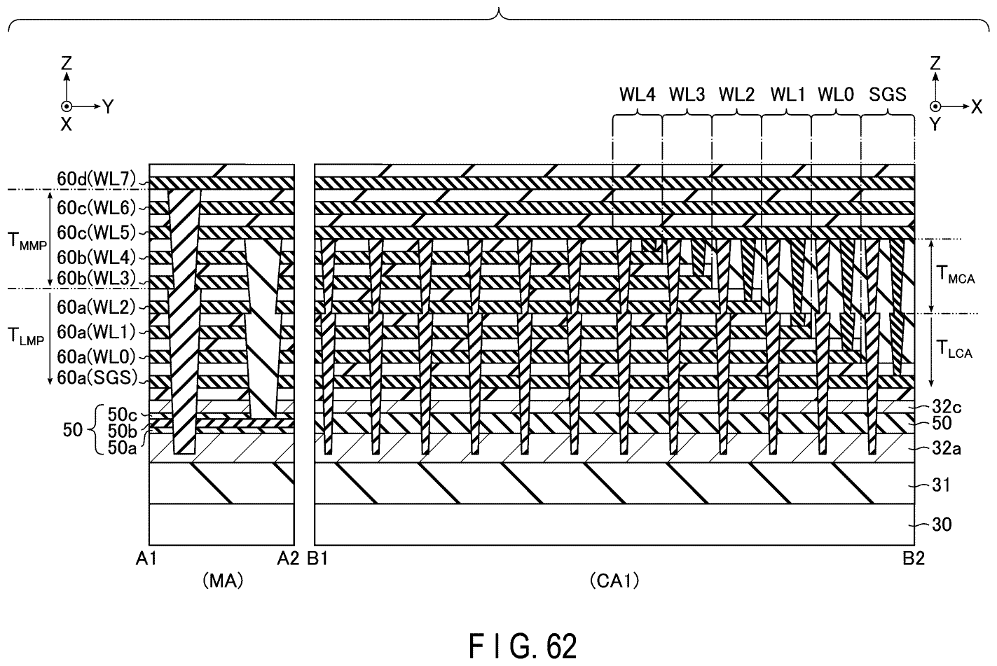

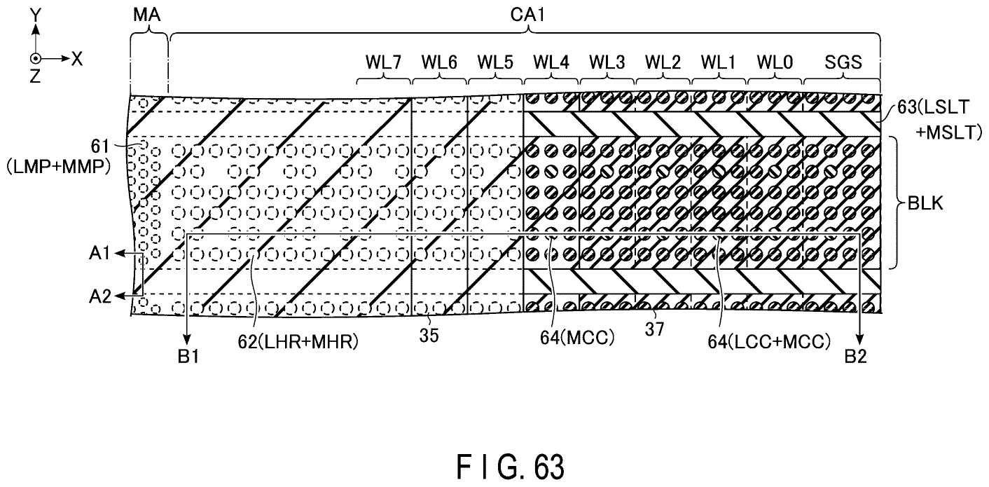

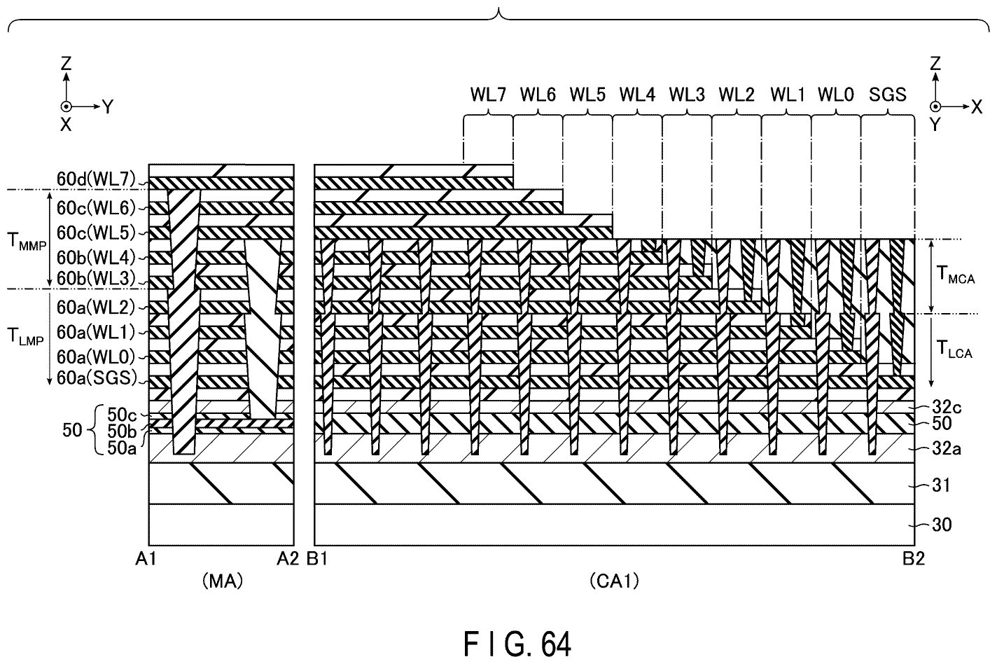

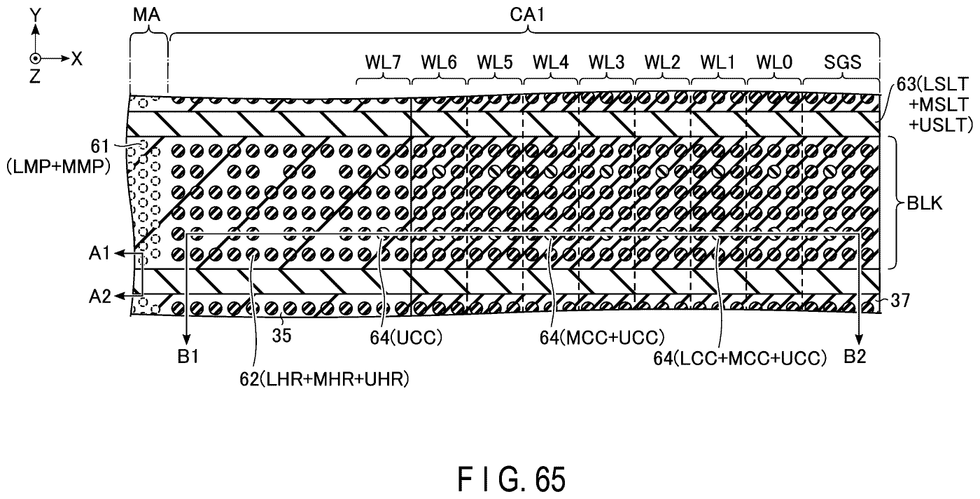

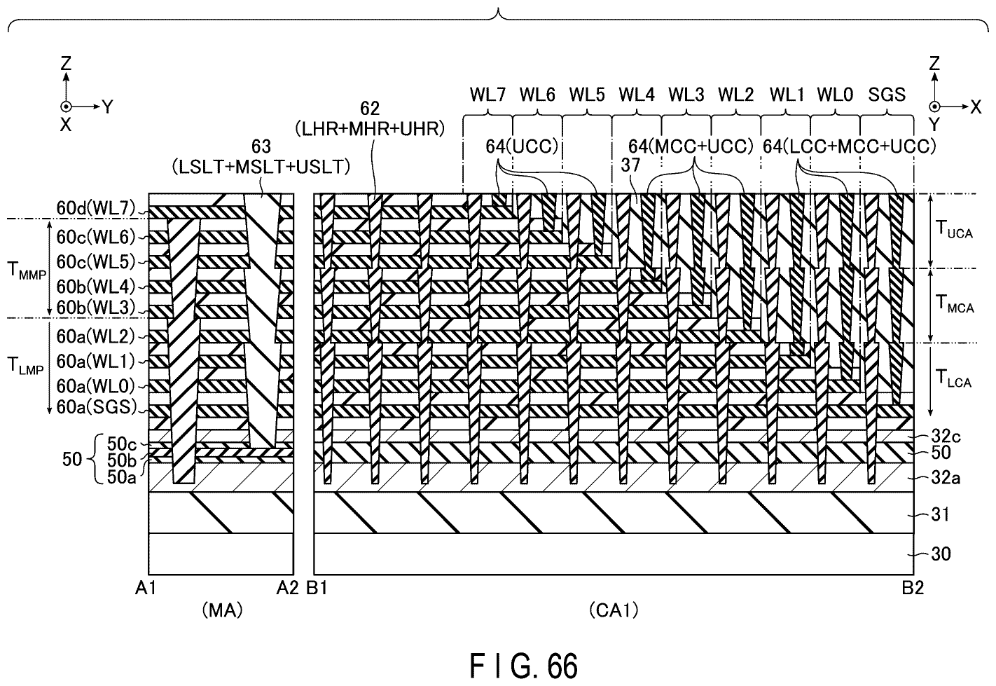

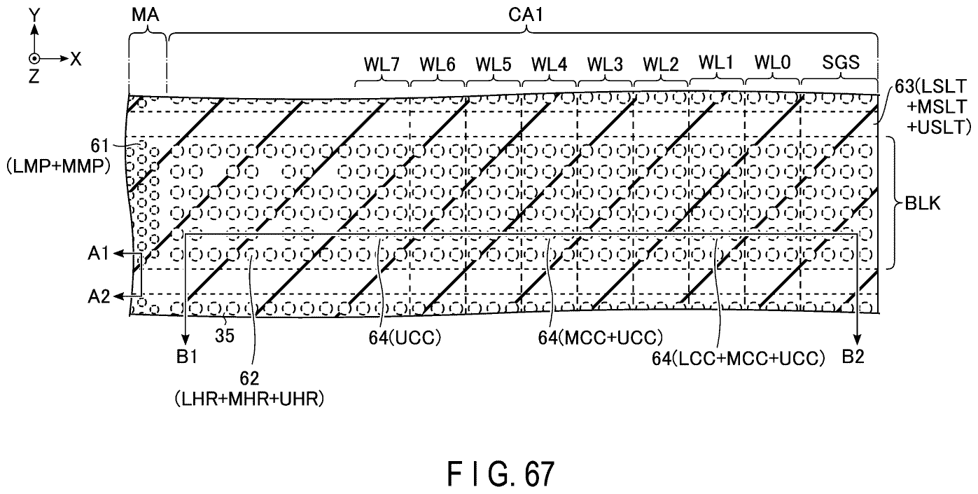

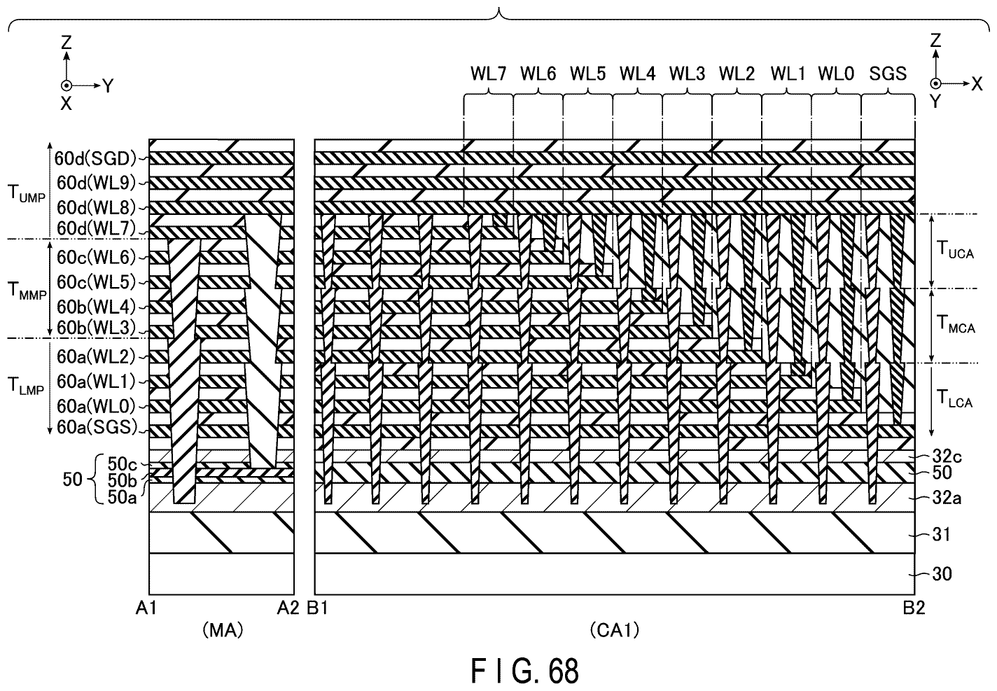

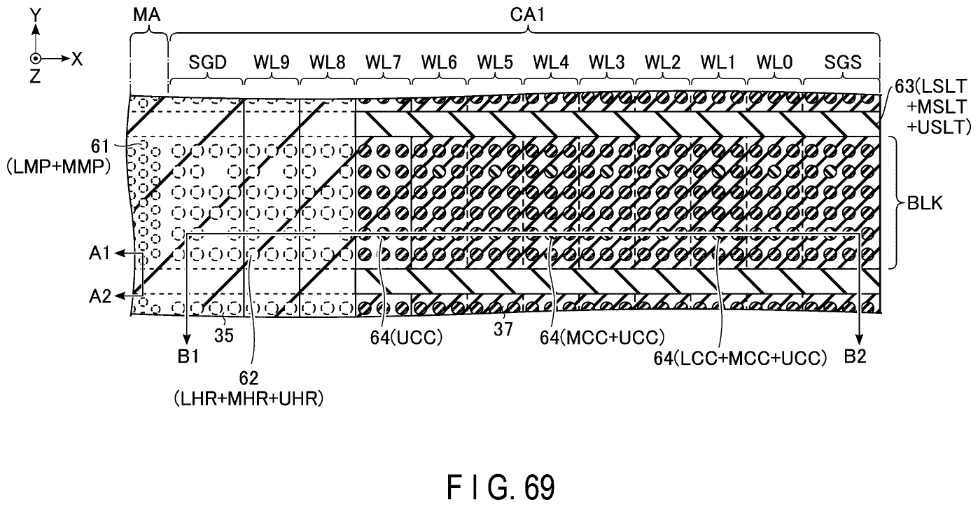

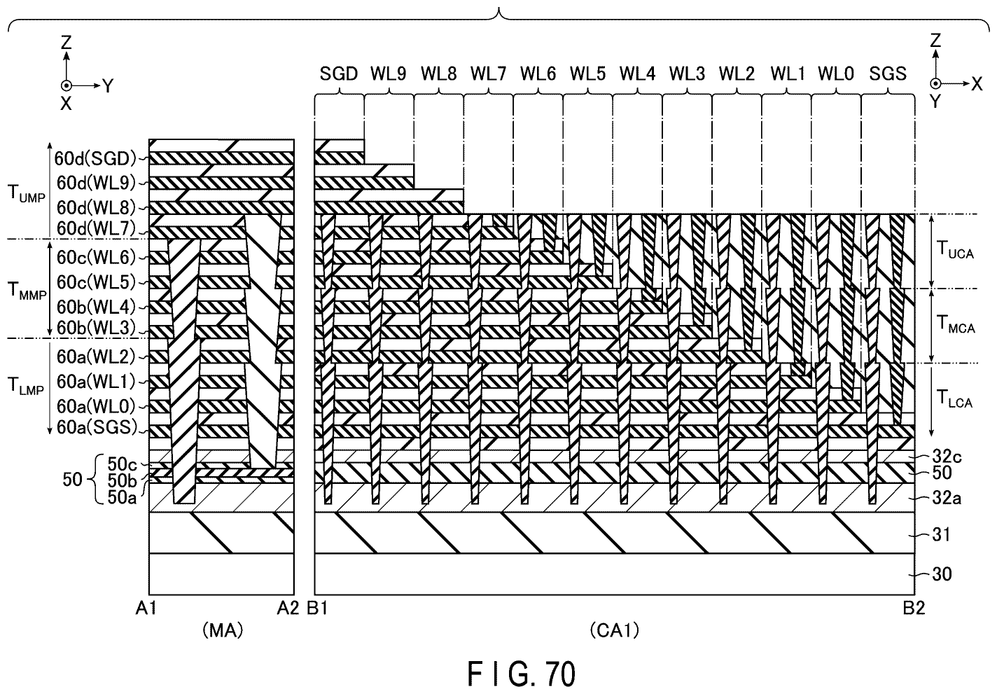

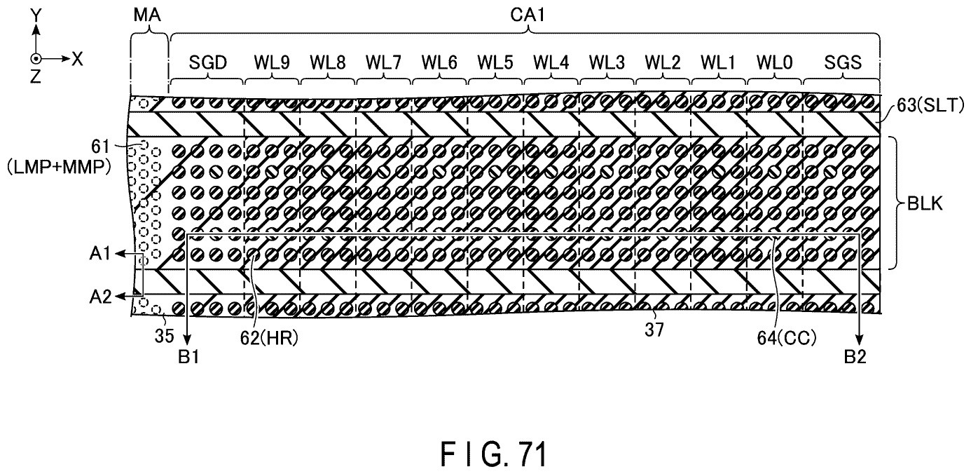

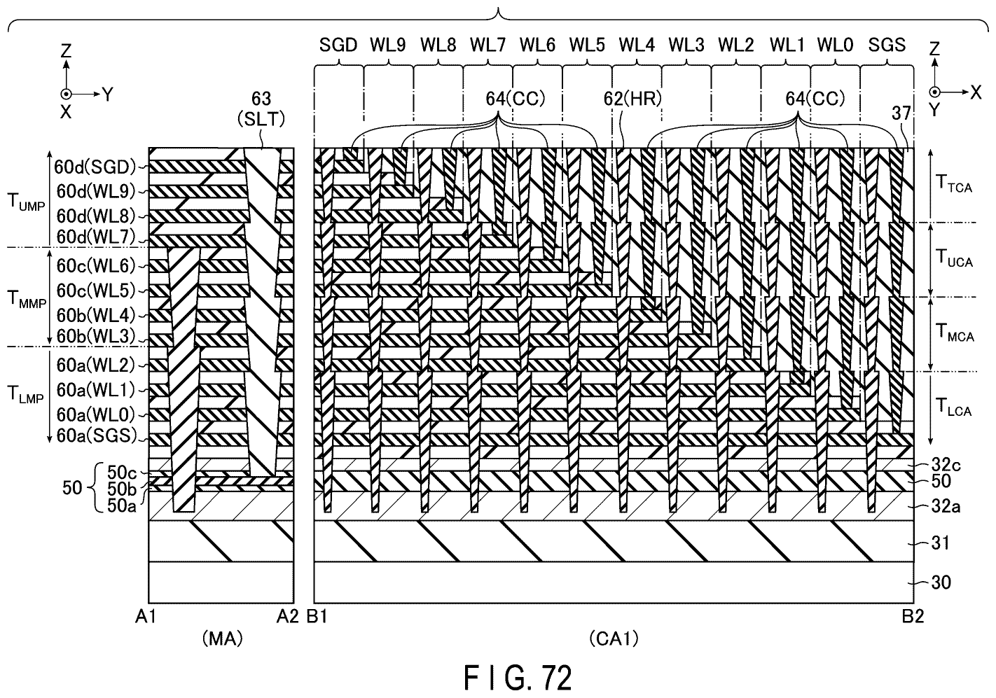

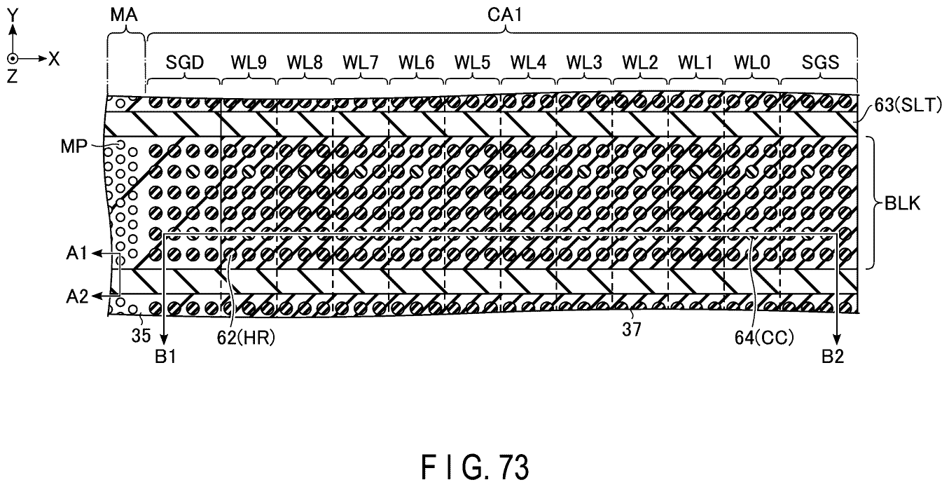

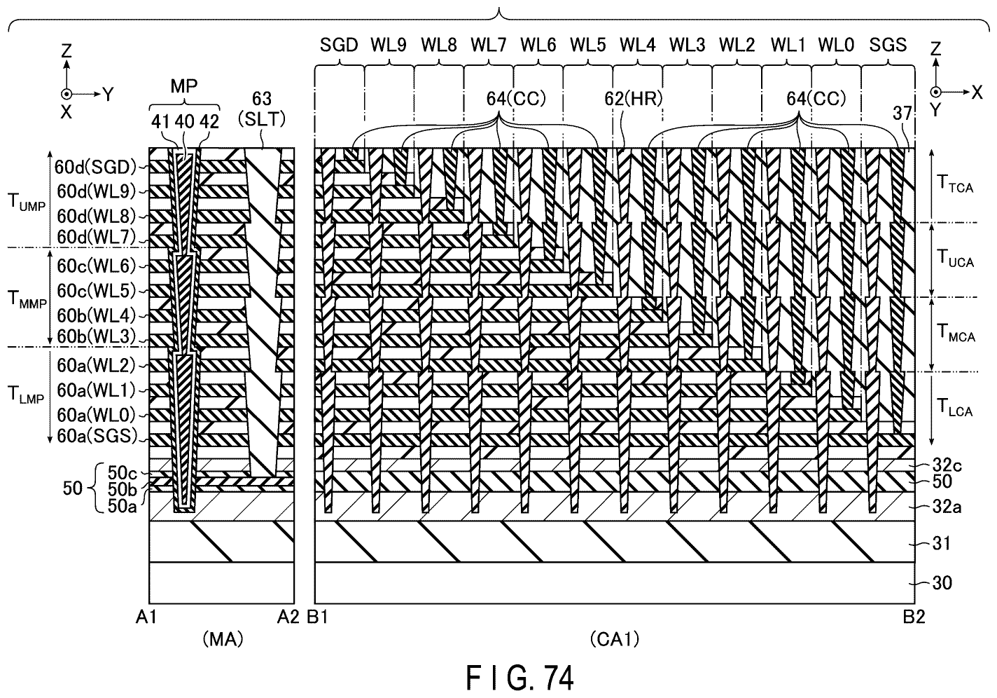

Next, referring to FIG. 41 to FIG. 74, an example of a manufacturing method of the memory cell array 11 is described. FIG. 41 and FIG. 42 are flowcharts illustrating an example of a manufacturing process of the memory cell array 11. FIG. 43, FIG. 45, FIG. 47, FIG. 49, FIG. 51, FIG. 53, FIG. 55, FIG. 57, FIG. 59, FIG. 61, FIG. 63, FIG. 65, FIG. 67, FIG. 69, FIG. 71, and FIG. 73 illustrate examples of planar layouts of the memory cell array 11 in the manufacturing process of the memory cell array 11. FIG. 44 is a cross-sectional view along line A1-A2 and line B1-B2 in FIG. 43. FIG. 46 is a cross-sectional view along line A1-A2 and line B1-B2 in FIG. 45. FIG. 48 is a cross-sectional view along line A1-A2 and line B1-B2 in FIG. 47. FIG. 50 is a cross-sectional view along line A1-A2 and line B1-B2 in FIG. 49. FIG. 52 is a cross-sectional view along line A1-A2 and line B1-B2 in FIG. 51. FIG. 54 is a cross-sectional view along line A1-A2 and line B1-B2 in FIG. 53. FIG. 56 is a cross-sectional view along line A1-A2 and line B1-B2 in FIG. 55. FIG. 58 is a cross-sectional view along line A1-A2 and line B1-B2 in FIG. 57. FIG. 60 is a cross-sectional view along line A1-A2 and line B1-B2 in FIG. 59. FIG. 62 is a cross-sectional view along line A1-A2 and line B1-B2 in FIG. 61. FIG. 64 is a cross-sectional view along line A1-A2 and line B1-B2 in FIG. 63. FIG. 66 is a cross-sectional view along line A1-A2 and line B1-B2 in FIG. 65. FIG. 68 is a cross-sectional view along line A1-A2 and line B1-B2 in FIG. 67. FIG. 70 is a cross-sectional view along line A1-A2 and line B1-B2 in FIG. 69. FIG. 72 is a cross-sectional view along line A1-A2 and line B1-B2 in FIG. 71. FIG. 74 is a cross-sectional view along line A1-A2 and line B1-B2 in FIG. 73. Note that in the cross-sectional views of the manufacturing process to be described below, the depiction of some support pillars HR passing through terraces is omitted in order to make the drawings simpler.

In the description below, in the layer stack composed of twelve interconnect layers 34 and twelve insulating layers 35, a structure composed of three lower interconnect layers 34a and three insulating layers 35 provided thereon is described as “first layer stack”. A structure composed of the uppermost interconnect layer 34a and an insulating layer 35 provided thereon is described as “second layer stack”. A structure composed of two interconnect layers 34b and two insulating layers 35 provided thereon is described as “third layer stack”. A structure composed of two interconnect layers 34c and two insulating layers 35 provided thereon is described as “fourth layer stack”. A structure composed of the lowermost interconnect layer 34d and an insulating layer provided thereon is described as “fifth layer stack”. A structure composed of three upper interconnect layers 34d and three insulating layers 35 provided thereon is described as “sixth layer stack”.

As illustrated in FIG. 41, at first, the first layer stack is formed (S201).

As illustrated in FIG. 43 and FIG. 44, as a first layer stack before the WL replace, three sacrificial films 60a and three insulating layers 35 are alternately stacked one by one on the insulating layer 33. The three sacrificial films 60a correspond to the lower tier T_{LCA}, and are, in the WL replace, replaced with three interconnect layers 34a functioning as the select gate line SGS and the word lines WL0 and WL1, respectively.

As illustrated in FIG. 41, after step S201 is executed, a staircase part corresponding to the lower tier T_{LCA} of the coupling area CA is formed (S202).

As illustrated in FIG. 45 and FIG. 46, staircase processing is performed on the first layer stack, and terraces corresponding to the three sacrificial films 60a are formed. That is, terraces corresponding to the select gate line SGS and the word line WL0 are processed.

As illustrated in FIG. 41, after step S202 is executed, processing of the lower support pillars LHR and burying by a sacrificial film 62, processing of the lower members LSLT and burying by a sacrificial film 63, and processing of the lower contact plugs LCC and burying by a sacrificial film 64, are successively executed (S203). Note that the order of the processing of the lower support pillars LHR, lower members LSLT, and the lower contact plugs LCC and the burying by the sacrificial films 62 to 64 is arbitrary.

As illustrated in FIG. 47 and FIG. 48, the staircase part is filled with the insulating layer 37, and is planarized by, for example, CMP. Next, in the coupling area CA, holes corresponding to the lower support pillars LHR are formed, and a sacrificial film 62 is buried in the holes. For example, a lower end of each hole corresponding to the lower support pillar LHR reaches the semiconductor layer 32a. Next, slits corresponding to the lower members LSLT are formed, and a sacrificial film 63 is buried in the slits. A lower end of each slit corresponding to the lower member LSLT reaches the insulating layer 50. Next, in the coupling area CA, holes corresponding to the lower contact plugs LCC are formed, and a sacrificial film 64 is buried in the holes. A lower end of each lower contact plug LCC reaches the terrace of the corresponding sacrificial film 60a (interconnect layer 34a). Note that the lower contact plugs LCC are provided on the terrace portions of the select gate line SGS and the word lines WL0 and WL1, and are not provided at positions corresponding to the terrace portions of the word lines WL2 to WL9 and the select gate line SGD.

As illustrated in FIG. 41, after step S203 is executed, the second layer stack is formed (S204). As a second layer stack before the WL replace, one sacrificial film 60a and one insulating layer 35 are stacked. The sacrificial film 60a is, in the WL replace, replaced with an interconnect layer 34a functioning as the word line WL2.

After step S204 is executed, similarly with step S102 described with reference to FIG. 9 of the first embodiment, memory holes corresponding to the lower memory pillars LMP are processed (formed), and the memory holes are filled with a sacrificial film 61 (S205).

As illustrated in FIG. 49 and FIG. 50, in the memory cell area MA, memory holes corresponding to the lower memory pillars LMP are formed. Then, the memory holes are filled with the sacrificial film 61.

As illustrated in FIG. 41, after step S205 is executed, the third layer stack is formed (S206).

As illustrated in FIG. 51 and FIG. 52, as a third layer stack before the WL replace, two sacrificial films 60b and two insulating layers 35 are alternately stacked one by one. The two sacrificial films 60b are, in the WL replace, replaced with two interconnect layers 34b functioning as the word lines WL3 and WL4, respectively.

As illustrated in FIG. 41, after step S206 is executed, a staircase part corresponding to the middle tier T_{MCA} of the coupling area CA is formed (S207).

As illustrated in FIG. 53 and FIG. 54, staircase processing is performed on the second and third layer stacks, and terraces corresponding to the sacrificial film 60a and two sacrificial films 60b are formed. That is, terraces corresponding to the word lines WL1 to WL3 are processed.

As illustrated in FIG. 41, after step S207 is executed, processing of the middle support pillars MHR and burying by a sacrificial film 62, processing of the middle members MSLT and burying by a sacrificial film 63, and processing of the middle contact plugs MCC and burying by a sacrificial film 64, are successively executed (S208). Note that the order of the processing of the middle support pillars MHR, the middle members MSLT, and the middle contact plugs MCC and the burying by the sacrificial films 62 to 64 is arbitrary.

As illustrated in FIG. 55 and FIG. 56, the staircase part is filled with the insulating layer 37, and is planarized by, for example, CMP. Next, in the coupling area CA, holes corresponding to the middle support pillars MHR are formed, and a sacrificial film 62 is buried in the holes. Next, slits corresponding to the middle members MSLT are formed, and a sacrificial film 63 is buried in the slits. Next, in the coupling area CA, holes corresponding to the middle contact plugs MCC are formed, and a sacrificial film 64 is buried in the holes.

As illustrated in FIG. 41, after step S208 is executed, the fourth layer stack is formed (S209).

As illustrated in FIG. 57 and FIG. 58, as a fourth layer stack before the WL replace, two sacrificial films 60c and two insulating layers 35 are alternately stacked one by one. The two sacrificial films 60c are, in the WL replace, replaced with two interconnect layers 34c functioning as the word lines WL5 and WL6, respectively.

As illustrated in FIG. 41, after step S209 is executed, similarly with step S107 described with reference to FIG. 9 of the first embodiment, memory holes corresponding to the middle memory pillars MMP are processed (formed), and a sacrificial film 61 is buried in the memory holes (S210).

As illustrated in FIG. 59 and FIG. 60, in the memory cell area MA, memory holes corresponding to the middle memory pillars MMP are formed. A lower end of each memory hole corresponding to the middle memory pillar MMP reaches the lower memory pillar LMP. Next, a sacrificial film 61 is buried in the memory holes corresponding to the middle memory pillars MMP. In other words, a stacked structure of the lower memory pillar LMP and the middle memory pillar MMP, which are filled with the sacrificial film 61, is formed.

As illustrated in FIG. 41, after step S210 is executed, the fifth layer stack is formed (S211).

As illustrated in FIG. 61 and FIG. 62, as a fifth layer stack before the WL replace, one sacrificial film 60d and one insulating layer 35 are stacked. The sacrificial film 60d is, in the WL replace, replaced with an interconnect layer 34d functioning as the word line WL7.

As illustrated in FIG. 42, after step S211 is executed, a staircase part corresponding to the upper tier T_{UCA} of the coupling area CA is formed (S212).

As illustrated in FIG. 63 and FIG. 64, staircase processing is performed on the fourth and fifth layer stacks, and terraces corresponding to the two sacrificial films 60c and one sacrificial film 60d are formed. That is, terraces corresponding to the word lines WL4 to WL6 are processed.

As illustrated in FIG. 42, after step S212 is executed, processing of the upper support pillars UHR and burying by a sacrificial film 62, processing of the upper members USLT and burying by a sacrificial film 63, and processing of the upper contact plugs UCC and burying by a sacrificial film 64, are successively executed (S213). Note that the order of the processing of the upper support pillars UHR, the upper members USLT, and the upper contact plugs UCC and the burying by the sacrificial films 62 to 64 is arbitrary.

As illustrated in FIG. 65 and FIG. 66, the staircase part is filled with the insulating layer 37, and is planarized by, for example, CMP. Next, in the coupling area CA, holes corresponding to the upper support pillars UHR are formed, and a sacrificial film 62 is buried in the holes. Next, slits corresponding to the upper members USLT are formed, and a sacrificial film 63 is buried in the slits. Next, in the coupling area CA, holes corresponding to the upper contact plugs UCC are formed, and a sacrificial film 64 is buried in the holes.

As illustrated in FIG. 42, after step S213 is executed, the sixth layer stack is formed (S214).

As illustrated in FIG. 67 and FIG. 68, as a sixth layer stack before the WL replace, three sacrificial films 60d and three insulating layers 35 are alternately stacked one by one. The three sacrificial films 60d are, in the WL replace, replaced with three interconnect layers 34d functioning as the word lines WL8 and WL9 and select gate line SGD, respectively.

As illustrated in FIG. 42, after step S214 is executed, a staircase part corresponding to the top tier T_{TCA} of the coupling area CA is formed (S215).

As illustrated in FIG. 69 and FIG. 70, staircase processing is performed on the sixth layer stack, and terraces corresponding to the three sacrificial films 60d are formed. That is, terraces corresponding to the word lines WL7 to WL9 are processed.

As illustrated in FIG. 42, after step S215 is executed, processing of the top support pillars THR and burying by a sacrificial film 62, processing of the top members TSLT and burying by a sacrificial film 63, and processing of the top contact plugs TCC and burying by a sacrificial film 64, are successively executed (S216). Note that the order of the processing of the top support pillars THR, the top members TSLT, and the top contact plugs TCC and the burying by the sacrificial films 62 to 64 is arbitrary.

As illustrated in FIG. 71 and FIG. 72, the staircase part is filled with the insulating layer 37, and is planarized by, for example, CMP. Next, in the coupling area CA, holes corresponding to the top support pillars THR are formed, and a sacrificial film 62 is buried in the holes. Thereby, the support pillars HR, in which the sacrificial film 62 is buried, are formed. Next, slits corresponding to the top members TSLT are formed, and a sacrificial film 63 is buried in the slits. Thereby, the members SLT, in which the sacrificial film 63 is buried, are formed. Next, in the coupling area CA, holes corresponding to the top contact plugs TCC are formed, and a sacrificial film 64 is buried in the holes. Thereby, the contact plugs CC, in which the sacrificial film 64 is buried, are formed.

As illustrated in FIG. 42, after step S216 is executed, similarly with step S111 described with reference to FIG. 9 of the first embodiment, memory holes corresponding to the upper memory pillars UMP are processed (formed), and the memory pillars MP are formed (S217).

As illustrated in FIG. 73 and FIG. 74, in the memory cell area MA, memory holes corresponding to the upper memory pillars UMP are formed. A lower end of each memory hole corresponding to the upper memory pillar UMP reaches the middle memory pillar MMP. Next, the sacrificial films 61 in the memory holes are removed. Subsequently, a stacked film 42, a semiconductor film 41 and a core film 40 are formed and filled in the memory holes, thus forming the memory pillars MP.

As illustrated in FIG. 42, after step S217 is executed, similarly with step S112 described with reference to FIG. 9 of the first embodiment, the sacrificial films 62 in the support pillars HR are removed, and an insulator 38 is buried in the holes (S218).

Next, similarly with step S113 described with reference to FIG. 9 of the first embodiment, the sacrificial films 63 in the members SLT are removed (S219).

Subsequently, similarly with step S114 described with reference to FIG. 9 of the first embodiment, the SL replace and the WL replace are successively executed (S220).

Next, similarly with step S115 described with reference to FIG. 9 of the first embodiment, a spacer SP and a conductor LI are buried in the member SLT (S221).

Subsequently, similarly with step S116 described with reference to FIG. 9 of the first embodiment, the sacrificial films 64 in the contact plugs CC are removed, and a conductor 39 is buried in the holes (S222). Thereby, the configuration of the memory cell array 11, which was described with reference to FIG. 38 and FIG. 39, is formed.

### 2.5. Advantageous Effects According to Present Embodiment

With the configuration according to the present embodiment, the same advantageous effects as in the first embodiment are obtained.

### 3. Third Embodiment

Next, a third embodiment is described. In the third embodiment, a configuration of the contact plug CC, which is different from the first embodiment, is described. Hereinafter, different points from the first embodiment are mainly described.

### 3.1. Planar Layout of Coupling Area

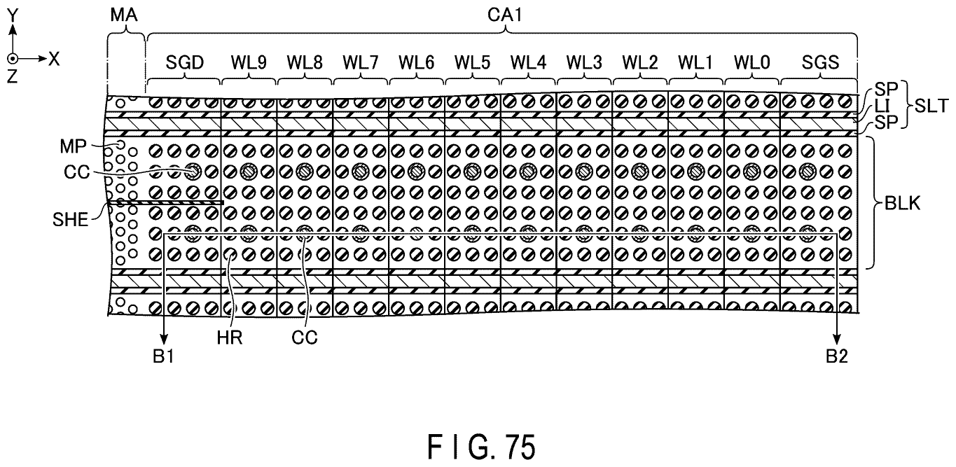

First, referring to FIG. 75, an example of a planar layout of the coupling area CA1 is described. FIG. 75 is a plan view illustrating an example of the planar layout of the coupling area CA1. FIG. 75 illustrates the coupling area CA1 corresponding to one block BLK, and a part of the memory cell area MA located near the coupling area CA1. Note that in the example illustrated in FIG. 75, for the purpose of simpler description, only one member SHE is representatively shown in the block BLK. In addition, in the example illustrated in FIG. 75, a part of interlayer insulating films is omitted.

As illustrated in FIG. 75, like the first embodiment, in the coupling area CA1, terraces, which correspond to the select gate line SGD, the word lines WL9 to WL0, and the select gate line SGS, are successively provided from the memory cell area MA toward an X-directional end portion (toward the right on the drawing sheet).

The configurations and arrangements of the memory pillars MP of the memory cell area MA, the members SLT and SHE, and the support pillars HR of the coupling area CA1, are the same as those in the first embodiment.

The contact plug CC of the present embodiment is a contact that extends in the Z direction and penetrates the terrace of the corresponding interconnect layer 34, and the interconnect layers 34 located under the corresponding interconnect layer 34. For example, the contact plug CC includes a projecting portion that projects concentrically on the XY plane at a coupling portion with the corresponding terrace. The contact plug CC is electrically coupled to the corresponding terrace via the projecting portion, and is not electrically coupled to the interconnect layers 34 located thereunder. In addition, a lower end of each contact plug CC reaches the semiconductor layer 32, but is not electrically coupled to the semiconductor layer 32. That is, the contact plug CC is electrically coupled to the terrace of the interconnect layer 34 that corresponds to any one of the select gate line SGS, the word lines WL0 to WL9, and the select gate line SGD.

### 3.2. Cross-Sectional Configuration of Coupling Area

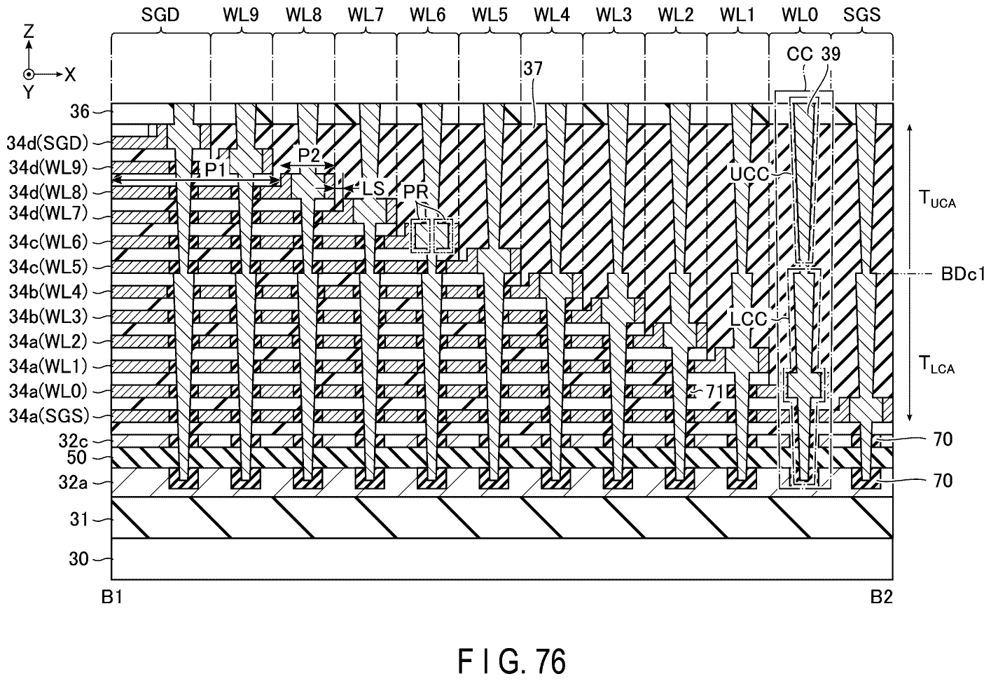

Referring to FIG. 76, an example of a cross-sectional configuration of the coupling area CA is described. FIG. 76 is a cross-sectional view of the coupling area CA1 along line B1-B2 in FIG. 75. Note that in the example illustrated in FIG. 76, the depiction of support pillars HR is omitted for the purpose of simpler illustration.

As illustrated in FIG. 76, in the coupling area CA, a staircase part composed of terraces (plug coupling portions) of interconnect layers 34 is formed. In the interconnect layer 34 of the present embodiment, the thickness of the terrace is increased. That is, the interconnect layer 34 includes a first portion P1 that is a central portion extending in the X direction, and a second portion P2 provided at an end portion (terrace) of the first portion P1 in the X direction. The thickness of the second portion P2 is greater than the thickness of the first portion P1. On the upper and lower sides of the second portion P2, a second portion P2 (a large thickness portion) of another interconnect layer 34 is not provided. A plurality of second portions P2 of the interconnect layers 34 are arranged in the X direction. Two second portions P2, which neighbor each other in the X direction, are spaced apart by a distance LS in the X direction, such that the two second portions P2 are not electrically coupled. Note that the distance LS is arbitrary.

The contact plug CC passes through the corresponding second portion P2 (terrace) and the first portions P1 of other interconnect layers 34 located below the second portion P2. Hereinafter, such a contact plug CC is also described as “through-contact”. The heights of contact plugs CC corresponding to the respective terraces are substantially equal. The contact plug CC includes a projecting portion PR that is provided in the same layer as the second portion P2. The projecting portion PR has a substantially cylindrical shape. A side surface of the projecting portion PR is in contact with the second portion P2. Note that a lower surface of the projecting portion PR may be electrically coupled to the terrace. The thickness (height) of the projecting portion PR is substantially equal to that of the second portion P2.

An insulator 71 is provided between the contact plug CC and the first portion P1 of the interconnect layer 34 through which the contact plug CC passes. The insulator 71 has an annular shape surrounding the side surface of the contact plug CC. By the insulator 71, the contact plug CC is not electrically coupled to the first portion P1 of the interconnect layer 34.

A lower end of the contact plug CC reaches, for example, the semiconductor layer 32a. Insulators 70 are provided between the contact plug CC and the semiconductor layers 32a and 32c. The insulator 70 provided in the same layer as the semiconductor layer 32c surrounds the side surface of the contact plug CC. The insulator 70 provided in the same layer as the semiconductor layer 32a surrounds the side surface and a bottom surface of the contact plug CC. By the insulators 70, the contact plug CC is not electrically coupled to the semiconductor layer 32. For example, the insulators 70 and 71 include silicon oxide.

Like the first embodiment, the contact plug CC includes the lower contact plug LCC and the upper contact plug UCC.

### 3.3. Manufacturing Method of Contact Plug

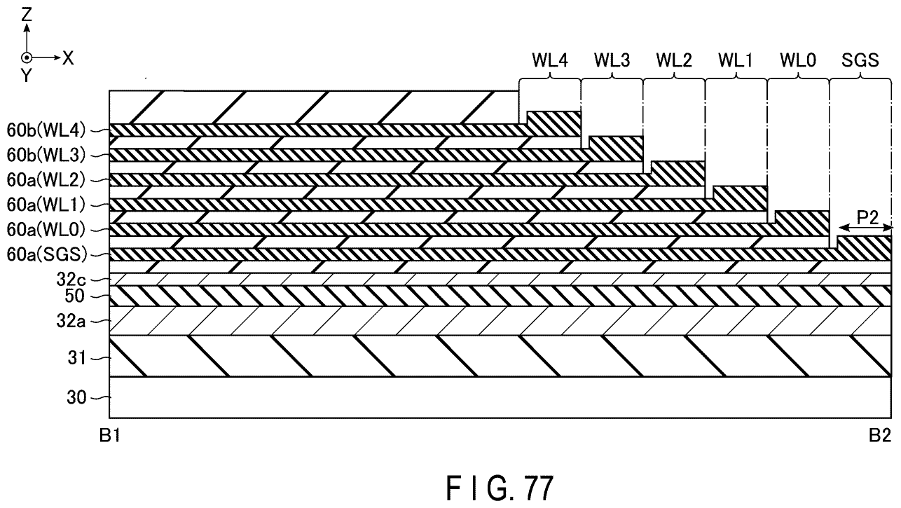

Next, referring to FIG. 77 to FIG. 81, a manufacturing method of the contact plug CC is described. FIG. 77 to FIG. 81 are views illustrating examples of cross-sectional configurations of the coupling area CA in the manufacturing process of the memory cell array 11. In the description below, manufacturing steps from the processing of the lower contact plugs LCC up to the burying by a sacrificial film 64 are described. Note that in the cross-sectional views of the manufacturing steps illustrated below, the depiction of support pillars HR is omitted in order to make the drawings simpler.

The general flow of the manufacturing method of the memory cell array 11 of the third embodiment is the same as in the flowchart described with reference to FIG. 9 of the first embodiment. The manufacturing method of the third embodiment differs from that of the first embodiment, with respect to the staircase processing in step S104, the processing method of the lower contact plugs LCC in step S105, the staircase processing in step S109, and the processing method of the upper contact plugs UCC in step S110.

As illustrated in FIG. 77, for example, like steps S101 to S103 described using FIG. 9 of the first embodiment, the processing is executed up to the formation of the lower layers of the middle layer stack. Next, in step S104, at first, the staircase part corresponding to the lower tier T_{LCA} of the coupling area CA is processed. More specifically, staircase processing is performed on the lower layer stack and the lower layers of the middle layer stack, and terraces corresponding to the sacrificial films 60a and 60b are formed. Next, second portions P2 by the sacrificial films 60a and 60b are formed. More specifically, after the terraces of the sacrificial films 60a and 60b are exposed, the sacrificial films 60 are formed, and the entire surface is covered with the sacrificial films 60. Next, the sacrificial film 60 is processed, and the second portions P2 are formed.

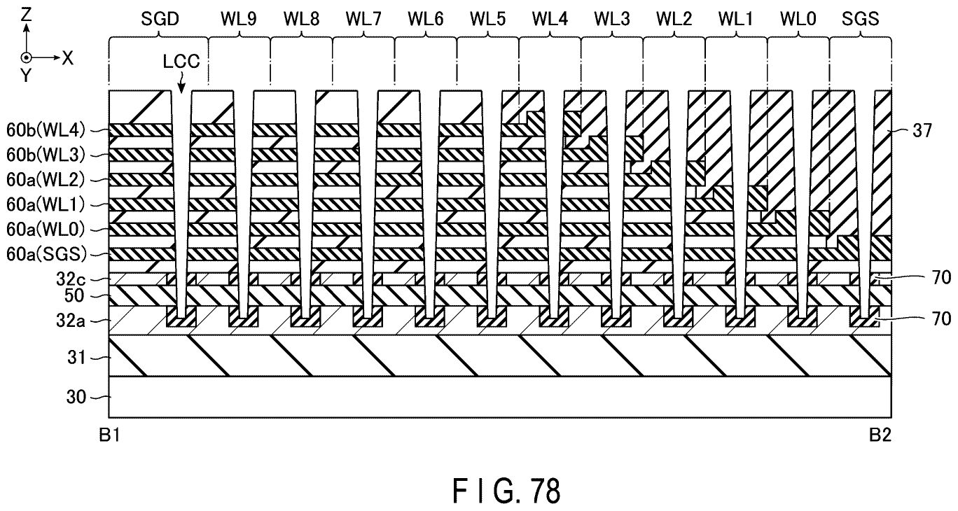

As illustrated in FIG. 78, the staircase part is first filled with the insulating layer 37, and is planarized by, for example, CMP. Next, holes corresponding to the lower contact plugs LCC are formed in the processing of the lower contact plugs LCC and the burying process by the sacrificial film 64 in step S105 described using FIG. 9 of the first embodiment. In the present embodiment, the holes corresponding to the lower contact plugs LCC are formed at positions corresponding to the terraces of the select gate line SGS, the word lines WL0 to WL9, and the select gate line SGD. A lower end of each hole reaches the semiconductor layer 32a. Next, the semiconductor layers 32a and 32c exposed on the lower side of the holes corresponding to the lower contact plugs LCC are oxidized, thereby forming insulators 70.

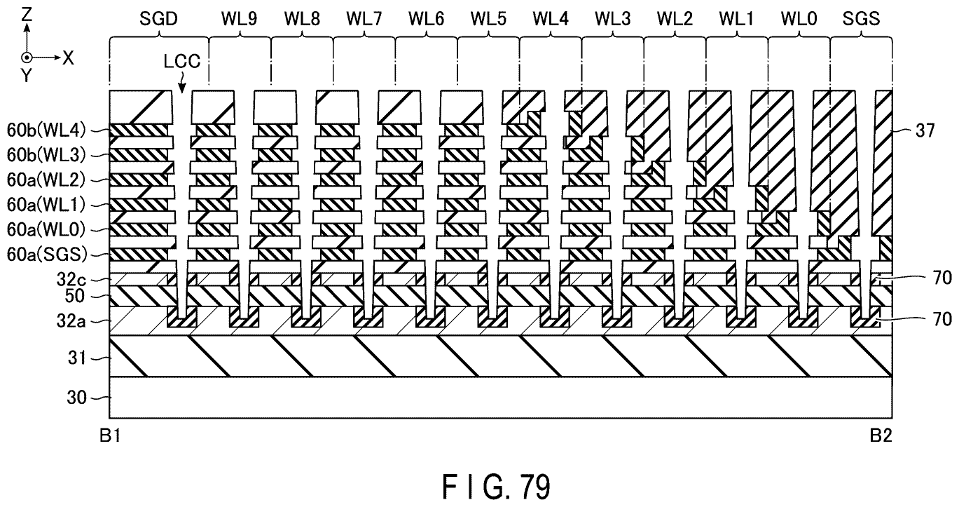

As illustrated in FIG. 79, recess etching is performed on the sacrificial films 60a and 60b from side surfaces of the holes corresponding to the lower contact plugs LCC.

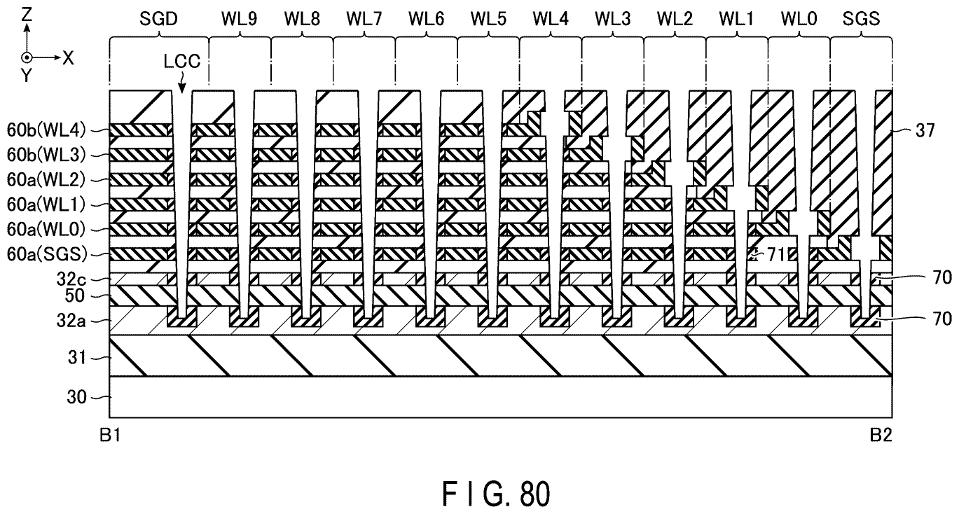

As illustrated in FIG. 80, an insulator 71 is formed and buried in recess areas corresponding to the first portions P1 of the sacrificial films 60a and 60b. More specifically, for example, the insulator 71, which has a thickness of ½ or more of the thickness of the first portion P1 and has a thickness of less than ½ of the thickness of the second portion P2, is conformally formed. Thereby, the recess portion of the first portion P1 is filled with the insulator 71, and the recess portion of the second portion P2 is not filled with the insulator 71. In this state, wet etching of the insulator 71 is executed, and the insulator 71 on the side surface of the hole and in the recess portion of the second portion P2 corresponding to the lower contact plug LCC is removed.

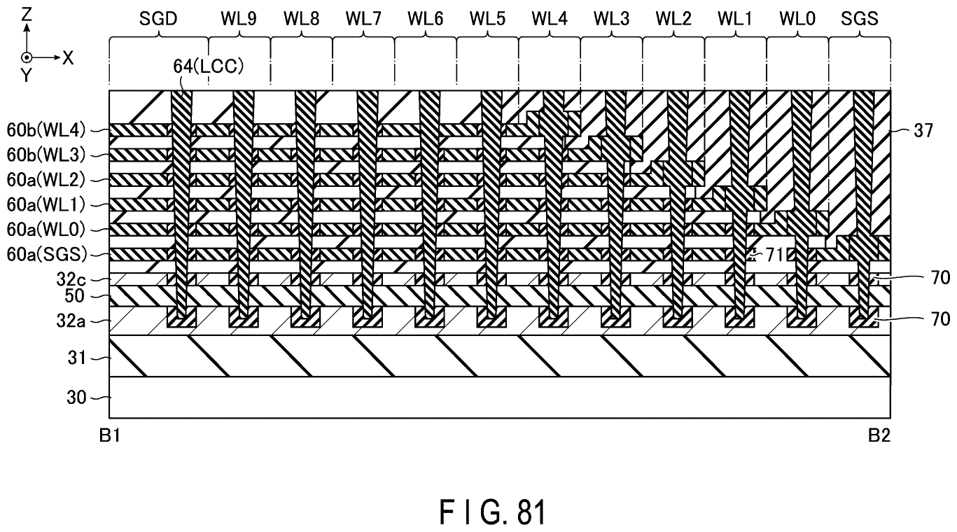

As illustrated in FIG. 81, a sacrificial film 64 is buried in the holes corresponding to the lower contact plugs LCC.

Steps S106 to S108 are the same as described using FIG. 9 of the first embodiment.

In steps S109 and S110, similar steps to steps S104 and S105 are executed, and thereby the through-contact plugs CC filled with the sacrificial film 64 are formed.

The steps of step S111 onwards are similar to the steps described using FIG. 9 of the first embodiment.

### 3.4. Advantageous Effects of Present Embodiment

With the configuration according to the present embodiment, the same advantageous effects as in the first embodiment can be obtained.

### 3.5. Modifications of Third Embodiment

Next, two modifications of the third embodiment are described. In the two modifications, a case is described in which the thicknesses of the insulating layers 35 formed on the interconnect layers 34 are different. Hereinafter, different points from the third embodiment are mainly described.

### 3.5.1. First Modification

First, a first modification is described. In the first modification, a case is described in which the thickness of the uppermost insulating layer 35 of each tier (lower tier T_{LMP}, middle tier T_{MMP}, upper tier T_{UMP}, lower tier T_{LCA}, and upper tier T_{UCA}) is greater than the thickness of the other insulating layers 35.

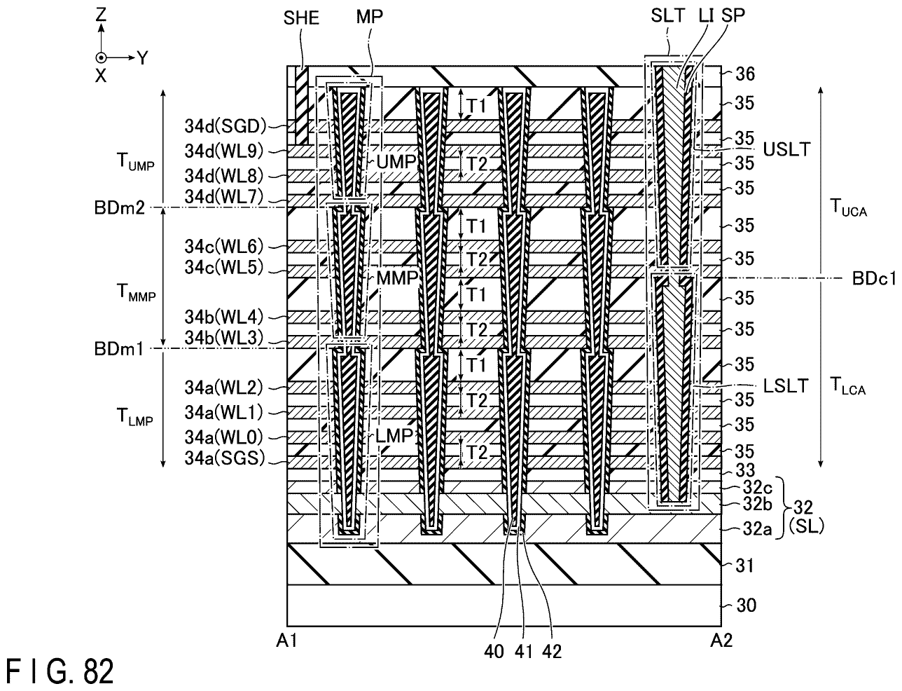

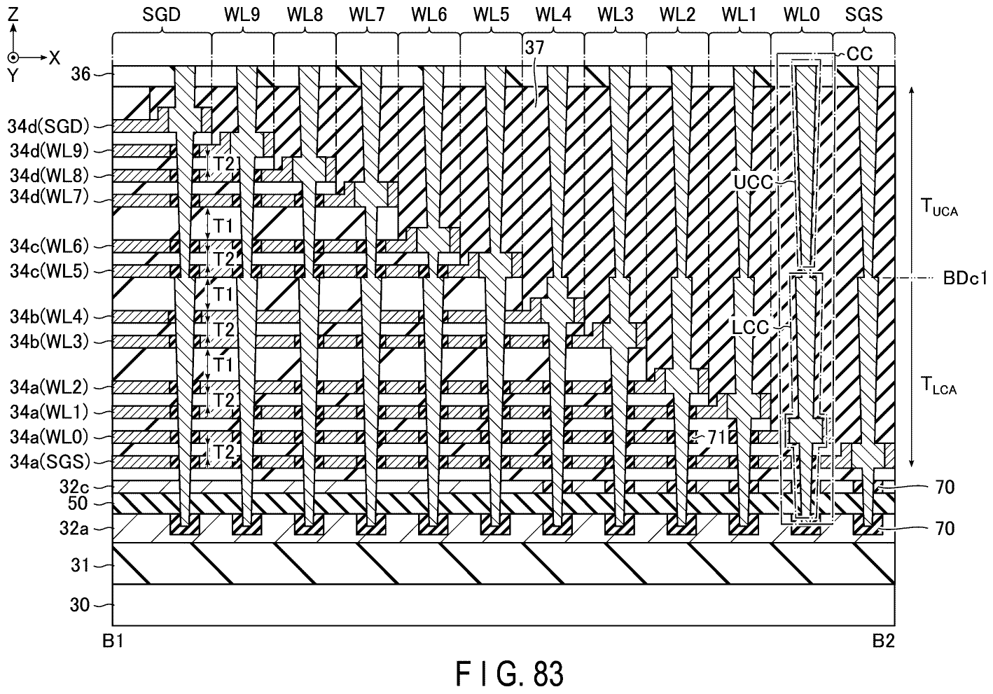

Referring to FIG. 82 and FIG. 83, an example of a cross-sectional configuration of the memory cell array 11 is described. FIG. 82 is a view illustrating an example of a cross-sectional configuration of the memory cell area MA. FIG. 83 is a view illustrating an example of a cross-sectional configuration of the coupling area CA1. Note that in the example illustrated in FIG. 83, the depiction of support pillars HR is omitted in order to make the description simpler.

As illustrated in FIG. 82 and FIG. 83, in the present modification, at a time of forming a layer stack (corresponding to steps S101, S103, S106, and S108 in FIG. 9), the thickness of the uppermost insulating layer 35 is made greater than the thickness of the lower insulating layers 35. In the other respects, the manufacturing method is the same as in the third embodiment. More specifically, for example, in step S101, at a time of forming the lower layer stack, the thickness of the insulating layer 35, which is provided on the sacrificial film 60a that is to be replaced with the interconnect layer 34a functioning as the word line WL2, is made greater than the thickness of the lower insulating layers 35. In step S103, at a time of forming the lower layers of the middle layer stack, the thickness of the insulating layer 35, which is provided on the sacrificial film 60b that is to be replaced with the interconnect layer 34b functioning as the word line WL4, is made greater than the thickness of the lower insulating layer 35. In step S106, at a time of forming the upper layers of the middle layer stack, the thickness of the insulating layer 35, which is provided on the sacrificial film 60c that is to be replaced with the interconnect layer 34c functioning as the word line WL6, is made greater than the thickness of the lower insulating layer 35. In step S108, at a time of forming the upper layer stack, the thickness of the insulating layer 35, which is provided on the sacrificial film 60d that is to be replaced with the interconnect layer 34d functioning as the select gate line SGD, is made greater than the thickness of the lower insulating layers 35.

For example, the thickness of each of the insulating layers 35, which are provided on the sacrificial films 60 that are to be replaced with the interconnect layers 34 functioning as the word lines WL2, WL4, and WL6 and the select gate line SGD, is set to be T1. In addition, the thickness of each of the other insulating layers 35 is set to be T2. In this case, the thickness T1 and the thickness T2 have a relationship of T1>T2. Note that the insulating layers 35, which are formed to be thick, are not limited to these. For example, in accordance with the number of times of staircase processing that is divisionally executed in the coupling area CA, the thickness of the uppermost insulating layer 35 at the time of each staircase processing may be made greater than the thickness of the lower insulating layers 35.

### 3.5.2. Second Modification

Next, a second modification is described. In the second modification, a case is described in which the thickness of the uppermost insulating layer 35 of each of the lower tier T_{LCA} and the upper tier T_{UCA} is greater than the thickness of the other insulating layers 35.

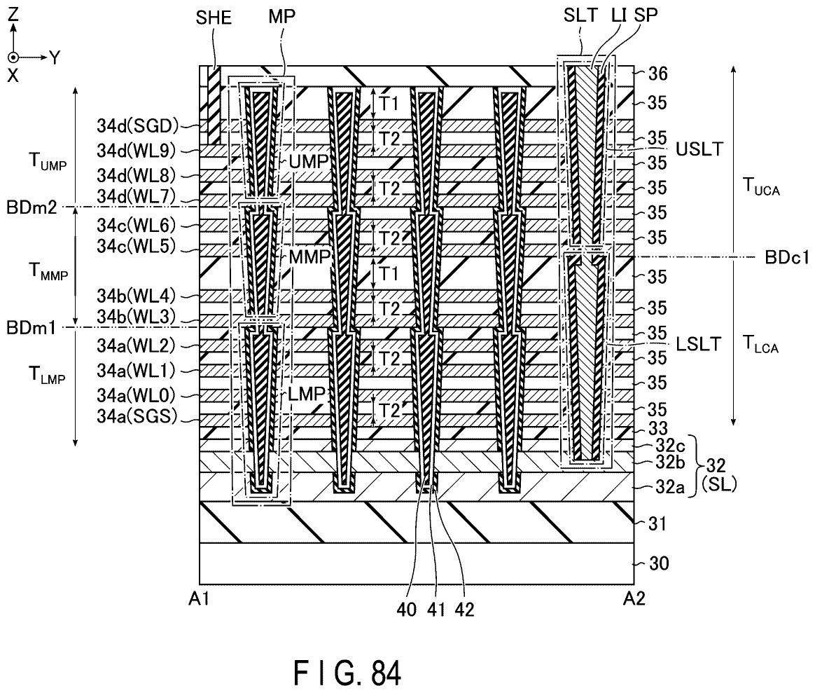

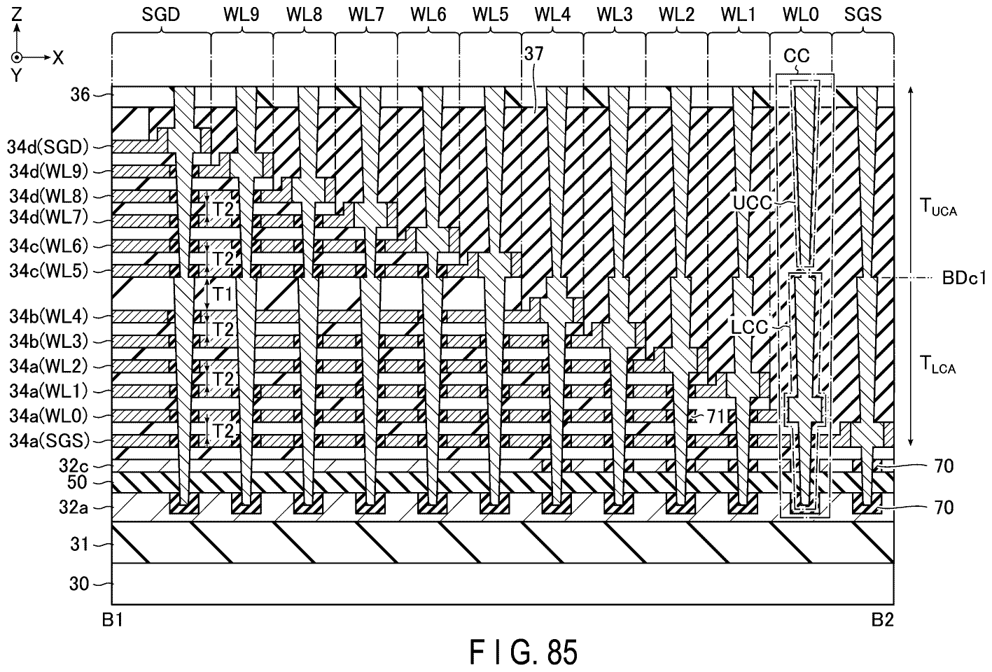

Referring to FIG. 84 and FIG. 85, an example of a cross-sectional configuration of the memory cell array 11 is described. FIG. 84 is a view illustrating an example of a cross-sectional configuration of the memory cell area MA. FIG. 85 is a view illustrating an example of a cross-sectional configuration of the coupling area CA1. Note that in the example illustrated in FIG. 85, the depiction of support pillars HR is omitted in order to make the description simpler.

As illustrated in FIG. 84 and FIG. 85, in the present modification, at a time of forming the lower layers of the middle layer stack and the upper layer stack (corresponding to steps S103 and S108 in FIG. 9), the thickness of the uppermost insulating layer 35 is made greater than the thickness of the lower insulating layers 35. In the other respects, the manufacturing method is the same as in the third embodiment. More specifically, for example, in step S103, at a time of forming the lower layers of the middle layer stack, the thickness of the insulating layer 35, which is provided on the sacrificial film 60b that is to be replaced with the interconnect layer 34b functioning as the word line WL4, is made greater than the thickness of the lower insulating layer 35. Further, in step S108, at a time of forming the upper layer stack, the thickness of the insulating layer 35, which is provided on the sacrificial film 60d that is to be replaced with the interconnect layer 34d functioning as the select gate line SGD, is made greater than the thickness of the lower insulating layers 35.

For example, the thickness of each of the insulating layers 35, which are provided on the sacrificial films 60 that are to be replaced with the interconnect layers 34 functioning as the word lines WL4 and the select gate line SGD, is set to be T1. In addition, the thickness of each of the other insulating layers 35 is set to be T2. In this case, the thickness T1 and the thickness T2 have a relationship of T1>T2.

### 3.5.3. Advantageous Effects According to First Modification and Second Modification

With the configurations according to the first modification and the second modification, the same advantageous effects as in the first embodiment are obtained.

With the configuration according to the first modification, some of the insulating layers 35 are formed to have large thickness. Thereby, for example, it is possible to suppress a decrease in thickness of insulating layers 35 due to the processing of the memory pillars MP, the members SLT, the support pillars HR, and the contact plugs CC, or due to the planarization of the insulating layer 37 by CMP or the like. Furthermore, with the configuration according to the first modification, the thickness of the insulating layer 35 corresponding to the boundary of two tiers is increased. Thereby, for example, it is possible to secure an area for forming a coupling portion that couples the lower memory pillar LMP and the middle memory pillar MMP, between the lower memory pillar LMP and the middle memory pillar MMP.

With the configuration according to the second modification, for example, it is possible to suppress a decrease in thickness of insulating layers 35 due to the processing of the members SLT, the support pillars HR, and the contact plugs CC, or due to the planarization of the insulating layer 37 by CMP or the like.

Note that the first modification and the second modification can be applied to the first embodiment or the second embodiment.

### 4. Fourth Embodiment

Next, a fourth embodiment is described. In the fourth embodiment, a configuration of the memory cell array 11, which is different from the first embodiment and third embodiment, is described. Hereinafter, different points from the first embodiment and third embodiment are mainly described.

### 4.1. Planar Layout of Coupling Area

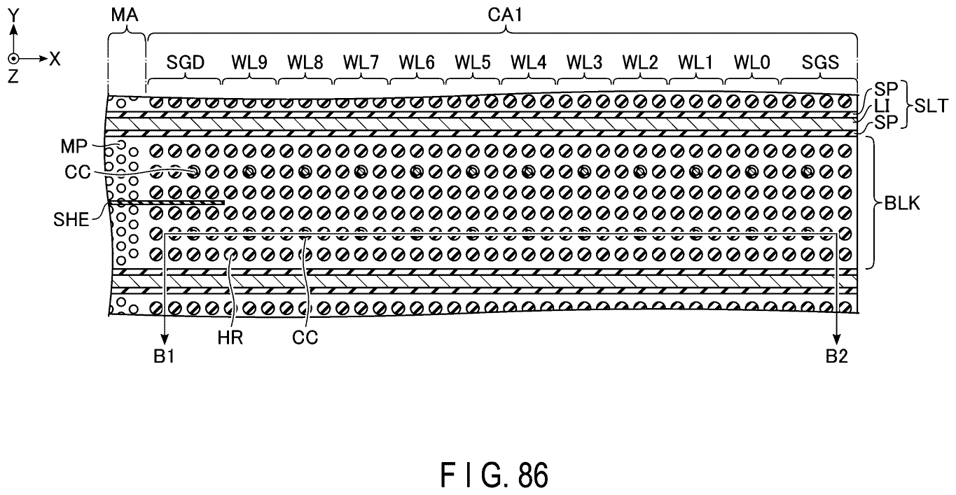

First, referring to FIG. 86, an example of a planar layout of the coupling area CA1 is described. FIG. 86 is a plan view illustrating an example of the planar layout of the coupling area CA1. FIG. 86 illustrates the coupling area CA1 corresponding to one block BLK, and a part of the memory cell area MA located near the coupling area CA1. Note that in the example illustrated in FIG. 86, for the purpose of simpler description, only one member SHE is representatively shown in the block BLK.

As illustrated in FIG. 86, in the coupling area CA1, plug coupling portions, which correspond to the select gate line SGD, the word lines WL9 to WL0, and the select gate line SGS, are successively provided from the memory cell area MA toward an X-directional end portion (toward the right on the drawing sheet). In the present embodiment, however, a staircase by a layer stack is not formed. That is, no terrace is provided. In the present embodiment, other interconnect layers 34 are provided above the plug coupling portions corresponding to the select gate line SGS and the word lines WL0 to WL9.

The planar layout of the memory pillar MP, the members SLT and SHE, the support pillar HR, and the contact plug CC is the same as in the first embodiment.

The contact plug CC of the present embodiment extends in the Z direction and passes through the interconnect layers 34 located above the plug coupling portion of the corresponding interconnect layer 34, and a lower end of the contact plug CC is in contact with the plug coupling portion. Thus, like the first embodiment, the height of the contact plug CC varies depending on the corresponding plug coupling portion (interconnect layer 34). A side wall by an insulator is provided on a side surface of the contact plug CC. By the side wall, the contact plug CC is not electrically coupled to the interconnect layers 34 provided above the plug coupling portion. That is, the contact plug CC is electrically coupled to the plug coupling portion of the interconnect layer 34 that corresponds to any one of the select gate line SGS, the word lines WL0 to WL9, and the select gate line SGD.

### 4.2. Cross-Sectional Configuration of Coupling Area

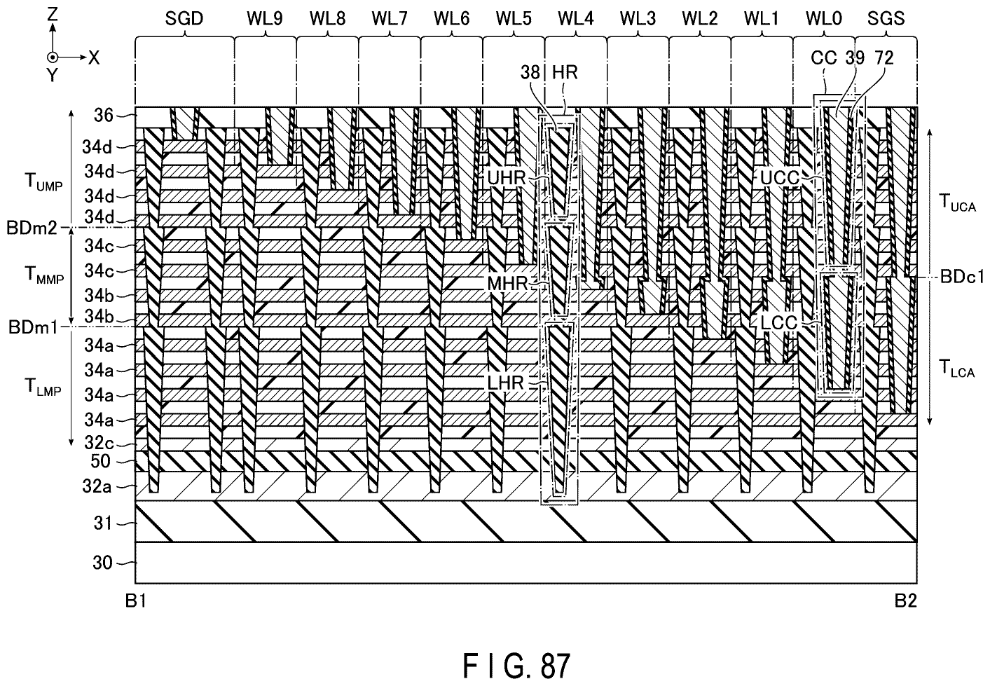

Next, referring to FIG. 87, an example of a cross-sectional configuration of the coupling area CA is described. FIG. 87 is a cross-sectional view of the coupling area CA1 along line B1-B2 in FIG. 86. Note that in the example illustrated in FIG. 87, similarly with FIG. 7, in the plug coupling portion of the select gate line SGD, two support pillars HR passing through the plug coupling portion are illustrated in such a manner as to correspond to the cross section along line B1 to B2. On the other hand, in each plug coupling portion of the word lines WL0 to WL9 and the select gate line SGS, the depiction of some support pillars HR is omitted for the purpose of simpler illustration, and one support pillar HR passing through each plug coupling portion is illustrated. In each plug coupling portion of the word lines WL0 to WL9 and the select gate line SGS, although the depiction of some support pillars HR is omitted, the support pillars HR are provided in each plug coupling portion in the same arrangement as in the plug coupling portion of the select gate line SGD.

As illustrated in FIG. 87, in the coupling area CA of the present embodiment, a staircase by a plurality of interconnect layers 34 is not formed. In other words, X-directional end portions of a plurality of interconnect layers 34 are not led out in a staircase fashion. The lengths in the X direction of the interconnect layers 34 are substantially equal. Thus, in the present embodiment, the insulating layer 37 is omitted.

The support pillar HR of the present embodiment includes a lower support pillar LHR, a middle support pillar MHR, and an upper support pillar UHR. The middle support pillar MHR is provided on the lower support pillar LHR. The upper support pillar UHR is provided on the middle support pillar MHR. In the present embodiment, the boundary position of tiers of the memory pillar MP is equal to the boundary position of tiers of the support pillar HR. That is, the support pillar HR, like the memory pillar MP, has a configuration of three tiers which includes the lower tier T_{LMP}, the middle tier T_{MMP}, and the upper tier T_{UMP}. Like the memory pillar MP, the support pillar HR is divisionally processed three times. Note that in the example illustrated in FIG. 87, although the support pillar HR is filled with the insulator 38, the support pillar HR may have the same configuration as the memory pillar MP. That is, the support pillar HR may be filled with the core film 40, the semiconductor film 41, and the stacked film 42. In the coupling area CA, the SL replace is not executed, that is, the insulating layer 50 is not replaced with the semiconductor layer 32b. Thus, even where the support pillar HR has the same configuration as the memory pillar MP, the support pillar HR is not electrically coupled to the semiconductor layer 32.

Like the lower memory pillar LMP, the lower support pillar LHR passes through the lower tier T_{LMP}. That is, the lower support pillar LHR passes through the four interconnect layers 34a functioning as the select gate line SGS and the word lines WL0 to WL2. A lower surface of the lower support pillar LHR reaches, for example, the semiconductor layer 32a.

Like the middle memory pillar MMP, the middle support pillar MHR passes through the middle tier T_{MM}e. That is, the middle support pillar MHR passes through the two interconnect layers 34b functioning as the word lines WL3 and WL4, and the two interconnect layers 34c functioning as the word lines WL5 and WL6. A lower surface of the middle support pillar MHR is in contact with an upper surface of the lower support pillar LHR at the boundary BDm1.

Like the upper memory pillar UMP, the upper support pillar UHR passes through the upper tier T_{UMP}. That is, the upper support pillar UHR passes through the four interconnect layers 34d functioning as the word lines WL7 to WL9 and the select gate line SGD. A lower surface of the upper support pillar UHR is in contact with an upper surface of the middle support pillar MHR at the boundary BDm2.

Each of the lower support pillar LHR, the middle support pillar MHR, and the upper support pillar UHR has, for example, a taper shape with a greater diameter at an upper end than at a lower end thereof. In other words, each of the lower support pillar LHR, the middle support pillar MHR, and the upper support pillar UHR has, for example, a truncated conical shape with a lower surface being smaller than an upper surface thereof. Thus, the boundaries BDm1 and BDm2 between the lower support pillar LHR, the middle support pillar MHR, and the upper support pillar UHR can be confirmed by observing cross-sectional shapes.

Next, the contact plug CC is described. In the coupling area CA, on the plug coupling portion of each interconnect layer 34, a corresponding contact plug CC is provided. In other words, a lower end of the contact plug CC is in contact with the plug coupling portion of the corresponding interconnect layer 34. The contact plug CC extends in the Z direction. The contact plug CC passes through the interconnect layers 34 located above the corresponding plug coupling portion. The shape (height) of the contact plug CC varies depending on the plug coupling portion to which the contact plug CC is coupled. The contact plug CC includes a conductor 39, and an insulator 72 covering a side surface of the conductor 39. A bottom surface of the conductor 39 is in contact with the corresponding plug coupling portion. By the insulator 72, the side surface of the contact plug CC is not electrically coupled to the interconnect layers 34 through which the contact plug CC penetrates (passes). For example, the insulator 72 includes silicon oxide.

Like the first embodiment, the contact plug CC includes the lower contact plug LCC and the upper contact plug UCC. Hereinafter, like the first embodiment, a case is described in which the boundary position of tiers of the contact plug CC is equal to the the boundary position of tiers of the member SLT. Note that the boundary position of tiers of the member SLT may be equal to the boundary positions of tiers of the memory pillar MP and the support pillar HR, or may be different from the boundary positions of tiers of the memory pillar MP, the support pillar HR, and the contact plug CC.

### 4.3. Boundaries of Support Pillar and Contact Plug

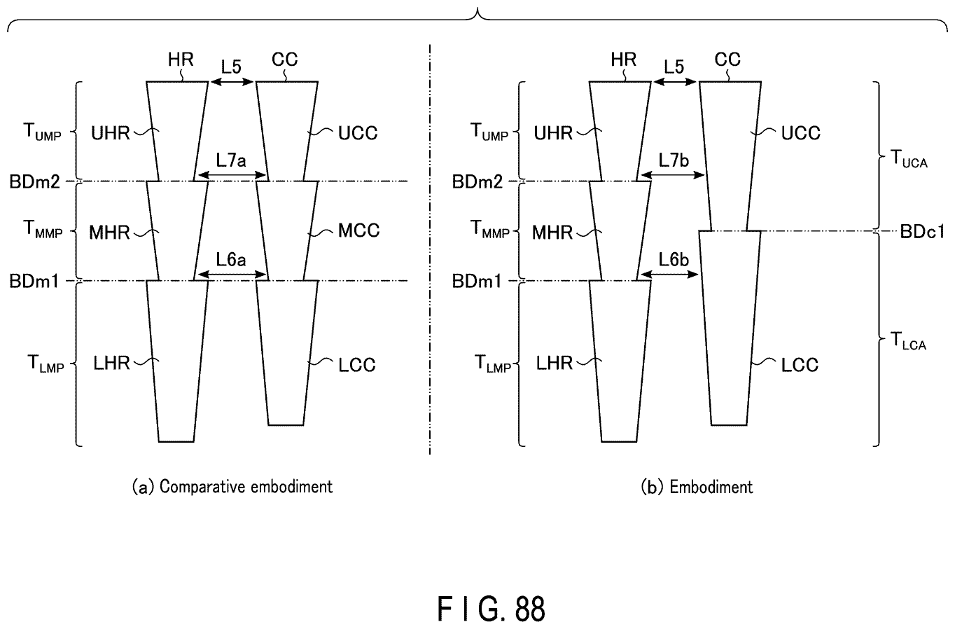

Next, referring to FIG. 88, boundaries of the support pillar HR and the contact plug CC are described. FIG. 88 is a conceptual view illustrating boundaries of the support pillar HR and the contact plug CC. FIG. 88 illustrates, as a comparative embodiment, a case in which the number of boundaries is equal in regard to the support pillar HR and the contact plug CC. Note that the shape and the number of boundaries of the support pillar HR are equal between the comparative embodiment and an embodiment.

First, the comparative embodiment is described.

As illustrated in part (a) of FIG. 88, for example, in the comparative embodiment, the number of tiers (the number of boundaries) is equal between the support pillar HR and the contact plug CC. In this case, the tier boundaries of the support pillar HR and the contact plug CC are located between the same interconnect layers 34.

For example, the support pillar HR includes a lower support pillar LHR, a middle support pillar MHR, and an upper support pillar UHR. The contact plug CC includes a lower contact plug LCC, a middle contact plug MCC, and an upper contact plug UCC. For example, a boundary BDm1 between the lower support pillar LHR and the middle support pillar MHR is equal to a boundary between the lower contact plug LCC and the middle contact plug MCC. In addition, a boundary BDm2 between the middle support pillar MHR and the upper support pillar UHR is equal to a boundary between the middle contact plug MCC and the upper contact plug UCC.

For example, a distance between the upper end of the support pillar HR (upper support pillar UHR) and the upper end of the contact plug CC (upper contact plug UCC), which neighbor each other, is defined as L5. A distance between the middle support pillar MHR and the middle contact plug MCC in the vicinity of the boundary BDm1 is defined as L6a. A distance between the upper support pillar UHR and the upper contact plug UCC in the vicinity of the boundary BDm2 is defined as L7a. Each of the support pillar HR and the contact plug CC has a taper shape at each of the divided parts thereof. Thus, the distance L5 and the distance L6a have a relationship of L5<L6a. Similarly, the distance L5 and the distance L7a have a relationship of L5<L7a.

Next, the embodiment is described.

As illustrated in part (b) of FIG. 88, in the embodiment, the support pillar HR includes three tiers. The contact plug CC includes two tiers. In other words, the support pillar HR includes two boundaries BDm1 and BDm2. The contact plug CC includes one boundary BDc1. That is, the number of tiers (the number of boundaries) is different between the support pillar HR and the contact plug CC.

In this case, as described with reference to FIG. 87, the boundaries BDm1 and BDm2 of the support pillar HR, and the boundary BDc1 of the contact plug CC, are located at different positions between the interconnect layers 34.

Each of the support pillar HR and contact plug CC has a taper shape at each of the divided parts (each of the tiers) thereof.

For example, a distance between the upper end of the support pillar HR (upper support pillar UHR) and the upper end of the contact plug CC (upper contact plug UCC), which neighbor each other, is defined as L5 that is identical to the comparative embodiment of part (a) of FIG. 88. A distance between the support pillar HR and the contact plug CC at the boundary BDm1 is defined as L6b. A distance between the support pillar HR and the contact plug CC at the boundary BDm2 is defined as L7b. The distance L5 and the distance L6b have a relationship of L5<L6b. Similarly, the distance L5 and the distance L7b have a relationship of L5<L7b.

In the case of the comparative embodiment of part (a) of FIG. 88, for example, the diameter of the middle contact plug MCC is smallest at the boundary BDm1. On the other hand, in the case of the embodiment of part (b), the boundary BDm1 is located at an intermediate portion of the lower contact plug LCC. Accordingly, the distance L6a and the distance L6b, if compared, have a relationship of L6a>L6b. Similarly, in the case of the comparative embodiment of part (a), the diameter of the upper contact plug UCC is smallest at the boundary BDm2. On the other hand, in the case of the embodiment of part (b), the boundary BDm2 is located at an intermediate portion of the upper contact plug UCC. Accordingly, the distance L7a and the distance L7b, if compared, have a relationship of L7a>L7b.

Therefore, in the case of the configuration according to the present embodiment, it is possible to suppress an increase in distance between the support pillar HR and the contact plug CC due to the taper shape. In other words, it is possible to suppress an increase in distance between the support pillar HR and the contact plug CC by providing the boundary position of the support pillar HR and the boundary position of the contact plug CC between mutually different interconnect layers 34. In the configuration according to the present embodiment, the contact plug CC passes through the interconnect layers 34 located above the plug coupling portion. Thus, like the support pillar HR, the contact plug CC functions as a pillar that supports the stacked structure including voids at the time of the WL replace. By suppressing the increase in distance between the support pillar HR and the contact plug CC, bending of the layer stack due to the WL replace can be suppressed above the plug coupling portion.

### 4.4. Manufacturing Method of Memory Cell Array

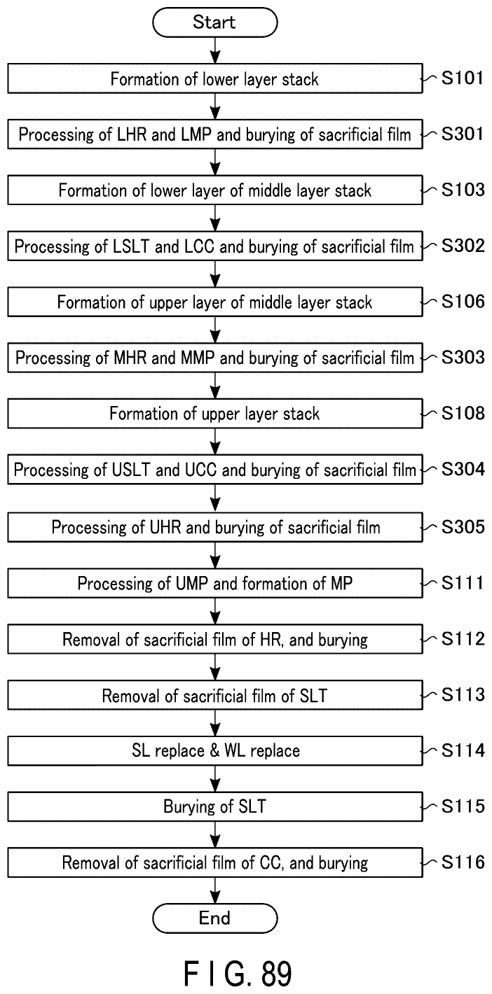

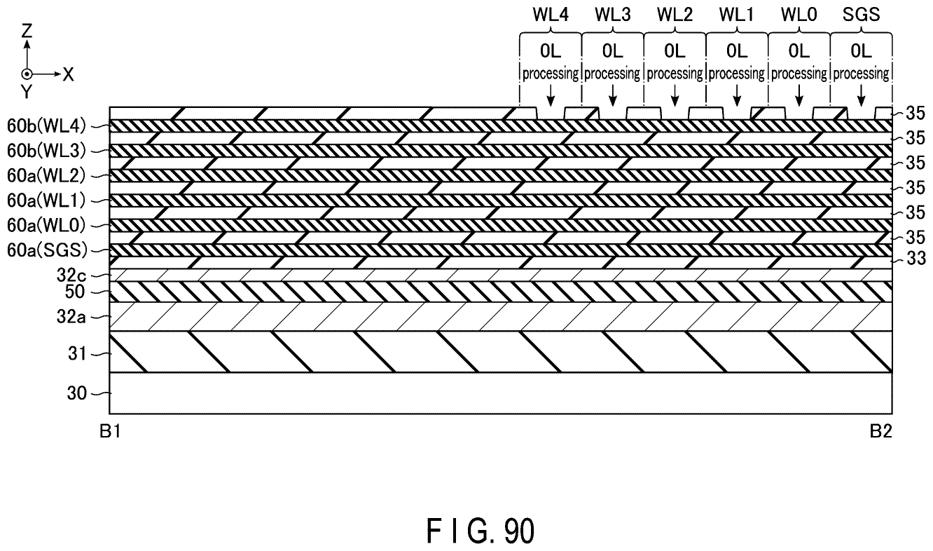

Next, referring to FIG. 89 to FIG. 98, a manufacturing method of the memory cell array 11 is described. FIG. 89 is a flowchart illustrating an example of a manufacturing process of the memory cell array 11. FIG. 90 to FIG. 98 are views illustrating examples of the cross-sectional configuration of the coupling area CA in the manufacturing process of the memory cell array 11. Note that in the examples illustrated in FIG. 90 to FIG. 98, the depiction of support pillars HR is omitted in order to make the description simpler. In the description below, attention is paid to manufacturing steps of processing the contact plugs CC.

As illustrated in FIG. 89, for example, like step S101 described using FIG. 9 of the first embodiment, processing is performed up to the formation of the lower layer stack.

After step S101 is executed, the processing of the lower support pillars LHR and the burying by the sacrificial film 62, and the processing of the lower memory pillars LMP and the burying by the sacrificial film 61, are successively executed (S301). Note that the order of the processing of the lower support pillars LHR and the lower memory pillars LMP and the burying by the sacrificial films 61 and 62 is arbitrary. In addition, the lower support pillars LHR and the lower memory pillars LMP may be collectively processed. In this case, the holes corresponding to the lower support pillars LHR and the lower memory pillars LMP can be filled with the same sacrificial material.

As described with reference to FIG. 9 of the first embodiment, after step S301 is executed, lower layers of the middle layer stack are formed (S103).

After step S103 is executed, the processing of the lower members LSLT and the burying by the sacrificial film 63, and the processing of the lower contact plugs LCC and the burying by the sacrificial film 64, are successively executed (S302). Note that the order of the processing of the lower members LSLT and lower contact plugs LCC and the burying by the sacrificial films 63 and 64 is arbitrary. In the present embodiment, at a time of forming the holes corresponding to the lower contact plugs LCC and the upper contact plugs UCC, the processing of the holes is divisionally executed multiple times. More specifically, while the number of interconnect layers 34 that are processed at one time is increased by a power of 2, the etching of selected holes is repeated, and thereby holes with different heights (depths) are formed.

With reference to FIG. 90 to FIG. 93, the processing method of the lower contact plugs LCC is described in detail.

As illustrated in FIG. 90, first, holes corresponding to the uppermost insulating layer 35 are processed in each plug coupling portion of the select gate line SGS and the word lines WL0 to WL4 (0L processing illustrated in FIG. 90). At this step, the sacrificial film 60 is not processed. Thereby, the formation of the hole of the lower contact plug LCC corresponding to the plug coupling portion of the word line WL4 is completed.

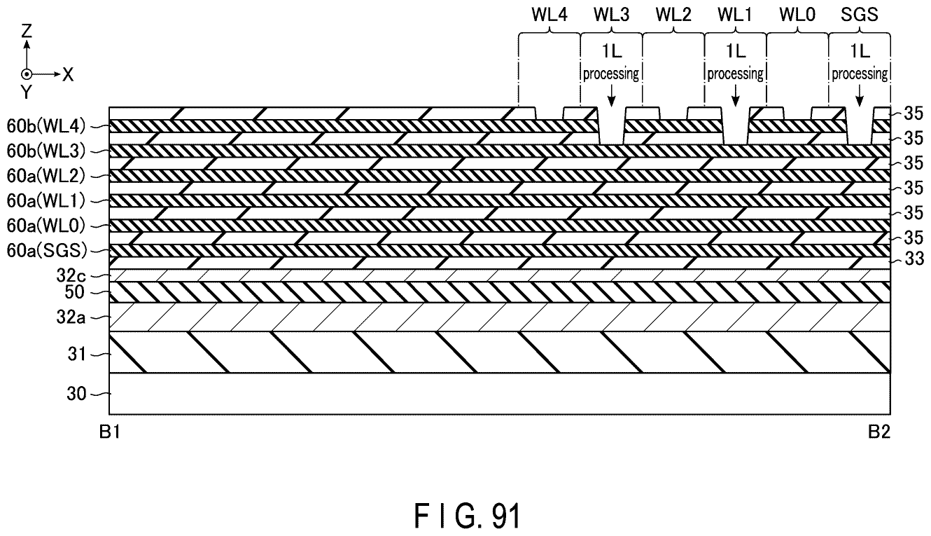

As illustrated in FIG. 91, in each plug coupling portion of the select gate line SGS and the word lines WL1 and WL3, a sacrificial film 60 for one layer and an insulating layer 35 for one layer in the hole are processed (1L processing illustrated in FIG. 91). That is, the sacrificial film 60 for 2⁰=1 layer is processed. Thereby, the formation of the hole of the lower contact plug LCC corresponding to the plug coupling portion of the word line WL3 is completed.

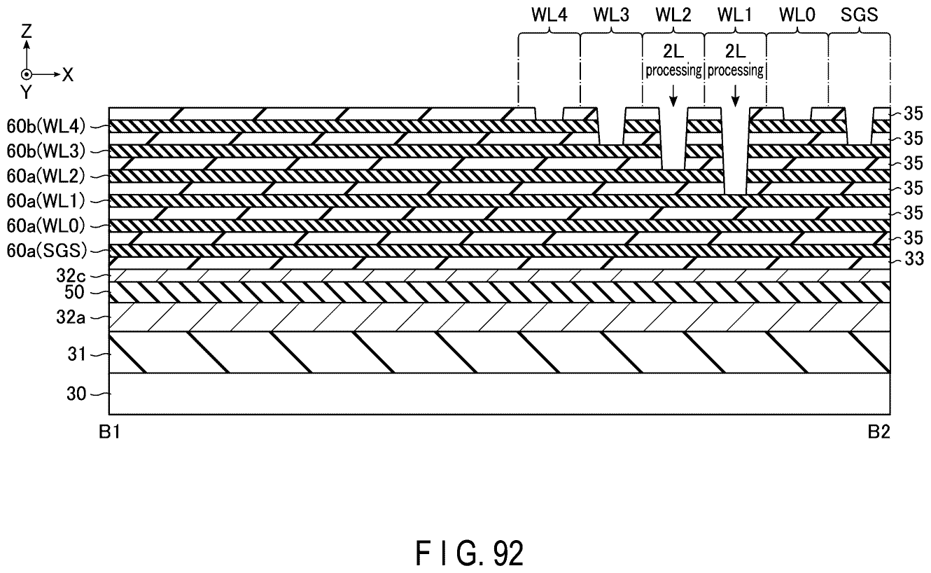

As illustrated in FIG. 92, in each plug coupling portion of the word lines WL1 and WL2, sacrificial films 60 for two layers and insulating layers 35 for two layers in the hole are processed (2L processing illustrated in FIG. 92). That is, the sacrificial films 60 for 2¹=2 layers are processed. Thereby, the formation of the holes of the lower contact plugs LCC corresponding to the plug coupling portions of the word lines WL1 and WL2 is completed.

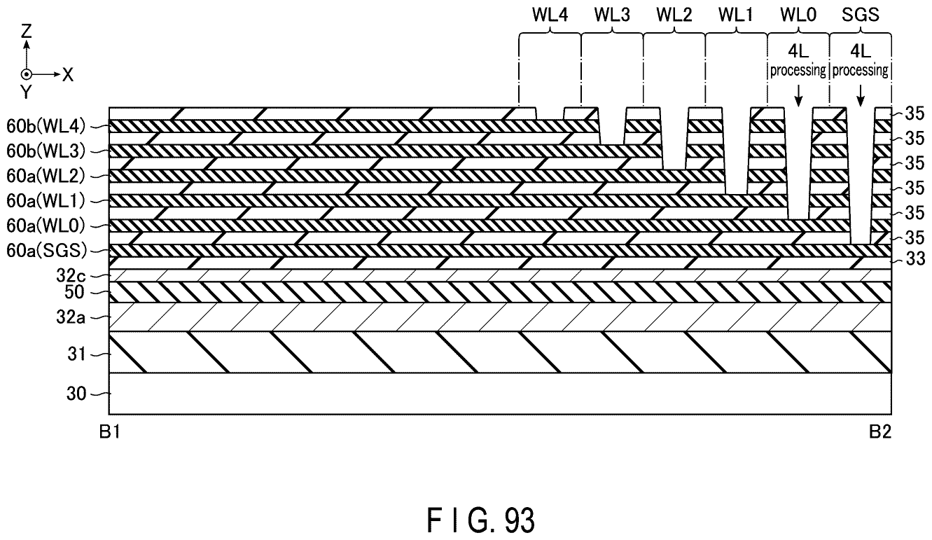

As illustrated in FIG. 93, in each plug coupling portion of the select gate line SGS and the word line WL0, sacrificial films 60 for four layers and insulating layers 35 for four layers in the hole are processed (4L processing illustrated in FIG. 93). That is, the sacrificial films 60 for 2²=4 layers are processed. Thereby, the formation of the holes of the lower contact plugs LCC corresponding to the plug coupling portions of the select gate line SGS and the word line WL0 is completed. After the 4L processing, the holes corresponding to the lower contact plugs LCC are filled with the sacrificial film 64.

After step S302 is executed, upper layers of the middle layer stack are formed (S106), similarly as described using FIG. 9 of the first embodiment.

After step S106 is executed, processing of the middle support pillars MHR and burying by a sacrificial film 62, and processing of the middle memory pillars MMP and burying by a sacrificial film 61, are successively executed (S303). Note that the order of the processing of the middle support pillars MHR and the middle memory pillars MMP, and the burying by the sacrificial films 61 and 62 is arbitrary. In addition, the middle support pillars MHR and the middle memory pillars MMP may be collectively processed. In this case, the holes corresponding to the middle support pillars MHR and the middle memory pillars MMP can be filled with the same sacrificial material.

After step S303 is executed, an upper layer stack is formed (S108), similarly as described using FIG. 9 of the first embodiment.

After step S108 is executed, processing of the upper members USLT and burying by a sacrificial film 63, and processing of the upper contact plugs UCC and burying by a sacrificial film 64, are successively executed (S304). Note that the order of the processing of the upper members USLT and the upper contact plugs UCC, and the burying by the sacrificial films 63 and 64 is arbitrary.

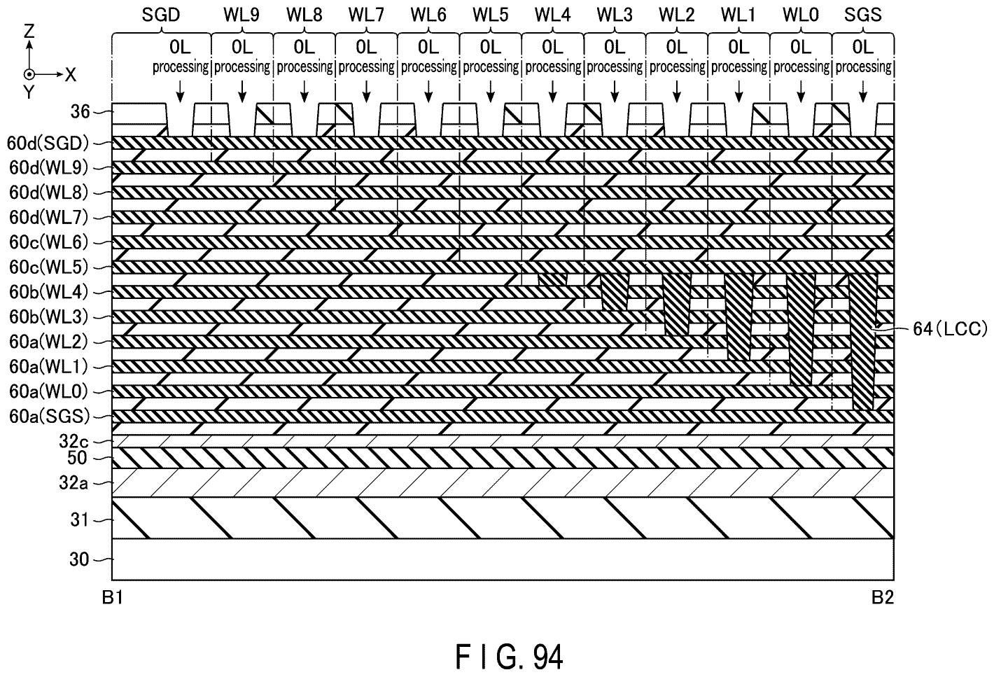

With reference to FIG. 94 to FIG. 98, the processing method of the upper contact plugs UCC is described in detail.

As illustrated in FIG. 94, first, holes corresponding to the insulating layer 36 and the uppermost insulating layer 35 are processed in each plug coupling portion of the select gate lines SGS and SGD and the word lines WL0 to WL9 (0L processing illustrated in FIG. 94). At this step, the sacrificial film 60 is not processed. Thereby, the formation of the hole of the upper contact plug UCC (contact plug CC) corresponding to the plug coupling portion of the select gate line SGD is completed.

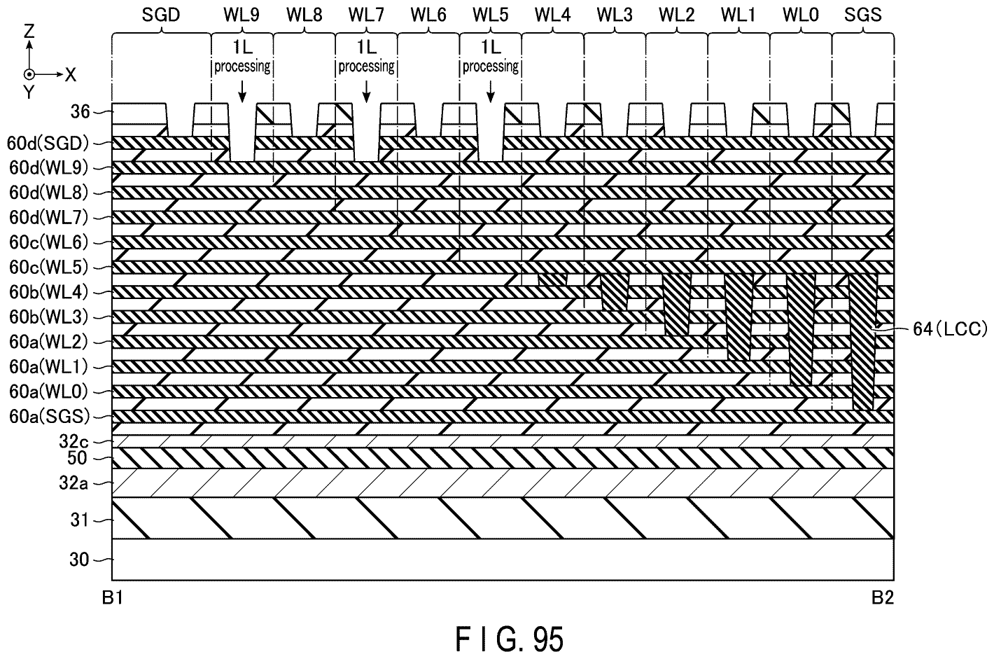

As illustrated in FIG. 95, in each plug coupling portion of the word lines WL5, WL7, and WL9, a sacrificial film 60 for one layer and an insulating layer 35 for one layer in the hole are processed (1L processing illustrated in FIG. 95). That is, the sacrificial film 60 for 2⁰=1 layer is processed. Thereby, the formation of the hole of the upper contact plug UCC (contact plug CC) corresponding to the plug coupling portion of the word line WL9 is completed.

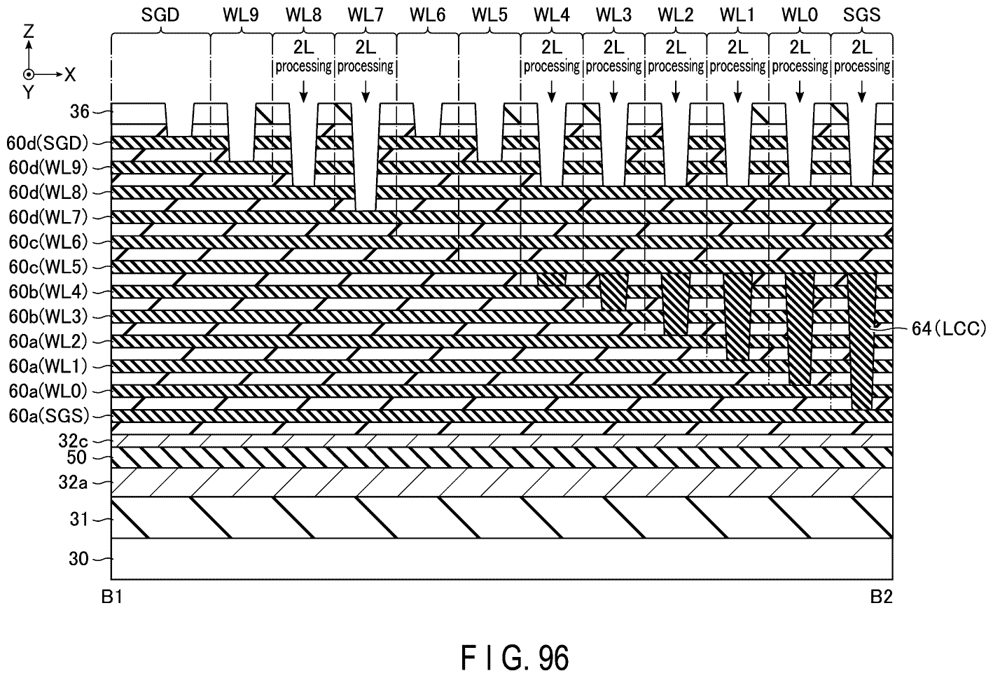

As illustrated in FIG. 96, in each plug coupling portion of the select gate line SGS, and the word lines WL0 to WL4, WL7, and WL8, sacrificial films 60 for two layers and insulating layers 35 for two layers in the hole are processed (2L processing illustrated in FIG. 96). That is, the sacrificial films 60 for 2¹=2 layers are processed. Thereby, the formation of the holes of the upper contact plugs UCC (contact plugs CC) corresponding to the plug coupling portions of the word lines WL7 and WL8 is completed.

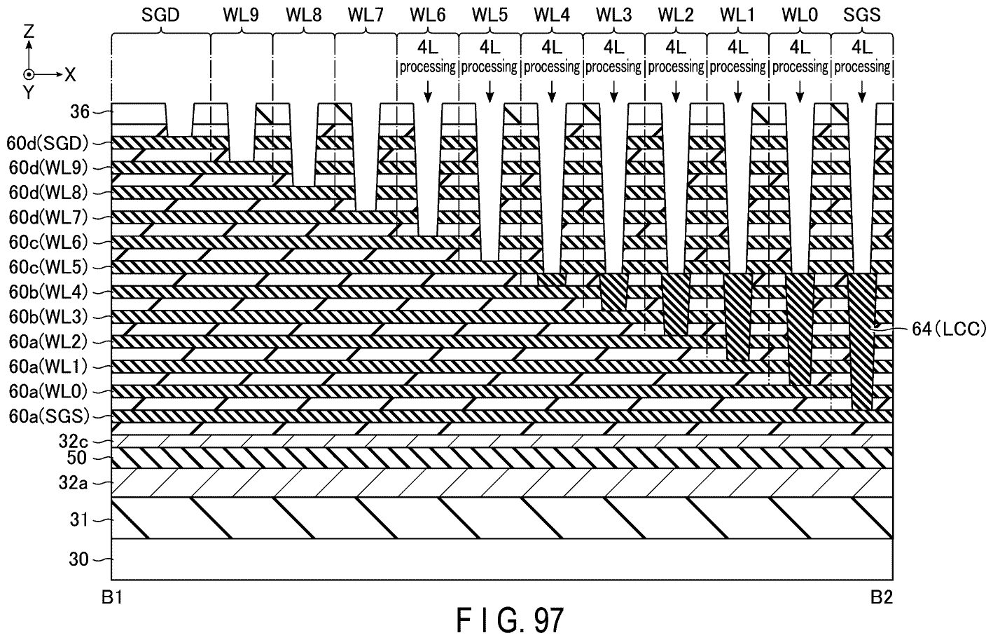

As illustrated in FIG. 97, in each plug coupling portion of the select gate line SGS and the word lines WL0 to WL6, sacrificial films 60 for four layers and insulating layers 35 for four layers in the hole are processed (4L processing illustrated in FIG. 97). That is, the sacrificial films 60 for 2²=4 layers are processed. Thereby, the formation of the holes of the upper contact plugs UCC (contact plugs CC) corresponding to the plug coupling portions of the word lines WL5 and WL6 is completed. Furthermore, in each plug coupling portion of the select gate line SGS and the word lines WL0 to WL4, the formation of the hole of the upper contact plug UCC having a lower end reaching the lower contact plug LCC is completed.

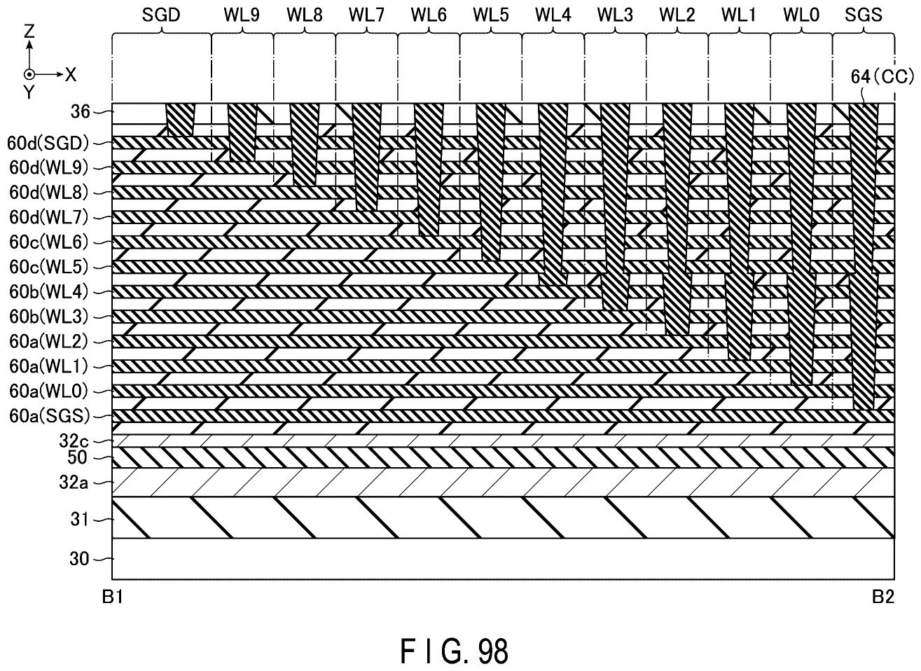

As illustrated in FIG. 98, the holes corresponding to the upper contact plugs UCC are filled with the sacrificial film 64. Thereby, the contact plugs CC filled with a sacrificial film 64 are formed.

After step S304 is executed, processing of the upper support pillars UHR and burying by a sacrificial film 62 are executed (S305).

After step S305 is executed, memory holes corresponding to the upper memory pillars UMP are processed (formed), and the memory pillars MP are formed (S111), similarly as described using FIG. 9 of the first embodiment.

After step S111 is executed, the sacrificial films 62 in the support pillars HR are removed, and an insulator 38 is buried in the holes (S112), similarly as described using FIG. 9 of the first embodiment. Note that in a case where the support pillars HR and the memory pillars MP are collectively formed, steps S305 and S112 are omitted. In addition, in step S111, the memory pillars MP and the support pillars HR are formed at the same time. More specifically, holes corresponding to the upper support pillars UHR and the upper memory pillars UMP are collectively formed. Next, the sacrificial films 61 and 62 in the respective holes are removed. Subsequently, a stacked film 42, a semiconductor film 41, and a core film 40 are formed and buried in each hole, and the support pillars HR and the memory pillars MP are collectively formed.

Steps S113 to S116 are the same as described with reference to FIG. 9 of the first embodiment.

### 4.5. Advantageous Effects According to Present Embodiment

With the configuration according to the present embodiment, like the first embodiment, the number of processes of the memory cell array and the manufacturing cost can be reduced by appropriately setting the number of tiers of the memory pillar MP, the member SLT, the support pillar HR, and the contact plug CC.

Furthermore, with the configuration according to the present embodiment, it is possible to provide the contact plug CC that passes through the interconnect layers 34 provided above the plug coupling portion, and that has a lower end in contact with the plug coupling portion. In addition, with the configuration according to the present embodiment, the boundary position corresponding to the tier of the support pillar HR and the boundary position corresponding to the tier of the contact plug CC can be set between different interconnect layers 34. Thereby, as described with reference to FIG. 88, for example, an increase in distance between the support pillar HR and the contact plug CC can be suppressed. Therefore, for example, bending of the layer stack above the plug coupling portion can be suppressed.

### 5. Modifications, Etc.

The semiconductor memory device according to the above-described embodiments includes a layer stack in which a plurality of interconnect layers (34) and a plurality of insulating layers (35) are alternately stacked one by one in a first direction (Z direction), a memory pillar (MP) extending in the first direction and passing through the layer stack, and a first member (SLT) extending in the first direction and a second direction (X direction) crossing the first direction and dividing the layer stack in a third direction (Y direction) crossing the first direction and the second direction. The plurality of insulating layers include a first insulating layer. The plurality of interconnect layers include a first interconnect layer (WL2) on which the first insulating layer is provided and a second interconnect layer (WL3) provided on the first insulating layer. The memory pillar includes a first sub-pillar (LMP) extending in the first direction, passing through the first interconnect layer, and including an upper end located between the first interconnect layer and the second interconnect layer, and a second sub-pillar (MMP) provided on the first sub-pillar, extending in the first direction, and passing through the second interconnect layer. The first member includes a first portion (LSLT) extending in the first direction and the second direction, passing through the first interconnect layer and the second interconnect layer, and including an upper end located above the second interconnect layer, and a second portion (USLT) provided on the first portion and extending in the layer stack in the first direction and the second direction.

With the configuration according to the above embodiment, the manufacturing cost can be reduced.

Note that, aside from the above-described embodiments, various modifications are applicable.

For example, in the above embodiments, the case was described in which each of the lower memory pillar LMP, the middle memory pillar MMP, and the upper memory pillar UMP has the forward taper shape with a greater diameter at the upper end than at the lower end thereof, but the shape of each pillar is not limited to this. For example, the pillar may have a straight shape with a coupling portion being provided at a tier boundary, or may have a bowing shape having a maximum diameter at an intermediate portion thereof in the Z direction. The same applies to the member SLT, the support pillar HR, and the contact plug CC.

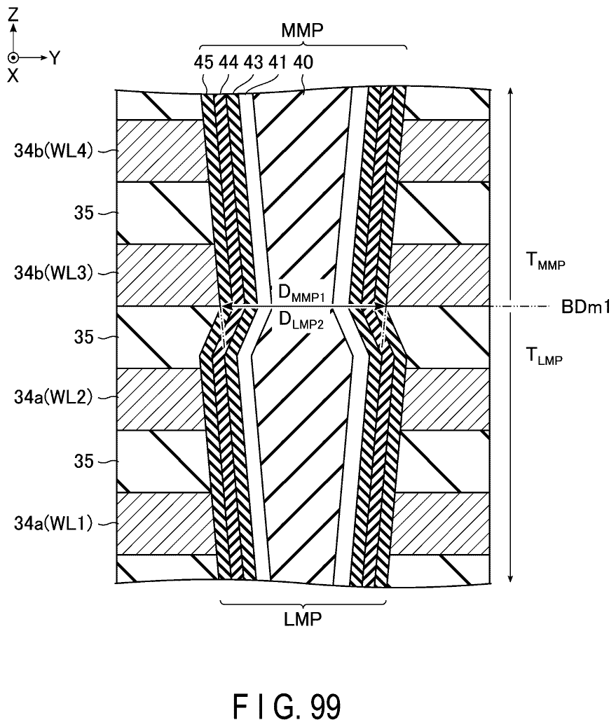

Furthermore, in the above embodiments, for example, the case was described in which the diameter D_{LMP2} of the upper end of the lower memory pillar LMP and the diameter D_{MMP1} of the lower end of the middle memory pillar MMP have a relationship of D_{LMP2}>D_{MMP1}, but the relationship is not limited to this. FIG. 99 is a cross-sectional view of a memory cell array 11 according to a modification. FIG. 99 illustrates the vicinity of the upper end of the lower memory pillar LMP and the vicinity of the lower end of the middle memory pillar MMP. In the example illustrated in FIG. 99, the diameter D_{LMP2} of the upper end of the lower memory pillar LMP and the diameter D_{MMP1} of the lower end of the middle memory pillar MMP have a relationship of D_{LMP2}=D_{MMP1}. In addition, at the upper end of the lower memory pillar LMP included in the lower tier T_{LMP} and at the lower end of the middle memory pillar MMP included in the middle tier T_{MMP}, the shape of the side surface of the lower memory pillar LMP and the shape of the side surface of the middle memory pillar MMP are discontinuous (i.e., in the cross section in the Z direction, the side surface of the lower memory pillar LMP is not aligned with an extension line of the side surface of the middle memory pillar MMP). Furthermore, the upper end of the lower memory pillar LMP has an inverse taper shape (i.e., a shape with a smaller diameter at an upper side than at a lower side thereof). In this case, the boundary BDm1 between the lower memory pillar LMP and the middle memory pillar MMP can be confirmed by observing the cross-sectional shape. The same applies to the relationship between the middle memory pillar MMP and the upper memory pillar UMP. Moreover, the same applies to the member SLT, the support pillar HR, and the contact plug CC.

Furthermore, “coupling” in the above embodiments includes a state of indirect coupling via some other element such as a transistor or a resistor.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a layer stack in which a plurality of interconnect layers and a plurality of insulating layers are alternately stacked one by one in a first direction;
a memory pillar extending in the first direction and passing through the layer stack; and
a first member extending in the first direction and a second direction crossing the first direction, and dividing the layer stack in a third direction crossing the first direction and the second direction, wherein
the plurality of insulating layers include a first insulating layer,
the plurality of interconnect layers include:
a first interconnect layer on which the first insulating layer is provided; and
a second interconnect layer provided on the first insulating layer,
the memory pillar includes:
a first sub-pillar extending in the first direction, passing through the first interconnect layer, and including an upper end located between the first interconnect layer and the second interconnect layer; and
a second sub-pillar provided on the first sub-pillar, extending in the first direction, and passing through the second interconnect layer, and
the first member includes:
a first portion extending in the first direction and the second direction, passing through the first interconnect layer and the second interconnect layer, and including an upper end located above the second interconnect layer; and
a second portion provided on the first portion and extending in the layer stack in the first direction and the second direction.

2. The semiconductor memory device according to claim 1, wherein
the layer stack includes:
a memory area including the memory pillar; and
a staircase area disposed to neighbor the memory area in the second direction, and configured such that a part of each of the plurality of interconnect layers is provided in a staircase fashion, and
the first member extends in the second direction and passes through the memory area and the staircase area.

3. The semiconductor memory device according to claim 1, further comprising a semiconductor layer provided below the layer stack, wherein
a lower end of the first sub-pillar and a lower end of the first portion in the first member reach the semiconductor layer, and
the first sub-pillar is electrically coupled to the semiconductor layer.

4. The semiconductor memory device according to claim 1, further comprising a support pillar extending in the first direction and passing through the layer stack, the support pillar being not electrically coupled to the plurality of interconnect layers, wherein
the layer stack includes:
a memory area including the memory pillar; and
a staircase area disposed to neighbor the memory area in the second direction, including the support pillar, and configured such that a part of each of the plurality of interconnect layers is provided in a staircase fashion, and
the support pillar includes:
a third sub-pillar extending in the first direction, passing through the first interconnect layer and the second interconnect layer, and including an upper end located above the second interconnect layer; and
a fourth sub-pillar provided on the third sub-pillar and extending in the first direction.

5. The semiconductor memory device according to claim 4, further comprising a semiconductor layer provided below the layer stack, wherein
a lower end of the third sub-pillar reaches the semiconductor layer, and
the third sub-pillar is not electrically coupled to the semiconductor layer.

6. The semiconductor memory device according to claim 1, further comprising a first contact plug extending in the first direction and electrically coupled to the first interconnect layer, wherein
the first contact plug includes:
a first sub-plug electrically coupled to the first interconnect layer, extending in the first direction, and including an upper end located above the second interconnect layer; and
a second sub-plug provided on the first sub-plug and extending in the first direction.

7. The semiconductor memory device according to claim 6, further comprising a second contact plug extending in the first direction and electrically coupled to the second interconnect layer, wherein
a lower end of the first contact plug is in contact with a first plug coupling portion that is provided in the first interconnect layer and that does not overlap, in the first direction, an interconnect layer provided above the first interconnect layer among the plurality of interconnect layers,
a lower end of the second contact plug is in contact with a second plug coupling portion that is provided in the second interconnect layer and that does not overlap, in the first direction, an interconnect layer provided above the second interconnect layer among the plurality of interconnect layers, and
a height of the first contact plug is different from a height of the second contact plug.

8. The semiconductor memory device according to claim 7, wherein the first plug coupling portion and the second plug coupling portion are disposed in a staircase fashion along the second direction.

9. The semiconductor memory device according to claim 1, wherein
the plurality of insulating layers further include a second insulating layer,
the plurality of interconnect layers further include:
a third interconnect layer provided above the second interconnect layer, the second insulating layer being provided on the third interconnect layer; and
a fourth interconnect layer provided on the second insulating layer,
the second sub-pillar passes through the third interconnect layer, and includes an upper end located between the third interconnect layer and the fourth interconnect layer,
the memory pillar further includes a fifth sub-pillar provided on the second sub-pillar, the fifth sub-pillar extending in the first direction and passing through the fourth interconnect layer, and
the second portion in the first member passes through the third interconnect layer and the fourth interconnect layer, and includes an upper end located above the plurality of interconnect layers.

10. The semiconductor memory device according to claim 6, wherein
the plurality of interconnect layers further include a fifth interconnect layer provided below the first interconnect layer, and
the first sub-plug passes through the fifth interconnect layer and is not electrically coupled to the fifth interconnect layer.

11. The semiconductor memory device according to claim 10, wherein
the first sub-plug includes a projecting portion that concentrically projects, and
the projecting portion is in contact with a first plug coupling portion that is provided in the first interconnect layer and that does not overlap, in the first direction, an interconnect layer provided above the first interconnect layer among the plurality of interconnect layers.

12. The semiconductor memory device according to claim 10, further comprising a second contact plug extending in the first direction and electrically coupled to the second interconnect layer, wherein
a height of the first contact plug is substantially equal to a height of the second contact plug.

13. A semiconductor memory device comprising:
a layer stack in which a plurality of interconnect layers and a plurality of insulating layers are alternately stacked one by one in a first direction;
a memory pillar extending in the first direction and passing through the layer stack; and
a support pillar extending in the first direction and passing through the layer stack, the support pillar being not electrically coupled to the plurality of interconnect layers, wherein
the layer stack includes:
a memory area including the memory pillar; and
a staircase area disposed to neighbor the memory area in a second direction crossing the first direction, including the support pillar, and configured such that a part of each of the plurality of interconnect layers is provided in a staircase fashion,
the plurality of insulating layers include a first insulating layer,
the plurality of interconnect layers include:
a first interconnect layer on which the first insulating layer is provided; and
a second interconnect layer provided on the first insulating layer,
the memory pillar includes:
a first sub-pillar extending in the first direction, passing through the first interconnect layer, and including an upper end located between the first interconnect layer and the second interconnect layer; and
a second sub-pillar provided on the first sub-pillar, extending in the first direction, and passing through the second interconnect layer, and
the support pillar includes:
a third sub-pillar extending in the first direction, passing through the first interconnect layer and the second interconnect layer, and including an upper end located above the second interconnect layer; and
a fourth sub-pillar provided on the third sub-pillar and extending in the first direction.

14. The semiconductor memory device according to claim 13, further comprising a semiconductor layer provided below the layer stack, wherein
a lower end of the first sub-pillar and a lower end of the third sub-pillar reach the semiconductor layer,
the first sub-pillar is electrically coupled to the semiconductor layer, and
the third sub-pillar is not electrically coupled to the semiconductor layer.

15. The semiconductor memory device according to claim 13, wherein
the plurality of insulating layers further include a second insulating layer,
the plurality of interconnect layers further include:
a third interconnect layer provided above the second interconnect layer, the second insulating layer being provided on the third interconnect layer; and
a fourth interconnect layer provided on the second insulating layer,
the second sub-pillar passes through the third interconnect layer, and includes an upper end located between the third interconnect layer and the fourth interconnect layer,
the memory pillar further includes a fifth sub-pillar provided on the second sub-pillar, the fifth sub-pillar extending in the first direction and passing through the fourth interconnect layer, and
the fourth sub-pillar passes through the third interconnect layer and the fourth interconnect layer, and includes an upper end located above the plurality of interconnect layers.

16. A semiconductor memory device comprising:
a layer stack in which a plurality of interconnect layers and a plurality of insulating layers are alternately stacked one by one in a first direction;
a memory pillar extending in the first direction and passing through the layer stack;
a support pillar extending in the first direction and passing through the layer stack, the support pillar being not electrically coupled to the plurality of interconnect layers; and
a first contact plug extending in the first direction and electrically coupled to any one of the plurality of interconnect layers, wherein
the plurality of insulating layers include a first insulating layer,
the plurality of interconnect layers include:
a first interconnect layer on which the first insulating layer is provided; and
a second interconnect layer provided on the first insulating layer,
the support pillar includes:
a first sub-pillar extending in the first direction, passing through the first interconnect layer, and including an upper end located between the first interconnect layer and the second interconnect layer; and
a second sub-pillar provided on the first sub-pillar, extending in the first direction, and passing through the second interconnect layer, and
the first contact plug includes:
a first sub-plug extending in the first direction, passing through the second interconnect layer, and not electrically coupled to the second interconnect layer, the first sub-plug including a lower end electrically coupled to the first interconnect layer and an upper end located above the second interconnect layer; and
a second sub-plug provided on the first sub-plug and extending in the first direction.

17. The semiconductor memory device according to claim 16, wherein
the plurality of interconnect layers further include a third interconnect layer provided above the second interconnect layer, and
the second sub-plug passes through the third interconnect layer and is not electrically coupled to the third interconnect layer.

18. The semiconductor memory device according to claim 16, wherein the first contact plug includes a conductor extending in the first direction and including a lower end in contact with the first interconnect layer, and an insulator covering a side surface of the conductor.

19. The semiconductor memory device according to claim 17, further comprising a second contact plug extending in the first direction and electrically coupled to the second interconnect layer, wherein
the second contact plug includes:
a third sub-plug extending in the first direction and including a lower end electrically coupled to the second interconnect layer; and
a fourth sub-plug provided on the third sub-plug, extending in the first direction, passing through the third interconnect layer, and not electrically coupled to the third interconnect layer,
a height of the first sub-plug is different from a height of the third sub-plug, and
a height of the second sub-plug is substantially equal to a height of the fourth sub-plug.

20. The semiconductor memory device according to claim 16, wherein
the plurality of insulating layers further include a second insulating layer,
the plurality of interconnect layers further include:
a third interconnect layer provided above the second interconnect layer, the second insulating layer being provided on the third interconnect layer; and
a fourth interconnect layer provided on the second insulating layer,
the second sub-pillar passes through the third interconnect layer, and includes an upper end located between the third interconnect layer and the fourth interconnect layer,
the support pillar further includes a third sub-pillar provided on the second sub-pillar, the third sub-pillar extending in the first direction and passing through the fourth interconnect layer, and
the second sub-plug passes through the third interconnect layer and the fourth interconnect layer, and is not electrically coupled to the third interconnect layer and the fourth interconnect layer, the second sub-plug including an upper end located above the interconnect layers.
